(19) United States
(12) Patent Application Publication
(10) Pub. No.: US 2025/0301737 A1
(43) Pub. Date: Sep. 25, 2025

(54) METHOD FOR MANUFACTURING SEMICONDUCTOR MEMORY DEVICE AND SEMICONDUCTOR MEMORY DEVICE

(71) Applicant: Kioxia Corporation, Tokyo (JP)

(72) Inventors: Atsuko SAKATA, Yokkaichi Mie (JP); Shinji MORI, Nagoya Aichi (JP); Kenichiro TORATANI, Yokkaichi Mie (JP); Hiroshi ITOKAWA, Oita Oita (JP); Takamitsu OCHI, Nagoya Aichi (JP)

(73) Assignee: Kioxia Corporation, Tokyo (JP)

(21) Appl. No.: 19/087,049

(22) Filed: Mar. 21, 2025

(30) Foreign Application Priority Data
Mar. 22, 2024 (JP) 2024-047373

(51) Int. Cl. H10D 62/40; G11C 5/06; H10B 12/00; H10D 62/83

(52) U.S. Cl. CPC H10D 62/40; G11C 5/063; H10B 12/03; H10B 12/05; H10D 62/83

(57) ABSTRACT

A method for manufacturing a semiconductor memory device according to an embodiment includes: forming a first film, a second film, and a third film in a first direction of a single crystal silicon substrate; forming a first opening penetrating the third to first films reaching the single crystal silicon substrate; forming a first single crystal silicon layer in the first opening; forming a second opening penetrating the third and second films; etching the second film from a side face of the second opening to form a first recess reaching the first single crystal silicon layer; forming a second single crystal silicon layer in the first recess; forming a wiring layer in contact with a first portion of the second single crystal silicon layer; forming a capacitor in contact with a second portion of the second single crystal silicon layer; and forming a gate electrode layer facing a third portion.

### CROSS-REFERENCE TO RELATED APPLICATION

This application is based upon and claims the benefit of priority from Japanese Patent Application No. 2024-047373, filed on Mar. 22, 2024, the entire contents of which are incorporated herein by reference.

### FIELD

Embodiments described herein relate generally to method for manufacturing semiconductor memory device and semiconductor memory device.

### BACKGROUND

It is conceivable to three-dimensionally dispose memory cells in order to realize high integration of a dynamic random access memory (DRAM).

### BRIEF DESCRIPTION OF THE DRAWINGS

FIG. 1 is an equivalent circuit diagram of a memory cell array of a semiconductor memory device of a first embodiment;

FIG. 2 is a schematic cross-sectional view of the semiconductor memory device of the first embodiment;

FIG. 3 is a schematic cross-sectional view of the semiconductor memory device of the first embodiment;

FIG. 4 is a schematic cross-sectional view illustrating a method for manufacturing the semiconductor memory device of the first embodiment;

FIG. 5 is a schematic cross-sectional view illustrating the method for manufacturing the semiconductor memory device of the first embodiment;

FIG. 6 is a schematic cross-sectional view illustrating the method for manufacturing the semiconductor memory device of the first embodiment;

FIG. 7 is a schematic cross-sectional view illustrating the method for manufacturing the semiconductor memory device of the first embodiment;

FIG. 8 is a schematic cross-sectional view illustrating the method for manufacturing the semiconductor memory device of the first embodiment;

FIG. 9 is a schematic cross-sectional view illustrating the method for manufacturing the semiconductor memory device of the first embodiment;

FIG. 10 is a schematic cross-sectional view illustrating the method for manufacturing the semiconductor memory device of the first embodiment;

FIG. 11 is a schematic cross-sectional view illustrating the method for manufacturing the semiconductor memory device of the first embodiment;

FIG. 12 is a schematic cross-sectional view illustrating the method for manufacturing the semiconductor memory device of the first embodiment;

FIG. 13 is a schematic cross-sectional view illustrating the method for manufacturing the semiconductor memory device of the first embodiment;

FIG. 14 is a schematic cross-sectional view illustrating the method for manufacturing the semiconductor memory device of the first embodiment;

FIG. 15 is a schematic cross-sectional view illustrating the method for manufacturing the semiconductor memory device of the first embodiment;

FIG. 16 is a schematic cross-sectional view illustrating the method for manufacturing the semiconductor memory device of the first embodiment;

FIG. 17 is a schematic cross-sectional view illustrating the method for manufacturing the semiconductor memory device of the first embodiment;

FIG. 18 is a schematic cross-sectional view illustrating the method for manufacturing the semiconductor memory device of the first embodiment;

FIG. 19 is a schematic cross-sectional view illustrating the method for manufacturing the semiconductor memory device of the first embodiment;

FIG. 20 is a schematic cross-sectional view illustrating the method for manufacturing the semiconductor memory device of the first embodiment;

FIG. 21 is a schematic cross-sectional view illustrating the method for manufacturing the semiconductor memory device of the first embodiment;

FIG. 22 is a schematic cross-sectional view illustrating the method for manufacturing the semiconductor memory device of the first embodiment;

FIG. 23 is a schematic cross-sectional view illustrating the method for manufacturing the semiconductor memory device of the first embodiment;

FIG. 24 is a schematic cross-sectional view illustrating a method for manufacturing a semiconductor memory device of a modified example of the first embodiment;

FIG. 25 is a schematic cross-sectional view illustrating the method for manufacturing a semiconductor memory device of the modified example of the first embodiment;

FIG. 26 is a schematic cross-sectional view illustrating the method for manufacturing a semiconductor memory device of the modified example of the first embodiment;

FIG. 27 is a schematic cross-sectional view illustrating the method for manufacturing a semiconductor memory device of the modified example of the first embodiment;

FIG. 28 is a schematic cross-sectional view illustrating the method for manufacturing a semiconductor memory device of the modified example of the first embodiment;

FIG. 29 is a schematic cross-sectional view illustrating the method for manufacturing a semiconductor memory device of the modified example of the first embodiment;

FIG. 30 is an equivalent circuit diagram of a memory cell array of a semiconductor memory device of a second embodiment;

FIG. 31 is a schematic cross-sectional view of the semiconductor memory device of the second embodiment;

FIG. 32 is a schematic cross-sectional view of the semiconductor memory device of the second embodiment;

FIG. 33 is a schematic cross-sectional view illustrating a method for manufacturing the semiconductor memory device of the second embodiment;

FIG. 34 is a schematic cross-sectional view illustrating the method for manufacturing the semiconductor memory device of the second embodiment;

FIG. 35 is a schematic cross-sectional view illustrating the method for manufacturing the semiconductor memory device of the second embodiment;

FIG. 36 is a schematic cross-sectional view illustrating the method for manufacturing the semiconductor memory device of the second embodiment;

FIG. 37 is a schematic cross-sectional view illustrating the method for manufacturing the semiconductor memory device of the second embodiment;

FIG. 38 is a schematic cross-sectional view illustrating the method for manufacturing the semiconductor memory device of the second embodiment;

FIG. 39 is a schematic cross-sectional view illustrating the method for manufacturing the semiconductor memory device of the second embodiment;

FIG. 40 is a schematic cross-sectional view illustrating the method for manufacturing the semiconductor memory device of the second embodiment;

FIG. 41 is a schematic cross-sectional view illustrating the method for manufacturing the semiconductor memory device of the second embodiment;

FIG. 42 is a schematic cross-sectional view illustrating the method for manufacturing the semiconductor memory device of the second embodiment;

FIG. 43 is a schematic cross-sectional view illustrating the method for manufacturing the semiconductor memory device of the second embodiment;

FIG. 44 is a schematic cross-sectional view illustrating the method for manufacturing the semiconductor memory device of the second embodiment;

FIG. 45 is a schematic cross-sectional view illustrating the method for manufacturing the semiconductor memory device of the second embodiment;

FIG. 46 is a schematic cross-sectional view illustrating the method for manufacturing the semiconductor memory device of the second embodiment;

FIG. 47 is a schematic cross-sectional view illustrating the method for manufacturing the semiconductor memory device of the second embodiment;

FIG. 48 is a schematic cross-sectional view illustrating the method for manufacturing the semiconductor memory device of the second embodiment;

FIG. 49 is a schematic cross-sectional view illustrating the method for manufacturing the semiconductor memory device of the second embodiment;

FIG. 50 is a schematic cross-sectional view illustrating the method for manufacturing the semiconductor memory device of the second embodiment;

FIG. 51 is a schematic cross-sectional view illustrating a method for manufacturing a semiconductor memory device of a third embodiment;

FIG. 52 is a schematic cross-sectional view illustrating the method for manufacturing the semiconductor memory device of the third embodiment;

FIG. 53 is a schematic cross-sectional view illustrating the method for manufacturing the semiconductor memory device of the third embodiment;

FIG. 54 is a schematic cross-sectional view illustrating the method for manufacturing the semiconductor memory device of the third embodiment;

FIG. 55 is a schematic cross-sectional view illustrating the method for manufacturing the semiconductor memory device of the third embodiment; and

FIG. 56 is a schematic cross-sectional view illustrating the method for manufacturing the semiconductor memory device of the third embodiment;

FIG. 57 is a schematic cross-sectional view illustrating a method for manufacturing a semiconductor memory device of a fourth embodiment;

FIG. 58 is a schematic cross-sectional view illustrating the method for manufacturing the semiconductor memory device of the fourth embodiment;

FIG. 59 is a schematic cross-sectional view illustrating the method for manufacturing the semiconductor memory device of the fourth embodiment;

FIG. 60 is a schematic cross-sectional view illustrating the method for manufacturing the semiconductor memory device of the fourth embodiment;

FIG. 61 is a schematic cross-sectional view illustrating the method for manufacturing the semiconductor memory device of the fourth embodiment;

FIG. 62 is a schematic cross-sectional view illustrating the method for manufacturing the semiconductor memory device of the fourth embodiment;

FIG. 63 is a schematic cross-sectional view illustrating the method for manufacturing the semiconductor memory device of the fourth embodiment;

FIG. 64 is a schematic cross-sectional view illustrating the method for manufacturing the semiconductor memory device of the fourth embodiment;

FIG. 65 is a schematic cross-sectional view illustrating the method for manufacturing the semiconductor memory device of the fourth embodiment;

FIG. 66 is a schematic cross-sectional view illustrating the method for manufacturing the semiconductor memory device of the fourth embodiment;

FIG. 67 is a schematic cross-sectional view illustrating the method for manufacturing the semiconductor memory device of the fourth embodiment;

FIG. 68 is a schematic cross-sectional view illustrating the method for manufacturing the semiconductor memory device of the fourth embodiment;

FIG. 69 is a schematic cross-sectional view illustrating the method for manufacturing the semiconductor memory device of the fourth embodiment;

FIG. 70 is a schematic cross-sectional view illustrating the method for manufacturing the semiconductor memory device of the fourth embodiment;

FIG. 71 is a schematic cross-sectional view illustrating the method for manufacturing the semiconductor memory device of the fourth embodiment;

FIG. 72 is a schematic cross-sectional view illustrating a method for manufacturing a semiconductor memory device of a modified example of the fourth embodiment;

FIG. 73 is a schematic cross-sectional view illustrating the method for manufacturing a semiconductor memory device of the modified example of the fourth embodiment;

FIG. 74 is a schematic cross-sectional view illustrating the method for manufacturing a semiconductor memory device of the modified example of the fourth embodiment;

FIG. 75 is a schematic cross-sectional view illustrating a method for manufacturing a semiconductor memory device of a fifth embodiment;

FIG. 76 is a schematic cross-sectional view illustrating the method for manufacturing the semiconductor memory device of the fifth embodiment;

FIG. 77 is a schematic cross-sectional view illustrating the method for manufacturing the semiconductor memory device of the fifth embodiment;

FIG. 78 is a schematic cross-sectional view illustrating the method for manufacturing the semiconductor memory device of the fifth embodiment;

FIG. 79 is a schematic cross-sectional view illustrating the method for manufacturing the semiconductor memory device of the fifth embodiment;

FIG. 80 is a schematic cross-sectional view illustrating the method for manufacturing the semiconductor memory device of the fifth embodiment;

FIG. 81 is a schematic cross-sectional view illustrating the method for manufacturing the semiconductor memory device of the fifth embodiment;

FIG. 82 is a schematic cross-sectional view illustrating the method for manufacturing the semiconductor memory device of the fifth embodiment;

FIG. 83 is a schematic cross-sectional view illustrating the method for manufacturing the semiconductor memory device of the fifth embodiment;

FIG. 84 is a schematic cross-sectional view illustrating the method for manufacturing the semiconductor memory device of the fifth embodiment;

FIG. 85 is a schematic cross-sectional view illustrating the method for manufacturing the semiconductor memory device of the fifth embodiment;

FIG. 86 is a schematic cross-sectional view illustrating the method for manufacturing the semiconductor memory device of the fifth embodiment;

FIG. 87 is a schematic cross-sectional view illustrating the method for manufacturing the semiconductor memory device of the fifth embodiment;

FIG. 88 is a schematic cross-sectional view illustrating the method for manufacturing the semiconductor memory device of the fifth embodiment;

FIG. 89 is a schematic cross-sectional view illustrating the method for manufacturing the semiconductor memory device of the fifth embodiment;

FIG. 90 is a schematic cross-sectional view illustrating the method for manufacturing the semiconductor memory device of the fifth embodiment;

FIG. 91 is a schematic cross-sectional view illustrating a method for manufacturing a semiconductor memory device of a sixth embodiment;

FIG. 92 is a schematic cross-sectional view illustrating the method for manufacturing the semiconductor memory device of the sixth embodiment;

FIG. 93 is a schematic cross-sectional view illustrating the method for manufacturing the semiconductor memory device of the sixth embodiment;

FIG. 94 is a schematic cross-sectional view illustrating the method for manufacturing the semiconductor memory device of the sixth embodiment; and

FIG. 95 is a schematic cross-sectional view illustrating the method for manufacturing the semiconductor memory device of the sixth embodiment.

### DETAILED DESCRIPTION

A method for manufacturing a semiconductor memory device of an embodiment includes: forming a first film of a first material in a first direction of a single crystal silicon substrate; forming a second film of a second material different from the first material, in the first direction of the first film; forming a third film of a third material different from the second material, in the first direction of the second film; forming a first opening penetrating the third film, the second film, and the first film and reaching the single crystal silicon substrate; forming a first single crystal silicon layer in contact with the single crystal silicon substrate in the first opening; forming a second opening penetrating the third film and the second film; etching the second film from a side face of the second opening to form a first recess reaching the first single crystal silicon layer; forming a second single crystal silicon layer in contact with the first single crystal silicon layer in the first recess; forming a wiring layer in contact with a first portion of the second single crystal silicon layer; forming a capacitor in contact with a second portion of the second single crystal silicon layer; and forming a gate electrode layer facing a third portion of the second single crystal silicon layer between the first portion and the second portion.

Hereinafter, embodiments will be described with reference to the drawings. In the following description, the same or equivalent members and the like will be denoted by the same reference numerals, and members that have been once described will not be described as appropriate.

In the present specification, the term “above” or “below” may be used for the sake of convenience. The term “above” or “below” is merely a term indicating a relative positional relationship within a drawing and is not a term that defines a positional relationship with respect to gravity.

Qualitative analysis and quantitative analysis of chemical compositions of the members forming the semiconductor memory device in the present specification can be carried out by secondary ion mass spectroscopy (SIMS), energy dispersive X-ray spectroscopy (EDX), electron energy loss spectroscopy (EELS), and the like. In addition, it is possible to use a transmission electron microscope (TEM), for example, for measurement of a thickness of a member forming the semiconductor memory device, a distance between members, and the like. In addition, the TEM can be used for evaluation of crystallinity of a member constituting the semiconductor memory device and evaluation of a crystal defect density.

### First Embodiment

A method for manufacturing a semiconductor memory device of a first embodiment includes: forming a first film of a first material in a first direction of a single crystal silicon substrate; forming a second film of a second material different from the first material, in the first direction of the first film; forming a third film of a third material different from the second material, in the first direction of the second film; forming a first opening penetrating the third film, the second film, and the first film and reaching the single crystal silicon substrate; forming a first single crystal silicon layer in contact with the single crystal silicon substrate in the first opening; forming a second opening penetrating the third film and the second film; etching the second film from a side face of the second opening to form a first recess reaching the first single crystal silicon layer; forming a second single crystal silicon layer in contact with the first single crystal silicon layer in the first recess; forming a wiring layer in contact with a first portion of the second single crystal silicon layer; forming a capacitor in contact with a second portion of the second single crystal silicon layer; and forming a gate electrode layer facing a third portion of the second single crystal silicon layer between the first portion and the second portion.

The semiconductor memory device of the first embodiment includes: the single crystal silicon substrate; the single crystal silicon layer extending in a direction along a surface of the single crystal silicon substrate, the single crystal silicon layer being separated from the single crystal silicon substrate; the wiring layer electrically connected to the first portion of the single crystal silicon layer; the capacitor electrically connected to the second portion of the single crystal silicon layer; and the gate electrode layer facing the third portion of the single crystal silicon layer between the first portion and the second portion. A crystal defect density of the first portion is higher than a crystal defect density of the third portion.

The semiconductor memory device of the first embodiment is a DRAM. The DRAM of the first embodiment is a DRAM having a three-dimensional structure in which memory cells are three-dimensionally disposed. The DRAM of the first embodiment is a DRAM in which a word line is provided in a direction perpendicular to the substrate.

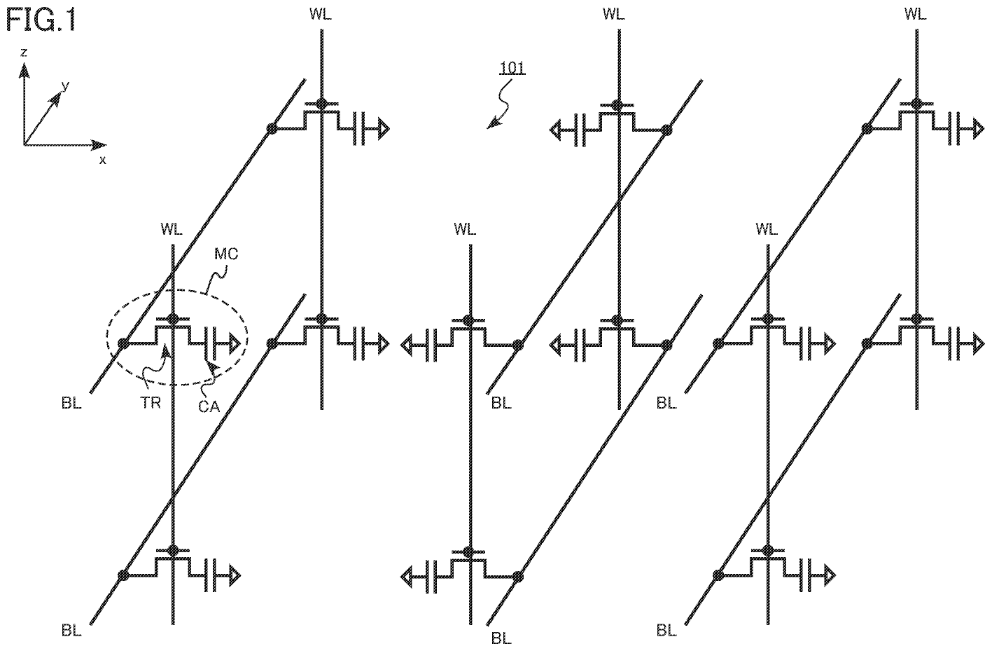

FIG. 1 is an equivalent circuit diagram of a memory cell array of the semiconductor memory device of the first embodiment. The DRAM of the first embodiment includes a memory cell array 101. FIG. 1 schematically illustrates a wiring structure in the memory cell array 101. The memory cell array 101 of the first embodiment has a three-dimensional structure in which a plurality of memory cells MC are three-dimensionally disposed. Although FIG. 1 illustrates a case where the number of the memory cells MC is twelve, the number of memory cells included in the memory cell array 101 is not limited to twelve.

Hereinafter, a z direction illustrated in FIG. 1 is an example of the first direction. An x direction is an example of a second direction. A y direction is an example of a third direction. The y direction intersects with the x direction. The z direction intersects with the x direction and the y direction. For example, the x direction and the y direction are orthogonal to each other. For example, the z direction, the x direction, and the y direction are orthogonal to each other.

The memory cell array 101 includes the plurality of memory cells MC, a plurality of word lines WL, and a plurality of bit lines BL. The memory cell MC includes the transistor TR and the capacitor CA.

The word line WL extends in the z direction. The bit line extends in the y direction.

The word line WL is electrically connected to a gate electrode of the transistor TR. The bit line BL is electrically connected to one of source and drain electrodes of the transistor TR. The other of the source and drain electrodes of the transistor TR is electrically connected to one of electrodes of the capacitor CA.

The memory cell MC stores data by accumulating charge in the capacitor CA. Data is written and read by turning on the transistor TR.

One memory cell MC can be selected by selecting one bit line BL and one word line WL. For example, the transistor TR is turned on by applying a voltage to the word line WL in a state where a desired voltage is applied to the bit line BL, thereby writing data to the memory cell MC. In addition, for example, the transistor TR is turned on, and a voltage change of the bit line BL corresponding to the amount of charge accumulated in the capacitor CA is detected, thereby reading data of the memory cell MC.

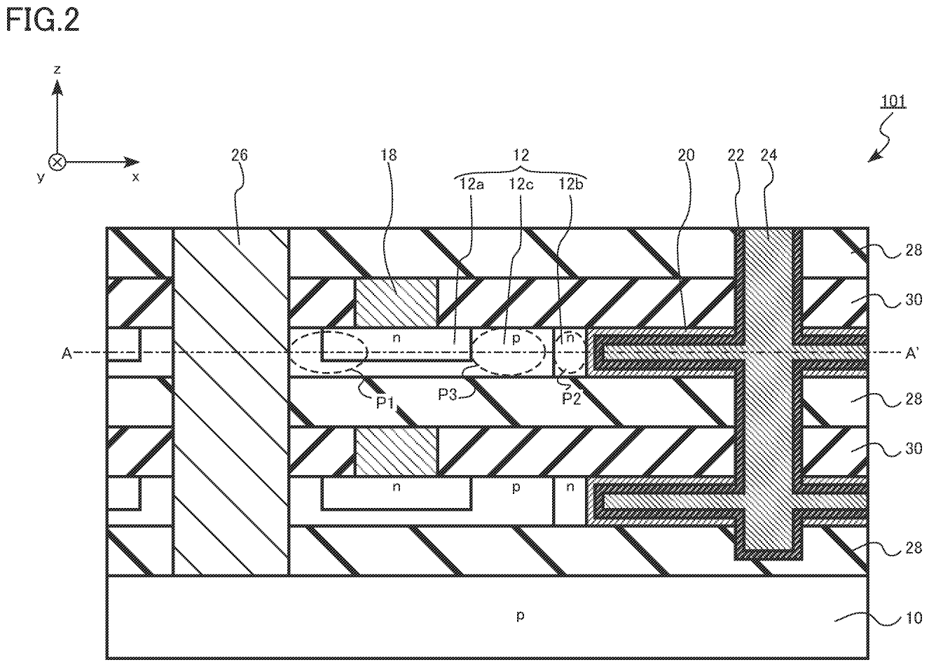

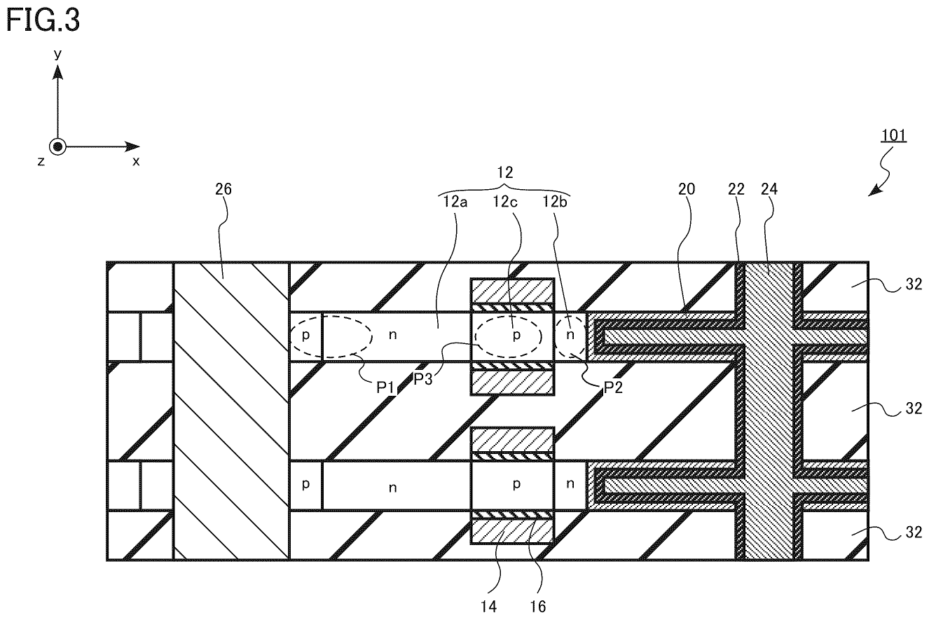

FIGS. 2 and 3 are schematic cross-sectional views of the semiconductor memory device of the first embodiment. FIGS. 2 and 3 are cross sections each including two memory cells MC.

FIG. 2 is an xz cross section. FIG. 3 is an xy cross section. FIG. 3 is a cross section taken along a line AA′ of FIG. 2.

The memory cell array 101 of the DRAM of the first embodiment includes a single crystal silicon substrate 10, a single crystal silicon layer 12, a gate electrode layer 14, a gate insulating film 16, a wiring layer 18, a storage node electrode 20, a capacitor insulating film 22, a plate electrode 24, a contact electrode 26, a first interlayer insulating layer 28, a second interlayer insulating layer 30, and a third interlayer insulating layer 32.

The single crystal silicon layer 12 includes the first n-type impurity region 12a, the second n-type impurity region 12b, and the p-type impurity region 12c.

The single crystal silicon layer 12, the gate electrode layer 14, and the gate insulating film 16 constitute the transistor TR. In addition, the storage node electrode 20, the capacitor insulating film 22, and the plate electrode 24 constitute the capacitor CA.

The single crystal silicon substrate 10 is single crystal silicon. The single crystal silicon substrate 10 contains, for example, p-type impurities. The single crystal silicon substrate 10 is, for example, a p-type substrate. A normal direction of a surface of the single crystal silicon substrate 10 is the z direction. The normal direction of the surface of the single crystal silicon substrate 10 is the first direction.

The single crystal silicon layer 12 is single crystal silicon. The single crystal silicon layer 12 extends in a direction along the surface of the single crystal silicon substrate 10. The single crystal silicon layer 12 extends, for example, in the second direction. The single crystal silicon layer 12 is separated from the single crystal silicon substrate 10 in the first direction.

The single crystal silicon layer 12 includes the first n-type impurity region 12a, the second n-type impurity region 12b, and the p-type impurity region 12c. The p-type impurity region 12c is provided between the first n-type impurity region 12a and the second n-type impurity region 12b.

The first n-type impurity region 12a contains n-type impurities. The first n-type impurity region 12a is n-type silicon. The second n-type impurity region 12b contains n-type impurities. The second n-type impurity region 12b is n-type silicon. The p-type impurity region 12c contains p-type impurities. The p-type impurity region 12c is p-type silicon.

The single crystal silicon layer 12 has the first portion P1, the second portion P2, and the third portion P3. The third portion P3 is provided between the first portion P1 and the second portion P2. The first portion P1, the second portion P2, and the third portion P3 are, for example, regions surrounded by dotted lines in FIGS. 1 and 2, respectively.

The first portion P1 includes, for example, the first n-type impurity region 12a. The second portion P2 includes, for example, the second n-type impurity region 12b. The third portion P3 includes, for example, the p-type impurity region 12c.

A crystal defect density of the first portion P1 is higher than a crystal defect density of the third portion P3. The crystal defect density of the first portion P1 is, for example, equal to or more than ten times and equal to or less than 1000 times the crystal defect density of the third portion P3.

A crystal defect density of the first n-type impurity region 12a is higher than a crystal defect density of the p-type impurity region 12c. The crystal defect density of the first n-type impurity region 12a is, for example, equal to or more than ten times and equal to or less than 1000 times the crystal defect density of the p-type impurity region 12c.

The gate electrode layer 14 extends in the normal direction of the surface of the single crystal silicon substrate 10. The gate electrode layer 14 extends in the first direction. The gate electrode layer 14 corresponds to the word line WL.

The gate electrode layer 14 is provided on each of both sides of the single crystal silicon layer 12 in the third direction. For example, the single crystal silicon layer 12 is provided between the two gate electrode layers 14 having the same electric potential.

The gate electrode layer 14 is facing the single crystal silicon layer 12. The gate electrode layer 14 is facing the third portion P3 of the single crystal silicon layer 12. The gate electrode layer 14 is facing the p-type impurity region 12c of the single crystal silicon layer 12.

The gate electrode layer 14 is a conductor. The gate electrode layer 14 is, for example, polycrystalline silicon containing conductive impurities.

The gate insulating film 16 is provided between the gate electrode layer 14 and the single crystal silicon layer 12. The gate insulating film 16 is provided between the gate electrode layer 14 and the third portion P3 of the single crystal silicon layer 12. The gate insulating film 16 is provided between the gate electrode layer 14 and the p-type impurity region 12c of the single crystal silicon layer 12.

The gate insulating film 16 is an insulator. The gate insulating film 16 is, for example, silicon oxide.

The wiring layer 18 extends in the direction along the surface of the single crystal silicon substrate 10. The wiring layer 18 extends, for example, in the third direction. The wiring layer 18 corresponds to the bit line BL.

The wiring layer 18 is electrically connected to the first portion P1 of the single crystal silicon layer 12. The wiring layer 18 is electrically connected to the first n-type impurity region 12a of the single crystal silicon layer 12. The wiring layer 18 is in contact with the first portion P1 of the single crystal silicon layer 12. The wiring layer 18 is in contact with the first n-type impurity region 12a of the single crystal silicon layer 12.

The wiring layer 18 is a conductor. The wiring layer 18 is, for example, metal. The wiring layer 18 contains, for example, tungsten.

The storage node electrode 20 is electrically connected to the second portion P2 of the single crystal silicon layer 12. The storage node electrode 20 is electrically connected to the second n-type impurity region 12b of the single crystal silicon layer 12. The storage node electrode 20 is in contact with the second portion P2 of the single crystal silicon layer 12. The storage node electrode 20 is in contact with the second n-type impurity region 12b of the single crystal silicon layer 12.

The storage node electrode 20 is a conductor. The storage node electrode 20 is, for example, metal. The storage node electrode 20 is, for example, titanium nitride.

The capacitor insulating film 22 is provided between the storage node electrode 20 and the plate electrode 24. The capacitor insulating film 22 is in contact with the storage node electrode 20 and the plate electrode 24.

The capacitor insulating film 22 is an insulator. The capacitor insulating film 22 includes, for example, an insulator having a dielectric constant higher than that of silicon dioxide. The capacitor insulating film 22 includes, for example, a so-called High-k insulator.

The capacitor insulating film 22 contains, for example, zirconium oxide or aluminum oxide. The capacitor insulating film 22 is, for example, zirconium oxide, aluminum oxide, or a combination of zirconium oxide and aluminum oxide.

The plate electrode 24 is a conductor. The plate electrode 24 is, for example, metal. The plate electrode 24 is, for example, titanium nitride.

The contact electrode 26 extends in the normal direction of the surface of the single crystal silicon substrate 10. The contact electrode 26 extends in the first direction. The contact electrode 26 is in contact with, for example, the single crystal silicon substrate 10.

The contact electrode 26 is electrically connected to the first portion P1 of the single crystal silicon layer 12. The contact electrode 26 is in contact with the first portion P1 of the single crystal silicon layer 12. The first portion P1 of the single crystal silicon layer 12 includes the p-type impurity region 12c. The contact electrode 26 is electrically connected to the p-type impurity region 12c of the single crystal silicon layer 12. The contact electrode 26 is in contact with the p-type impurity region 12c of the single crystal silicon layer 12.

The contact electrode 26 has a function of fixing an electric potential of the p-type impurity region 12c of the single crystal silicon layer 12.

The contact electrode 26 is a conductor. The contact electrode 26 is, for example, a semiconductor or metal. In a case where the contact electrode 26 is a semiconductor, the contact electrode 26 is, for example, polycrystalline silicon doped at a high concentration. In a case where the contact electrode 26 is metal, the contact electrode 26 contains, for example, tungsten, titanium, tantalum, or titanium nitride.

The first interlayer insulating layer 28, the second interlayer insulating layer 30, and the third interlayer insulating layer 32 are insulators. The first interlayer insulating layer 28, the second interlayer insulating layer 30, and the third interlayer insulating layer 32 are, for example, silicon oxide or silicon nitride. The first interlayer insulating layer 28, the second interlayer insulating layer 30, and the third interlayer insulating layer 32 may include, for example, a semiconductor.

Next, an example of a method for manufacturing the semiconductor memory device of the first embodiment will be described.

The example of the method for manufacturing the semiconductor memory device of the first embodiment includes: forming a first film of a first material in a first direction of a single crystal silicon substrate; forming a second film of a second material different from the first material, in the first direction of the first film; forming a third film of a third material different from the second material, in the first direction of the second film; forming a first opening penetrating the third film, the second film, and the first film and reaching the single crystal silicon substrate; forming a first single crystal silicon layer in contact with the single crystal silicon substrate in the first opening; forming a second opening penetrating the third film and the second film; etching the second film from a side face of the second opening to form a first recess reaching the first single crystal silicon layer; forming a second single crystal silicon layer in contact with the first single crystal silicon layer in the first recess; forming a wiring layer in contact with a first portion of the second single crystal silicon layer; forming a capacitor in contact with a second portion of the second single crystal silicon layer; and forming a gate electrode layer facing a third portion of the second single crystal silicon layer between the first portion and the second portion.

In addition, in the example of the method for manufacturing the semiconductor memory device of the first embodiment, the second material is amorphous silicon or polycrystalline silicon, an oxide film is formed on a surface of the second film exposed on a side face of the first opening after the forming the first opening and before the forming the first single crystal silicon layer, and the oxide film is removed after the etching the second film to form the first recess.

In addition, in the example of the method for manufacturing the semiconductor memory device of the first embodiment, a fourth film of a fourth material different from the second material and the third material, is formed between the second film and the third film, the first single crystal silicon layer in the first opening is removed after the forming the second single crystal silicon layer, and the fourth film is etched from a side face of the first opening to form a second recess after the removing the first single crystal silicon layer. The wiring layer is formed in the second recess.

Hereinafter, a case where the first material is silicon oxide, the second material is amorphous silicon, the third material is silicon oxide, and the fourth material is silicon nitride will be described as an example. In this case, the first material and the third material are the same material.

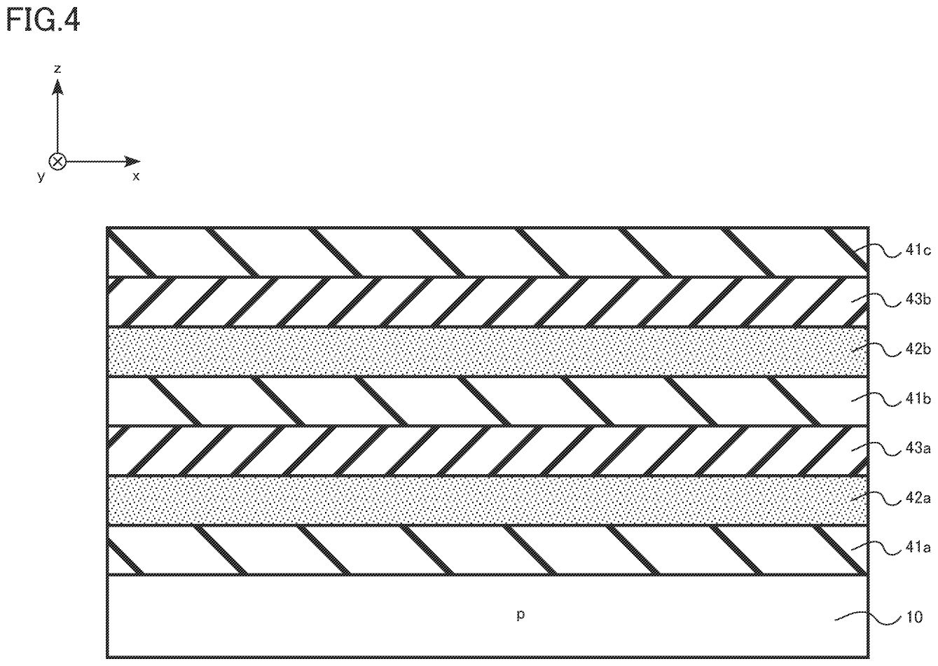

FIGS. 4, 5, 6, 7, 8, 9, 10, 11, 12, 13, 14, 15, 16, 17, 18, 19, 20, 21, 22, and 23 are schematic cross-sectional views illustrating the method for manufacturing the semiconductor memory device of the first embodiment.

FIGS. 4 to 23 are cross sections corresponding to FIG. 2. FIGS. 4 to 23 are xz cross sections.

First, a first silicon oxide film 41a, a first amorphous silicon film 42a, a first silicon nitride film 43a, a second silicon oxide film 41b, a second amorphous silicon film 42b, a second silicon nitride film 43b, and a third silicon oxide film 41c are formed in this order in the first direction of the single crystal silicon substrate 10 (FIG. 4).

The first silicon oxide film 41a is formed on the surface of the single crystal silicon substrate 10. The first amorphous silicon film 42a is formed on the first silicon oxide film 41a. The first silicon nitride film 43a is formed on the first amorphous silicon film 42a. The second silicon oxide film 41b is formed on the first silicon nitride film 43a. The second amorphous silicon film 42b is formed on the second silicon oxide film 41b. The second silicon nitride film 43b is formed on the second amorphous silicon film 42b. The third silicon oxide film 41c is formed on the second silicon nitride film 43b.

The first silicon oxide film 41a, the first amorphous silicon film 42a, the first silicon nitride film 43a, the second silicon oxide film 41b, the second amorphous silicon film 42b, the second silicon nitride film 43b, and the third silicon oxide film 41c are formed by, for example, a chemical vapor deposition method (CVD method).

The first silicon oxide film 41a is an example of the first film. The first amorphous silicon film 42a is an example of the second film. The second silicon oxide film 41b is an example of the third film. The first silicon nitride film 43a is an example of the fourth film.

A part of each of the first silicon oxide film 41a, the second silicon oxide film 41b, and the third silicon oxide film 41c finally serves as the first interlayer insulating layer 28. In addition, a part of each of the first silicon nitride film 43a and the second silicon nitride film 43b finally serves as the second interlayer insulating layer 30.

Note that each of the first amorphous silicon film 42a and the second amorphous silicon film 42b is patterned into a plurality of regions so as to be divided in the third direction by a method (not illustrated).

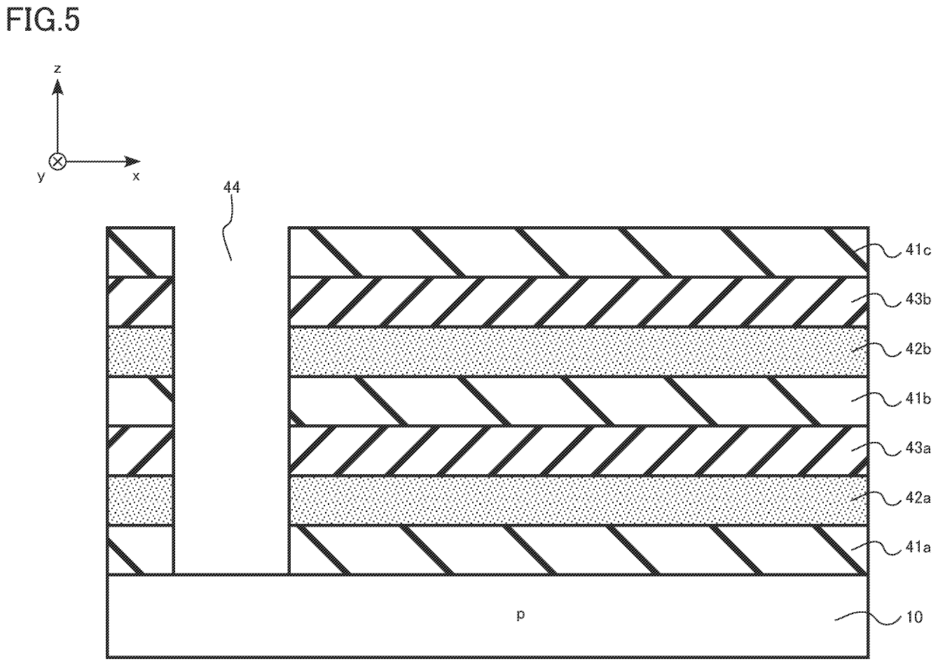

Next, a first opening 44 that penetrates the third silicon oxide film 41c, the second silicon nitride film 43b, the second amorphous silicon film 42b, the second silicon oxide film 41b, the first silicon nitride film 43a, the first amorphous silicon film 42a, and the first silicon oxide film 41a and reaches the single crystal silicon substrate 10 is formed (FIG. 5).

The first opening 44 is formed by, for example, a lithography method and a reactive ion etching method (RIE method).

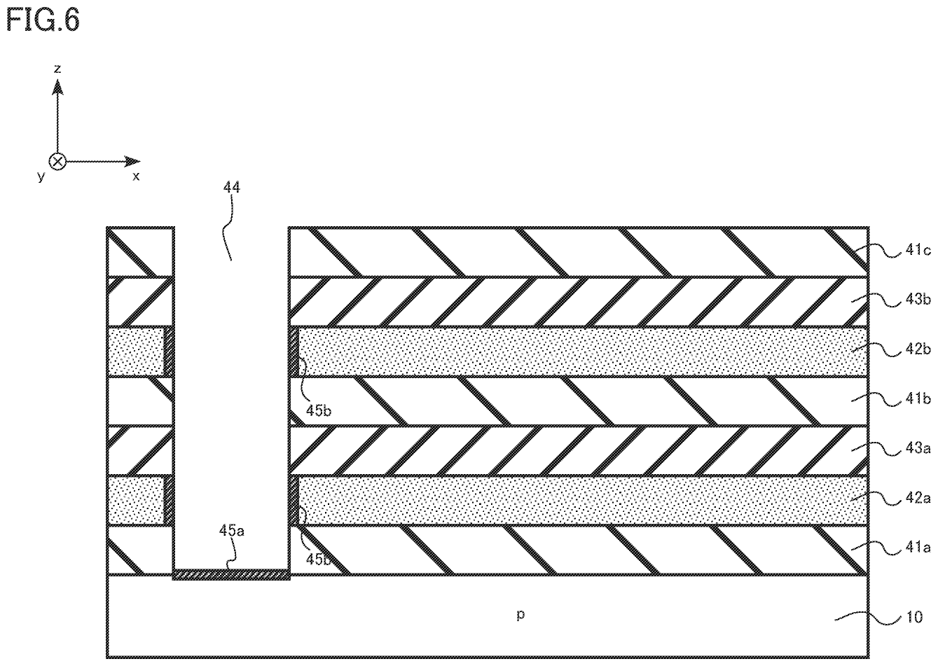

Next, the first oxide film 45a is formed on the surface of the single crystal silicon substrate 10 exposed at a bottom of the first opening 44. In addition, a second oxide film 45b is formed on each of a surface of the first amorphous silicon film 42a exposed on a side face of the first opening 44 and a surface of the second amorphous silicon film 42b exposed on the side face of the first opening 44 (FIG. 6). The second oxide film 45b is an example of the oxide film.

The first oxide film 45a and the second oxide film 45b are formed by thermal oxidation, for example. The oxide films including the first oxide film 45a at the bottom of the opening and the second oxide film 45b formed on the amorphous silicon side are simultaneously formed, but the second oxide film 45b formed on the amorphous silicon side is formed to be relatively thicker.

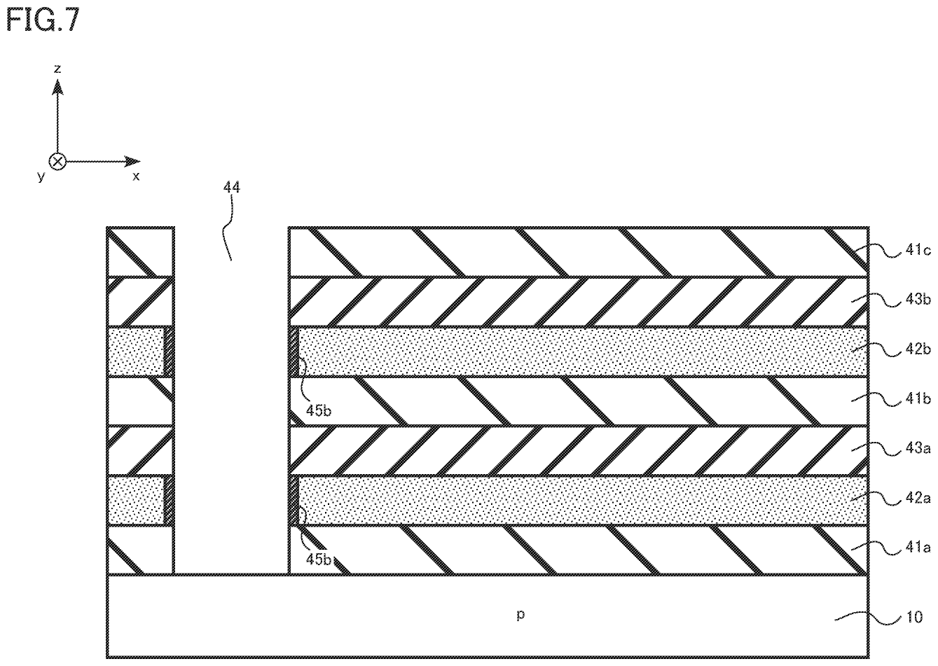

Next, the first oxide film 45a at the bottom of the first opening 44 is removed (FIG. 7). The first oxide film 45a is removed by, for example, a dry etching method or a wet etching method. The second oxide film 45b remains.

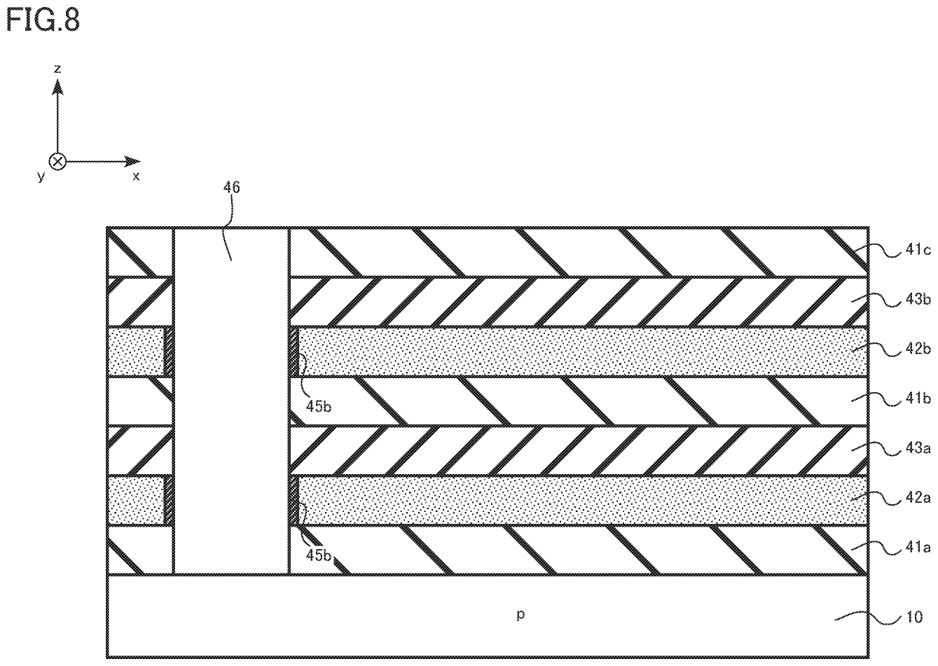

Next, a first single crystal silicon layer 46 in contact with the single crystal silicon substrate 10 is formed in the first opening 44 (FIG. 8). The first single crystal silicon layer 46 is formed using the single crystal silicon substrate 10 as a seed crystal. The first single crystal silicon layer 46 is, for example, non-doped single crystal silicon containing no conductive impurity.

The first single crystal silicon layer 46 is formed using, for example, a solid phase epitaxial growth method. In a case where the solid phase epitaxial growth method is used, for example, the first opening 44 is filled with an amorphous silicon layer. Thereafter, heat treatment is performed to form single crystal silicon grown from the substrate.

As another method, the first single crystal silicon layer 46 may be formed using, for example, a vapor phase epitaxial growth method.

Furthermore, as still another method, the first single crystal silicon layer 46 may be formed using, for example, a vapor-liquid-solid method (VLS method). In a case where the VLS method is used, metal or a metal compound is formed as a catalyst, and single crystal silicon is formed by vapor phase epitaxial growth using the catalyst as a nucleus. The catalyst is, for example, gold (Au), indium (In), tin (Sb), or indium tin oxide. The catalyst is grown on the bottom of the first opening 44 in FIG. 7, and is formed using, for example, an atomic layer deposition method (ALD method), a CVD method, or a sputtering method. The VLS method enables fast seed crystal growth.

Note that at least a part of the first single crystal silicon layer 46 is a single crystal. In the first single crystal silicon layer 46, for example, at least a portion in contact with the second oxide film 45b is a single crystal. The first single crystal silicon layer 46 may partially include, for example, crystal grains or crystal defects.

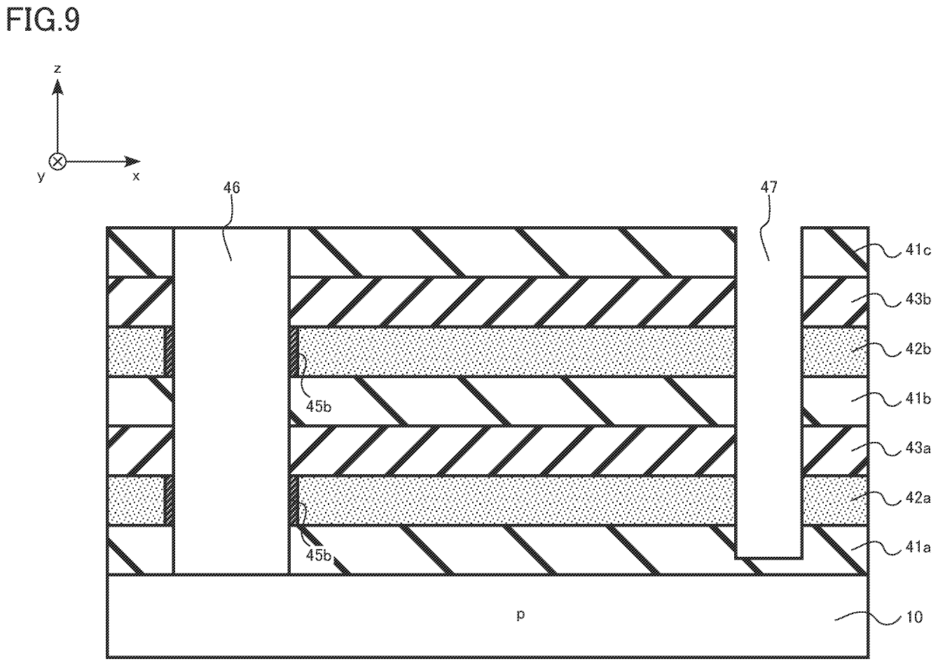

Next, a second opening 47 that penetrates the third silicon oxide film 41c, the second silicon nitride film 43b, the second amorphous silicon film 42b, the second silicon oxide film 41b, the first silicon nitride film 43a, and the first amorphous silicon film 42a is formed (FIG. 9). The surface of the single crystal silicon substrate 10 is not exposed at a bottom of the second opening 47.

The second opening 47 is formed by, for example, a lithography method and an RIE method.

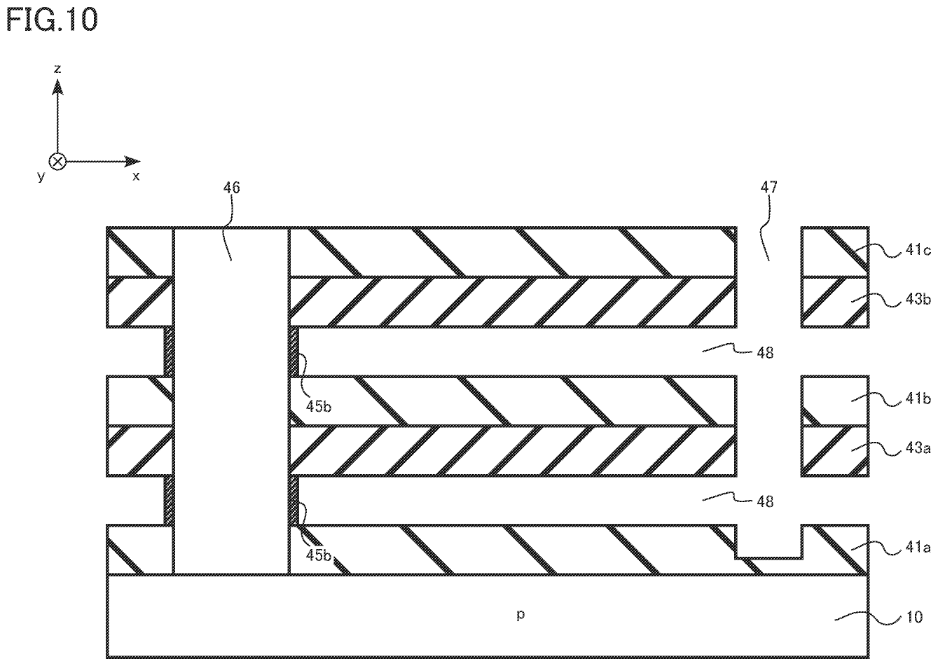

Next, the first amorphous silicon film 42a and the second amorphous silicon film 42b are selectively etched from a side face of the second opening 47 to form first recesses 48 (FIG. 10). The second oxide films 45b are exposed at depths of the first recesses 48, respectively. The first amorphous silicon film 42a and the second amorphous silicon film 42b are etched using, for example, a dry etching method or a wet etching method.

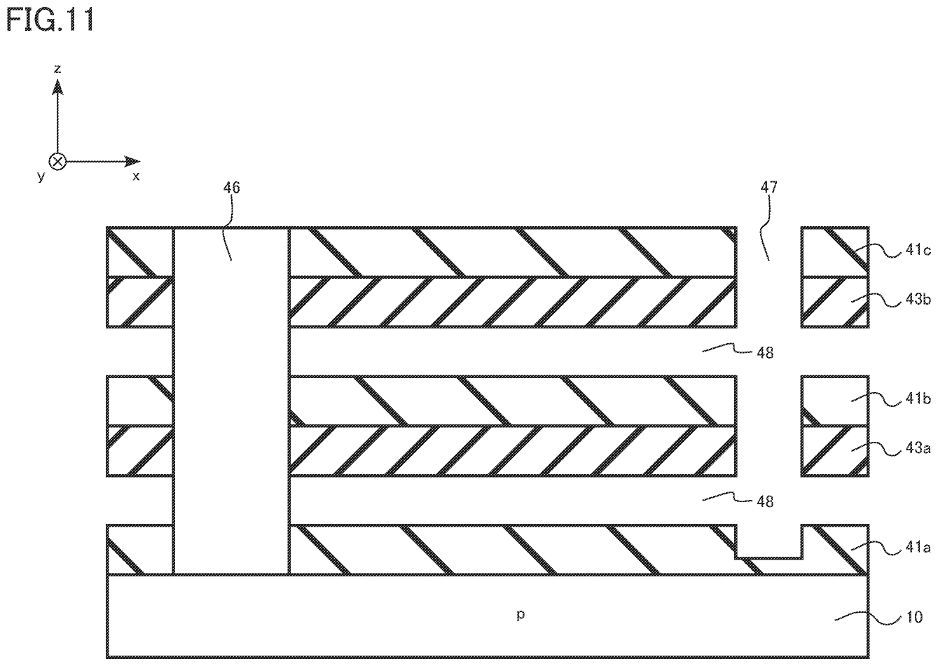

Next, the second oxide films 45b are removed (FIG. 11). The second oxide films 45b are removed using, for example, a wet etching method. The first single crystal silicon layer 46 is exposed at depths of the first recesses 48.

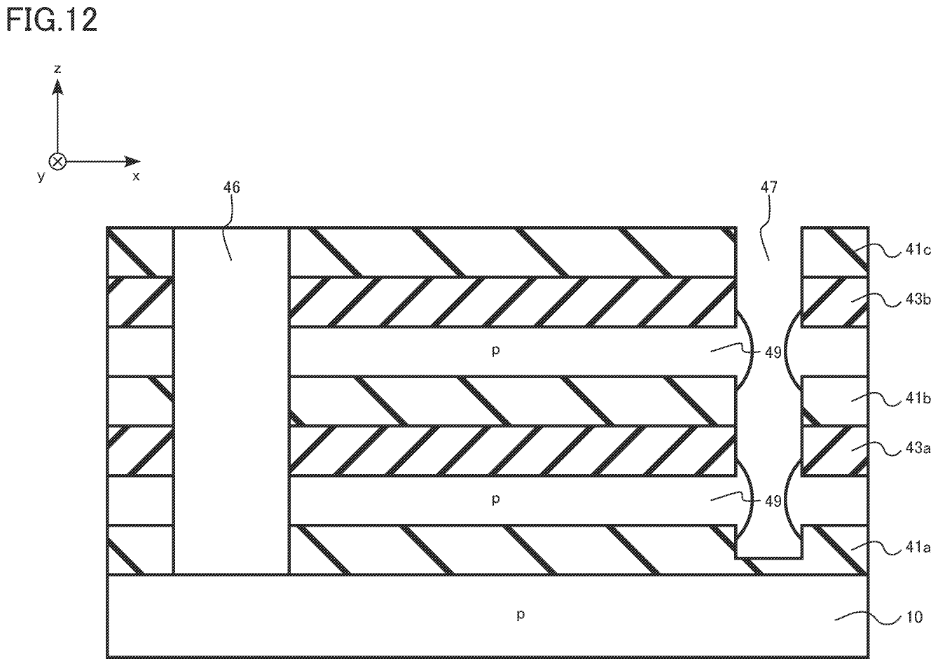

Next, a second single crystal silicon layer 49 in contact with the first single crystal silicon layer 46 is formed in each of the first recesses 48 (FIG. 12). The second single crystal silicon layer 49 is formed using the first single crystal silicon layer 46 as a seed crystal. The second single crystal silicon layer 49 is, for example, p-type single crystal silicon containing p-type impurities. A part of the second single crystal silicon layer 49 finally serves as the single crystal silicon layer 12 illustrated in FIGS. 2 and 3.

The second single crystal silicon layer 49 is formed using, for example, a vapor phase epitaxial growth method.

The second single crystal silicon layer 49 is formed using, for example, a VLS method. In a case where the VLS method is used, metal or a metal compound is formed as a catalyst, and single crystal silicon is formed using the catalyst as a nucleus. The catalyst is, for example, gold (Au), indium (In), tin (Sb), or indium tin oxide. Here, it is necessary to form the catalyst on an exposed surface of the first single crystal silicon layer 46 on sidewalls at the depth of the first recess 48, and thus the catalyst is selectively attached to the surface side of the exposed seed crystal silicon using, for example, an ALD method, a CVD method, or the like.

Note that at least a part of the second single crystal silicon layer 49 is a single crystal. In the second single crystal silicon layer 49, for example, at least a portion where the p-type impurity region 12c is to be finally formed is a single crystal. The second single crystal silicon layer 49 may partially include, for example, crystal grains or crystal defects.

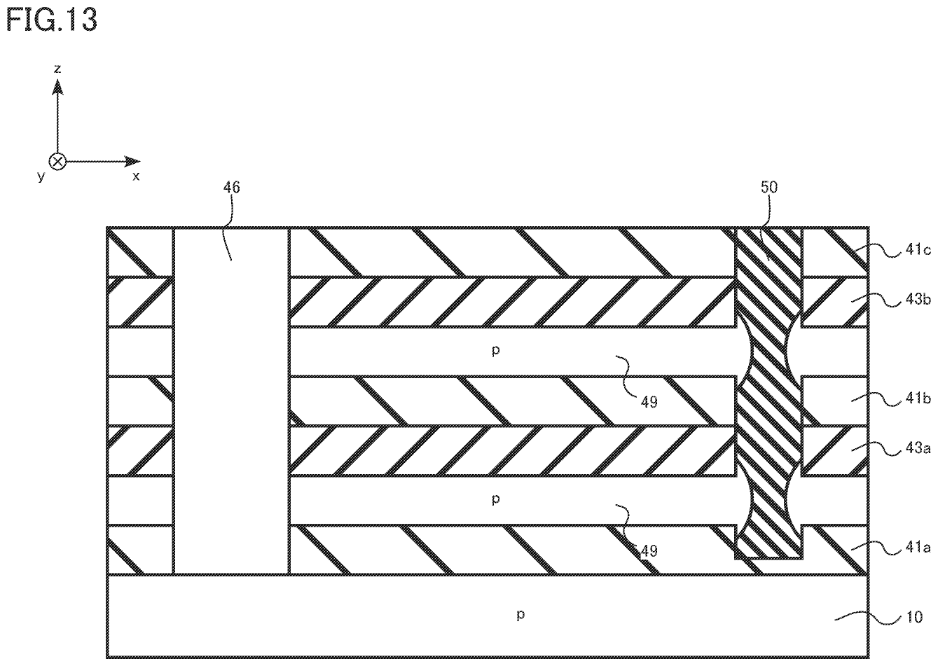

Next, the second opening 47 is filled with a silicon oxide film 50 (FIG. 13).

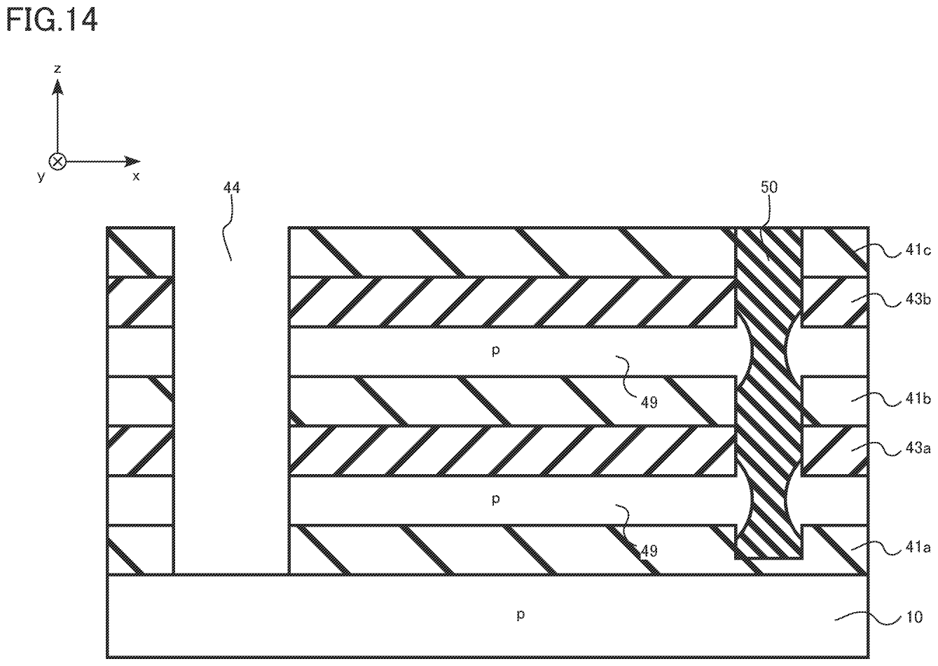

Next, the first single crystal silicon layer 46 in the first opening 44 is removed (FIG. 14). The first single crystal silicon layer 46 is removed by, for example, a dry etching method or a wet etching method.

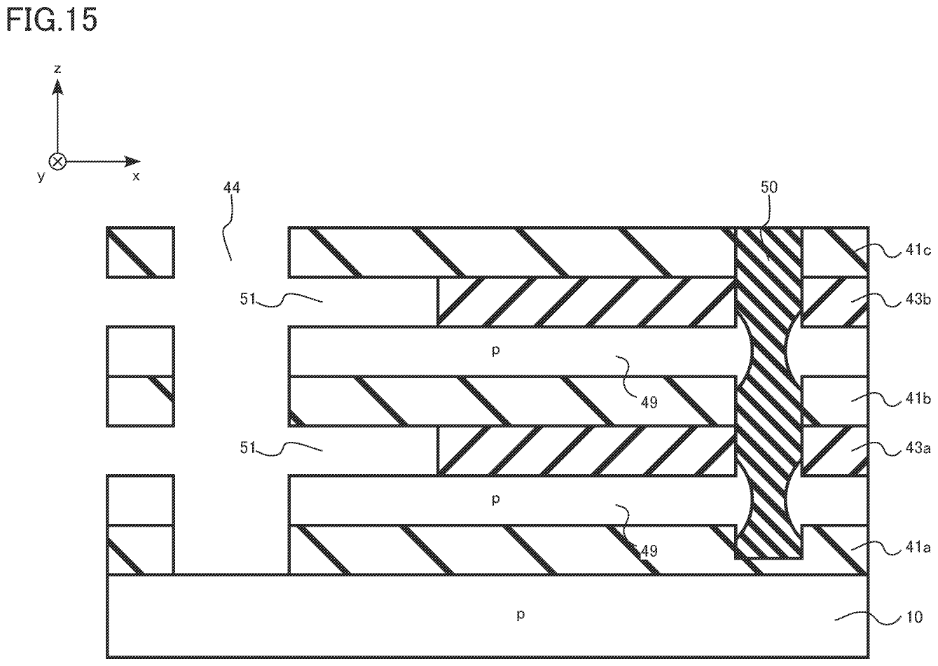

Next, a part of the first silicon nitride film 43a and a part of the second silicon nitride film 43b are etched from the side face of the first opening 44 to form second recesses 51 (FIG. 15). The first silicon nitride film 43a and the second silicon nitride film 43b are removed by, for example, a wet etching method.

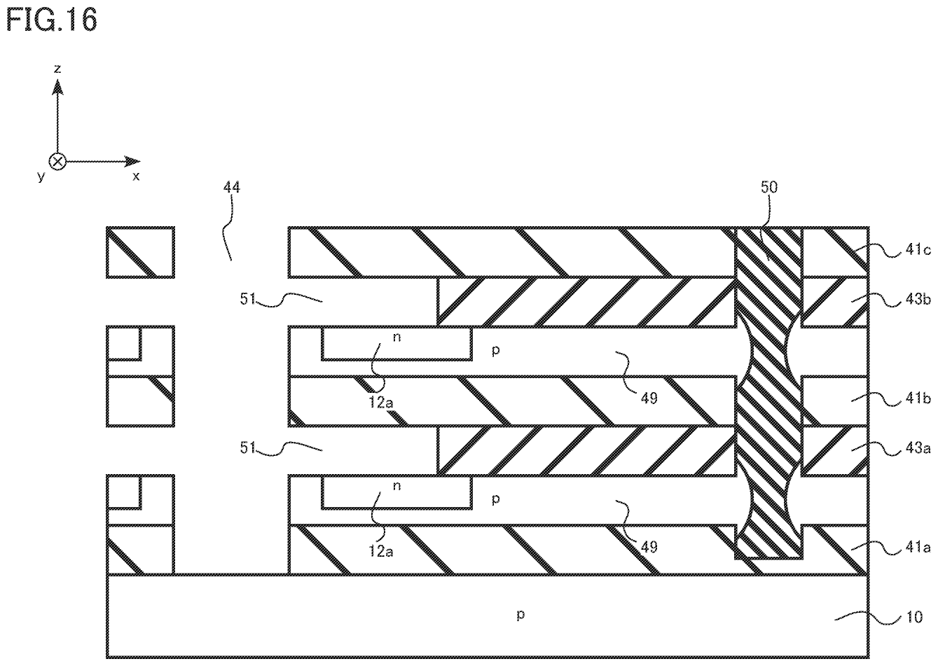

Next, the first n-type impurity region 12a is formed in the second single crystal silicon layer 49 (FIG. 16). The first n-type impurity region 12a is formed using, for example, a vapor phase diffusion method.

For example, a mask material (not illustrated) that covers corners of the second single crystal silicon layer 49 or the surface of the single crystal silicon substrate 10 at the bottom of the first opening 44 is used to form the first n-type impurity region 12a.

The n-type impurities introduced into the first n-type impurity region 12a are activated by, for example, heat treatment at a high temperature for a short time.

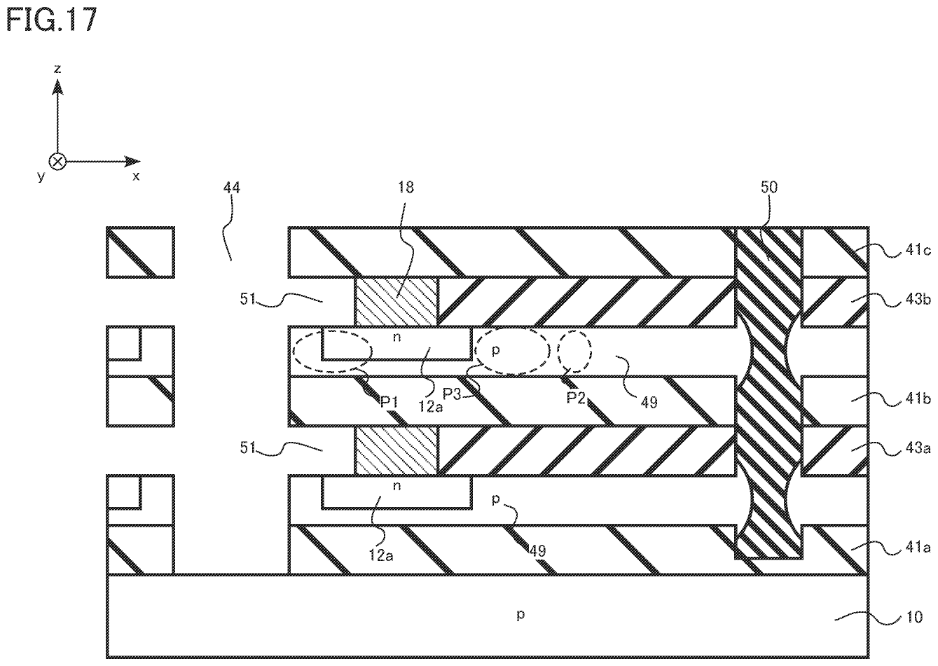

Next, the wiring layer 18 is formed in the second recess 51 (FIG. 17). The wiring layer 18 is in contact with the first portion P1 of the second single crystal silicon layer 49. The wiring layer 18 is in contact with the first n-type impurity region 12a. The wiring layer 18 is formed in the second recess 51 using, for example, a CVD method and a dry etching method.

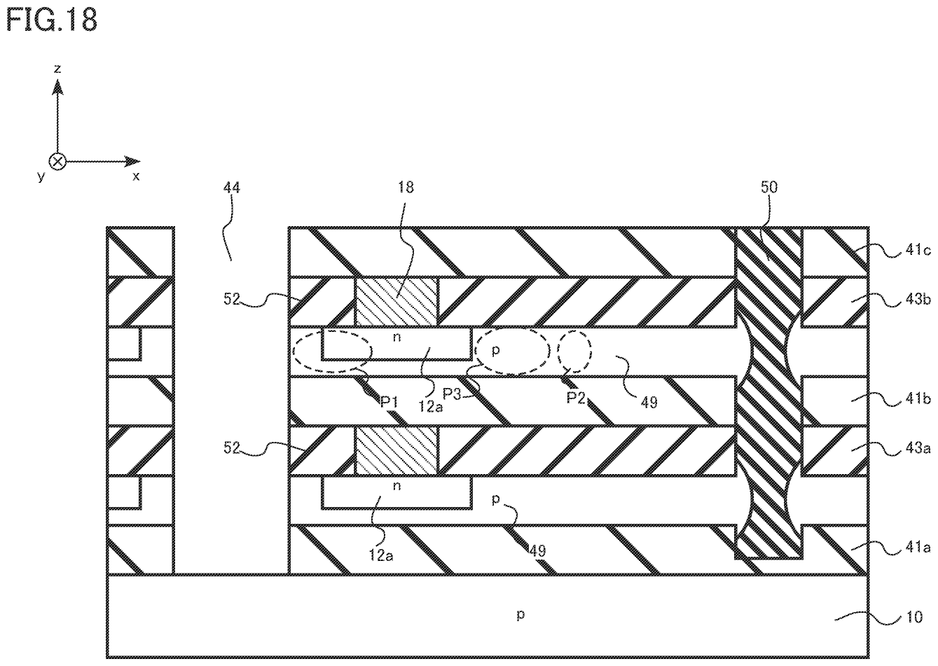

Next, the second recess 51 is filled with a silicon oxide film 52 (FIG. 18). The second recess 51 is filled with the silicon oxide film 52 using, for example, a CVD method and a dry etching method.

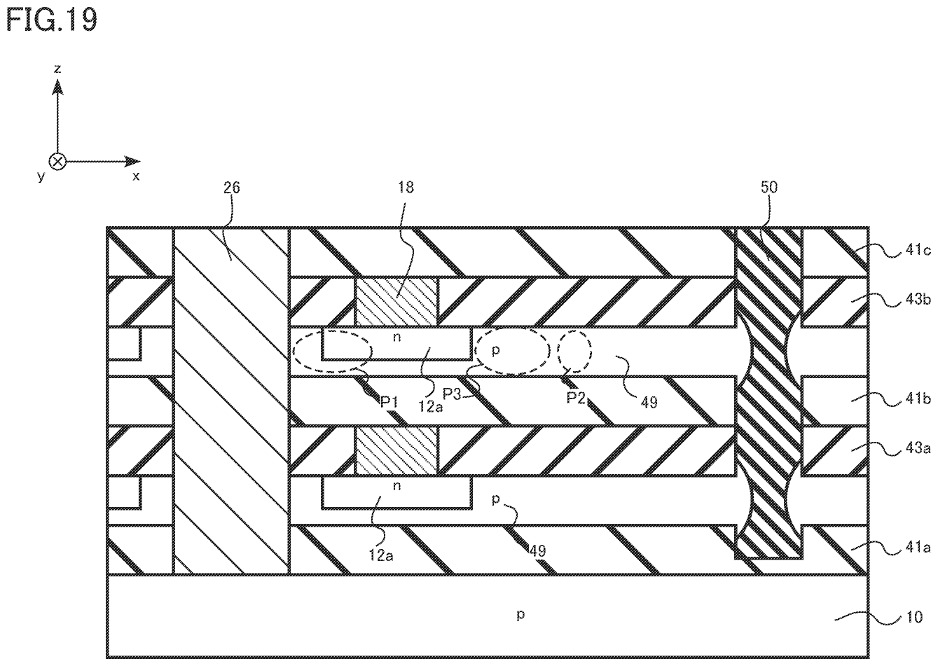

Next, the contact electrode 26 is formed in the first opening 44 (FIG. 19). The contact electrode 26 is formed by, for example, a CVD method.

Thereafter, grooves sandwiching the second single crystal silicon layer 49 in the third direction and extending in the first direction are formed by a method (not illustrated). The gate insulating film 16 and the gate electrode layer 14 extending in the first direction are formed using the formed groove. The gate electrode layer 14 is formed so as to be facing the third portion P3 of the second single crystal silicon layer 49.

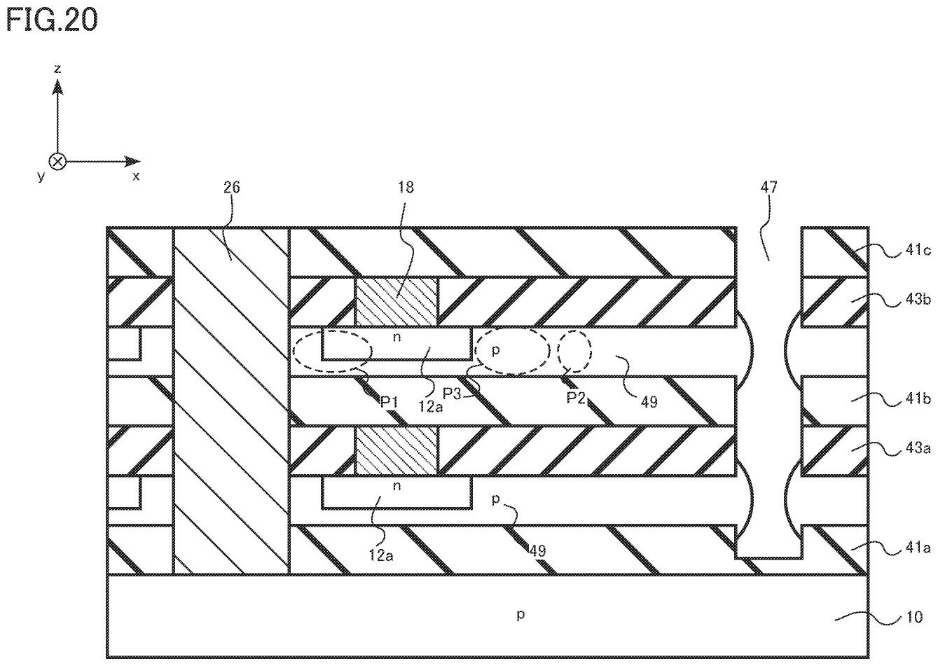

Next, the silicon oxide film 50 in the second opening 47 is removed (FIG. 20). The silicon oxide film 50 is removed by, for example, a wet etching method.

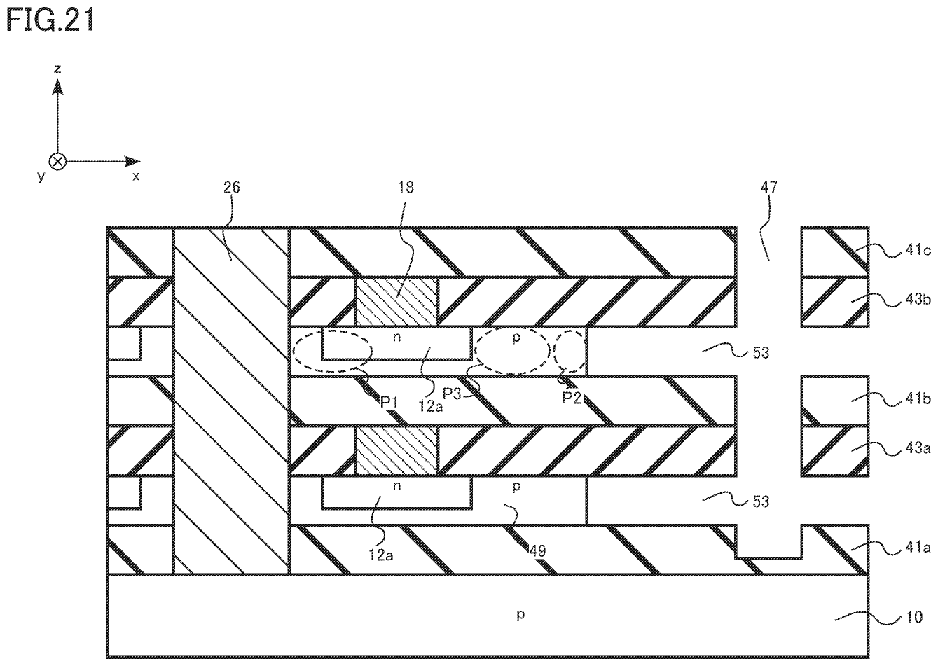

Next, the second single crystal silicon layers 49 are selectively etched from the side face of the second opening 47 to form third recesses 53 (FIG. 21). The second single crystal silicon layers 49 are etched using, for example, a dry etching method or a wet etching method.

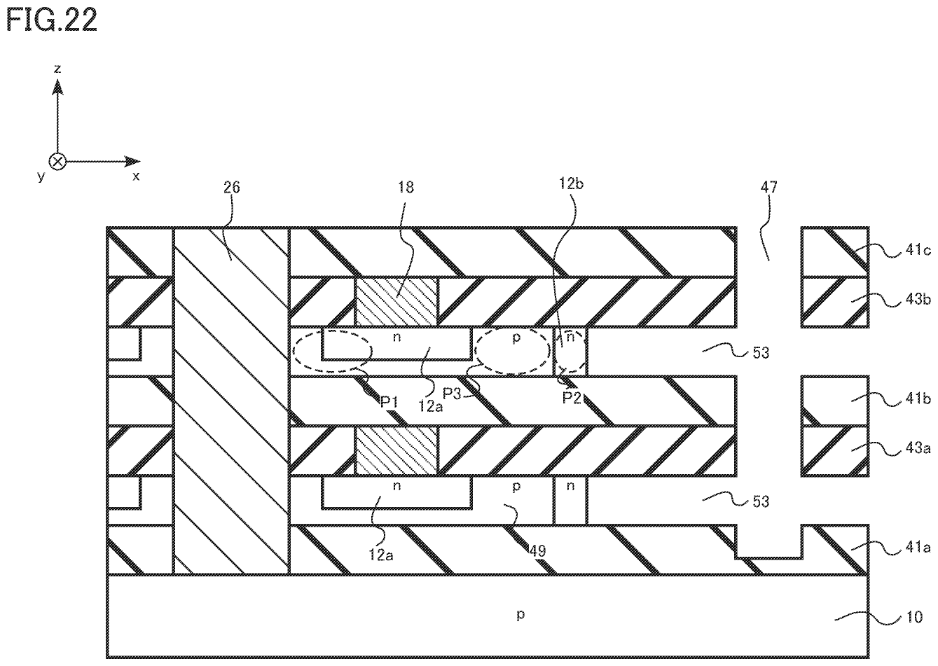

Next, the second n-type impurity region 12b is formed in the second portion P2 of the second single crystal silicon layer 49 (FIG. 22). The second n-type impurity region 12b is formed using, for example, a vapor phase diffusion method.

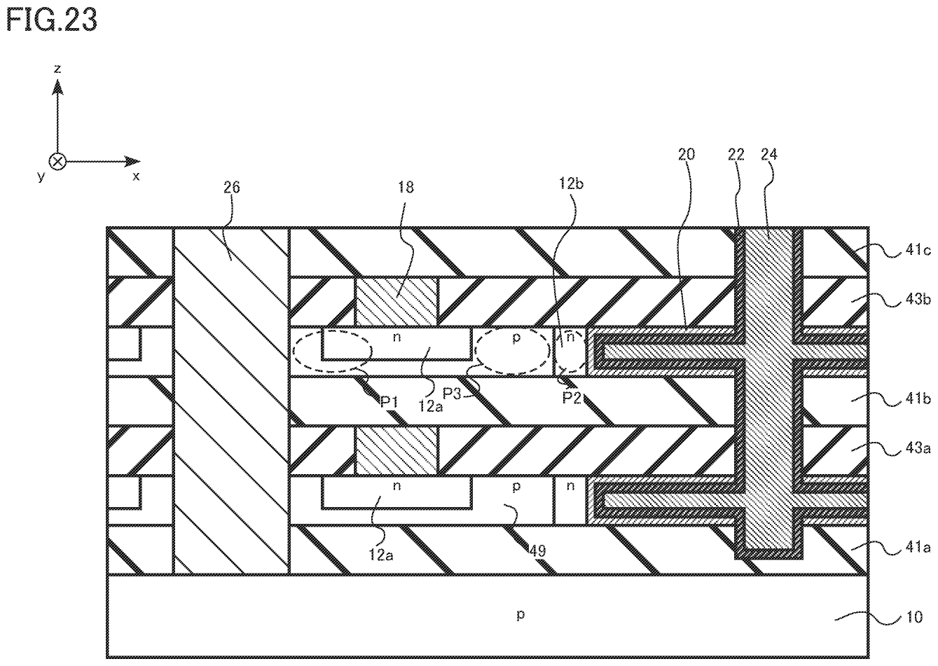

Next, the storage node electrode 20, the capacitor insulating film 22, and the plate electrode 24 are formed in each of the third recesses 53 (FIG. 23). The storage node electrode 20 is in contact with the second portion P2 of the second single crystal silicon layer 49. The capacitor CA including the storage node electrode 20, the capacitor insulating film 22, and the plate electrode 24 is in contact with the second portion P2 of the second single crystal silicon layer 49. The storage node electrode 20, the capacitor insulating film 22, and the plate electrode 24 are formed using, for example, a CVD method.

The memory cell array 101 of the DRAM of the first embodiment is formed by the above manufacturing method.

Next, a function and an effect of the semiconductor memory device of the first embodiment will be described.

In the DRAM of the first embodiment, the memory cells MC are three-dimensionally disposed. Therefore, high integration can be realized.

In the DRAM of the first embodiment, the crystal defect density of the first portion P1 of the single crystal silicon layer 12 is higher than the crystal defect density of the third portion P3. When the single crystal silicon layer 12 is manufactured by an epitaxial growth method, defects at the initial stage of growth of the single crystal silicon remain in a portion closer to the first single crystal silicon layer 46 which serves as the seed crystal, so that the crystal defect density increases. Since the first portion P1 is a portion closer to the first single crystal silicon layer 46 which serves as the seed crystal than the third portion P3, the crystal defect density increases.

The first portion P1 having a higher crystal defect density functions as, for example, a gettering site of metal contamination in the single crystal silicon layer 12. Therefore, for example, junction leakage of the DRAM of the first embodiment is reduced, and charge retention characteristics are improved. The first portion P1 is disposed on the opposite side of the second portion P2 on the storage node electrode 20 side where charge is retained. Therefore, the charge retention characteristics of the DRAM are not affected even if there is an increase in junction leakage due to the crystal defects of the first portion P1.

For example, when a VLS method using metal or a metal compound as a catalyst is used for the formation of the first single crystal silicon layer 46 or the formation of the second single crystal silicon layer 49, there is a possibility that the metal contamination in the single crystal silicon layer 12 increases. Therefore, particularly when the single crystal silicon layer 12 is manufactured using the VLS method, the effect of improving the charge retention characteristics by including the first portion P1 is remarkably exhibited.

For example, metal gettered in the first portion P1 can be silicided and fixed by a high-temperature process. In addition, for example, it is also possible to remove metal by etching a part of the first portion P1 where metal is gettered at a high concentration. In addition, when a film for forming the contact electrode 26 is deposited, the metal gettered in the first portion P1 can be taken into the film to stabilize the metal.

From the viewpoint of improving the charge retention characteristics, the crystal defect density of the first portion P1 is preferably equal to or more than ten times the crystal defect density of the third portion P3.

In addition, in the first portion P1 having a higher crystal defect density, diffusion of impurities in the single crystal silicon is promoted. Therefore, for example, a heat treatment time for forming the first n-type impurity region 12a can be shortened, or a heat treatment temperature can be reduced.

In the method for manufacturing the DRAM of the first embodiment, a plurality of the single crystal silicon layers 12 stacked in the first direction are simultaneously formed using the first single crystal silicon layer 46 as the seed crystal. Therefore, the uniformity of the plurality of single crystal silicon layers 12 stacked in the first direction is improved. In addition, a manufacturing time for forming the single crystal silicon layer 12 is shortened.

In addition, in the method for manufacturing the DRAM of the first embodiment, the formation of the first single crystal silicon layer 46 and the formation of the second single crystal silicon layer 49 are performed in different steps. As compared with a case where the formation of the first single crystal silicon layer 46 and the formation of the second single crystal silicon layer 49 are performed in the same step, the uniformity of growth in the second direction of the plurality of second single crystal silicon layers 49 stacked in the first direction is improved.

Therefore, according to the method for manufacturing the DRAM of the first embodiment, the DRAM having the three-dimensional structure with stable characteristics can be manufactured in a short manufacturing time.

From the viewpoint of shortening the manufacturing time, it is preferable to use a VLS method having a high growth rate of single crystal silicon for the formation of the first single crystal silicon layer 46 or the second single crystal silicon layer 49.

Note that a method for forming the first single crystal silicon layer 46 and a method for forming the second single crystal silicon layer 49 may be the same process method or different process methods.

### Modified Example

A method for manufacturing a semiconductor memory device of a modified example of the first embodiment is different from the method for manufacturing the semiconductor memory device of the first embodiment in that the second material is silicon nitride and the fourth material is amorphous silicon.

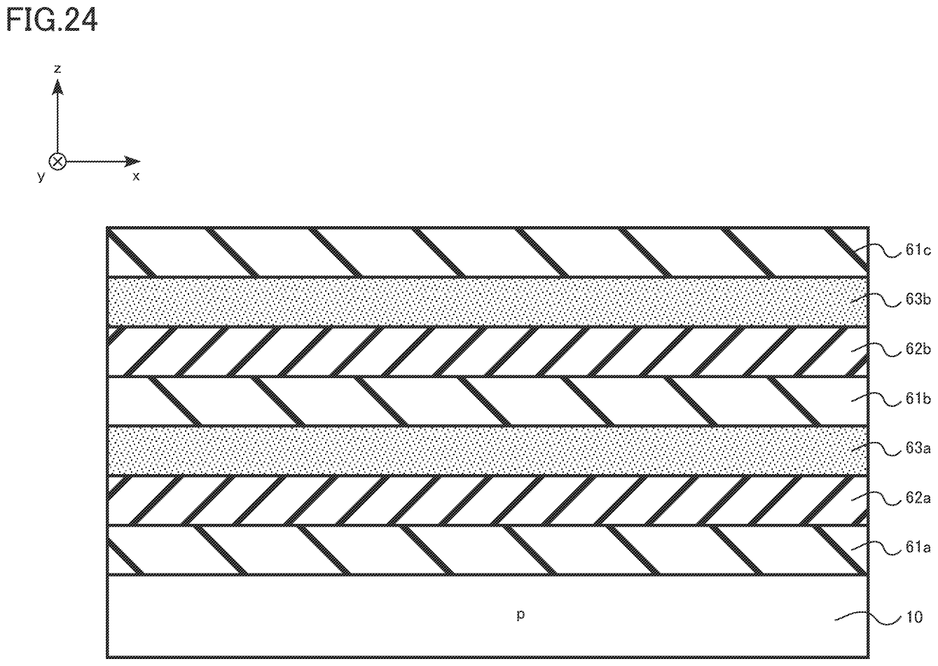

FIGS. 24, 25, 26, 27, 28, and 29 are schematic cross-sectional views illustrating the method for manufacturing the semiconductor memory device according to the modified example of the first embodiment.

FIGS. 24 to 29 are cross sections corresponding to FIG. 2. FIGS. 24 to 29 are xz cross sections.

First, a first silicon oxide film 61a, a first silicon nitride film 62a, a first amorphous silicon film 63a, a second silicon oxide film 61b, a second silicon nitride film 62b, a second amorphous silicon film 63b, and a third silicon oxide film 61c are formed in this order in the first direction of the single crystal silicon substrate 10 (FIG. 24).

The first silicon oxide film 61a is formed on the surface of the single crystal silicon substrate 10. The first silicon nitride film 62a is formed on the first silicon oxide film 61a. The first amorphous silicon film 63a is formed on the first silicon nitride film 62a. The second silicon oxide film 61b is formed on the first amorphous silicon film 63a. The second silicon nitride film 62b is formed on the second silicon oxide film 61b. The second amorphous silicon film 63b is formed on the second silicon nitride film 62b. The third silicon oxide film 61c is formed on the second amorphous silicon film 63b.

The first silicon oxide film 61a, the first silicon nitride film 62a, the first amorphous silicon film 63a, the second silicon oxide film 61b, the second silicon nitride film 62b, the second amorphous silicon film 63b, and the third silicon oxide film 61c are formed by, for example, a CVD method.

The first silicon oxide film 61a is an example of the first film. The first silicon nitride film 62a is an example of the second film. The second silicon oxide film 61b is an example of the third film. The first amorphous silicon film 63a is an example of the fourth film.

A part of each of the first silicon oxide film 61a, the second silicon oxide film 61b, and the third silicon oxide film 61c finally serves as the first interlayer insulating layer 28. In addition, a part of each of the first amorphous silicon film 63a and the second amorphous silicon film 63b finally serves as the second interlayer insulating layer 30. A part of each of the first amorphous silicon film 63a and the second amorphous silicon film 63b finally serves as the second interlayer insulating layer 30, for example, in an at least partially nitrided state.

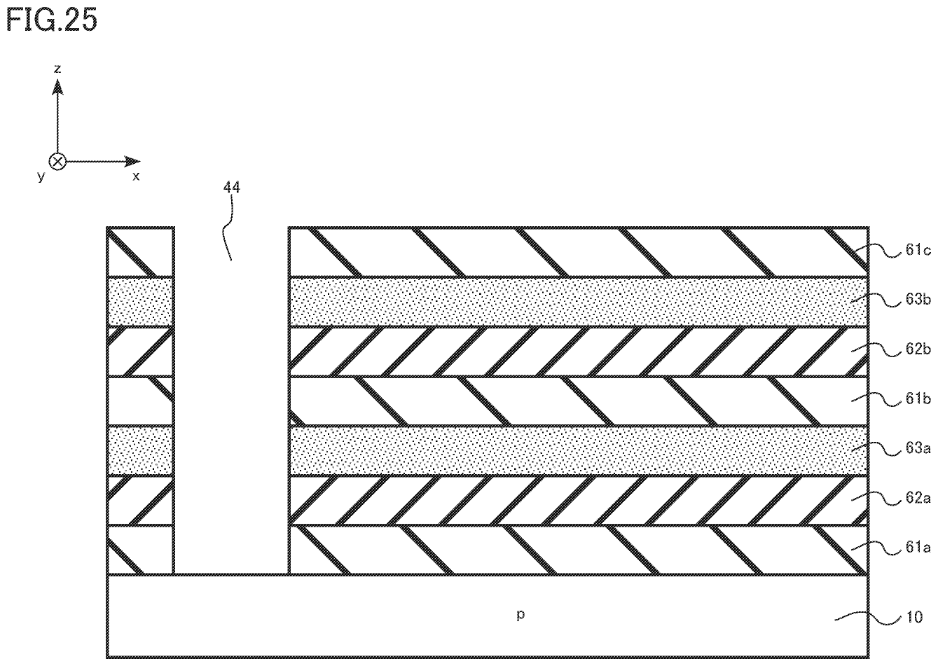

Next, the first opening 44 that penetrates the third silicon oxide film 61c, the second amorphous silicon film 63b, the second silicon nitride film 62b, the second silicon oxide film 61b, the first amorphous silicon film 63a, the first silicon nitride film 62a, and the first silicon oxide film 61a and reaches the single crystal silicon substrate 10 is formed (FIG. 25).

The first opening 44 is formed by, for example, a lithography method and a reactive ion etching method (RIE method).

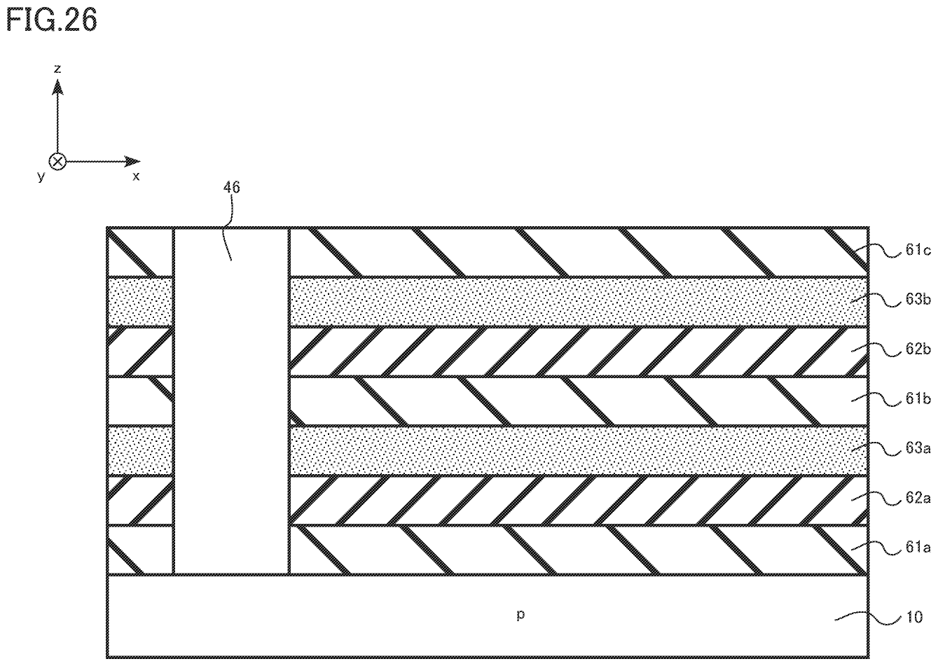

Next, the first single crystal silicon layer 46 in contact with the single crystal silicon substrate 10 is formed in the first opening 44 (FIG. 26). The first single crystal silicon layer 46 is formed using the single crystal silicon substrate 10 as a seed crystal. The first single crystal silicon layer 46 is, for example, non-doped single crystal silicon containing no conductive impurity.

The first single crystal silicon layer 46 is formed using, for example, a vapor phase epitaxial growth method.

The first single crystal silicon layer 46 may be formed using, for example, a VLS method. In a case where the VLS method is used, single crystal silicon is formed using metal or a metal compound as a catalyst. The catalyst is, for example, gold (Au), indium (In), tin (Sb), or indium tin oxide. The catalyst is formed using, for example, an ALD method, a CVD method, or a sputtering method.

The first single crystal silicon layer 46 is formed using, for example, a solid phase epitaxial growth method. In a case where the solid phase epitaxial growth method is used, for example, the first opening 44 is filled with an amorphous silicon layer. Thereafter, heat treatment is performed to form the single crystal silicon.

Note that at least a part of the first single crystal silicon layer 46 is a single crystal. In the first single crystal silicon layer 46, for example, at least a portion in contact with the first silicon nitride film 62a and a portion in contact with the second silicon nitride film 62b are single crystals. The first single crystal silicon layer 46 may partially include, for example, crystal grains or crystal defects.

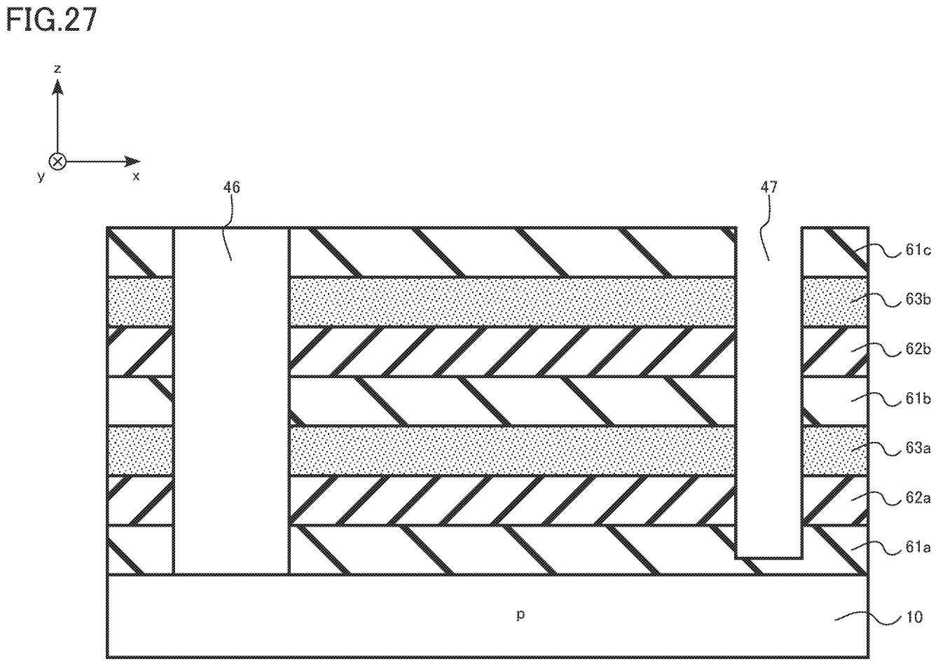

Next, the second opening 47 that penetrates the third silicon oxide film 61c, the second amorphous silicon film 63b, the second silicon nitride film 62b, the second silicon oxide film 61b, the first amorphous silicon film 63a, and the first silicon nitride film 62a is formed (FIG. 27). The surface of the single crystal silicon substrate 10 is not exposed at a bottom of the second opening 47.

The second opening 47 is formed by, for example, a lithography method and an RIE method.

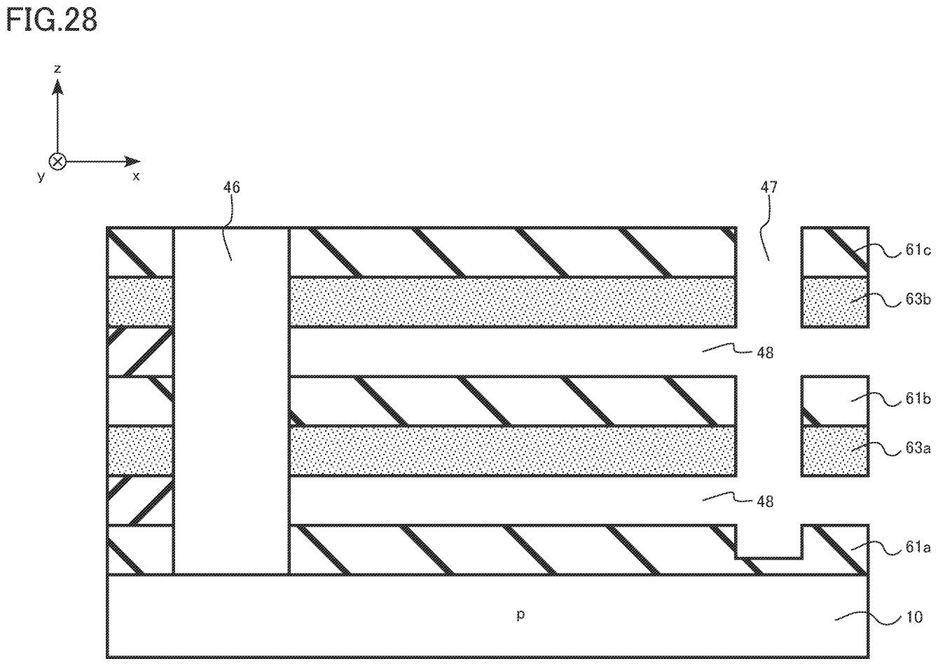

Next, the first silicon nitride film 62a and the second silicon nitride film 62b are selectively etched from the side face of the second opening 47 to form the first recesses 48 (FIG. 28). The first single crystal silicon layer 46 is exposed at the depths of the first recesses 48. The first silicon nitride film 62a and the second silicon nitride film 62b are etched using, for example, a dry etching method or a wet etching method.

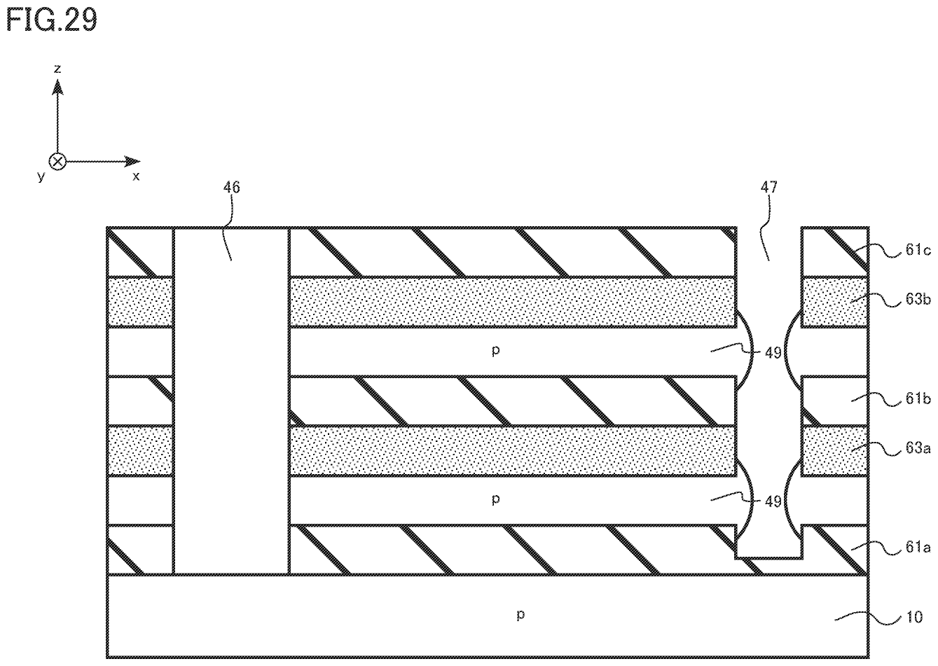

Next, the second single crystal silicon layer 49 in contact with the first single crystal silicon layer 46 is formed in each of the first recesses 48 (FIG. 29). The second single crystal silicon layer 49 is formed using the first single crystal silicon layer 46 as a seed crystal. The second single crystal silicon layer 49 is, for example, p-type single crystal silicon containing p-type impurities. A part of the second single crystal silicon layer 49 finally serves as the single crystal silicon layer 12.

The second single crystal silicon layer 49 is formed using, for example, a vapor phase epitaxial growth method.

The second single crystal silicon layer 49 is formed using, for example, a VLS method. In a case where the VLS method is used, single crystal silicon is formed using metal or a metal compound as a catalyst. The catalyst is, for example, gold (Au), indium (In), tin (Sb), or indium tin oxide. The catalyst is formed using, for example, an ALD method, a CVD method, or a sputtering method.

Note that at least a part of the second single crystal silicon layer 49 is a single crystal. In the second single crystal silicon layer 49, for example, at least a portion where the p-type impurity region 12c is to be finally formed is a single crystal. The second single crystal silicon layer 49 may partially include, for example, crystal grains or crystal defects.

Thereafter, the wiring layer 18 in contact with the first portion P1 of the second single crystal silicon layer 49 is formed by a manufacturing method similar to the manufacturing method of the first embodiment. In addition, the gate electrode layer 14 facing the third portion P3 of the second single crystal silicon layer 49 is formed as in the manufacturing method of the first embodiment. In addition, the capacitor CA in contact with the second portion P2 of the second single crystal silicon layer 49 is formed by the manufacturing method similar to the manufacturing method of the first embodiment.

The memory cell array 101 of the DRAM of the first embodiment is formed by the manufacturing method of the modified example described above.

As described above, according to the first embodiment and the modified example, it is possible to realize high integration of the semiconductor memory device.

### Second Embodiment

A method for manufacturing a semiconductor memory device of a second embodiment is different from the method for manufacturing the semiconductor memory device of the first embodiment in that a fourth film of a fourth material different from a first material and a second material, is formed between a first film and a second film, a fifth film of a fifth material identical to the fourth material, is formed between the second film and a third film, a first single crystal silicon layer in a first opening is removed after a second single crystal silicon layer is formed, each of the fourth film and the fifth film is etched from a side face of the first opening to form a second recess after the first single crystal silicon layer is removed, and a gate electrode layer is formed in the second recess.

Hereinafter, some of the content overlapping with that in the first embodiment will not be described in some cases.

The semiconductor memory device of the second embodiment is a DRAM. The DRAM of the second embodiment is a DRAM having a three-dimensional structure in which memory cells are three-dimensionally disposed. The DRAM of the second embodiment is a DRAM in which a bit line is provided in a direction perpendicular to a substrate.

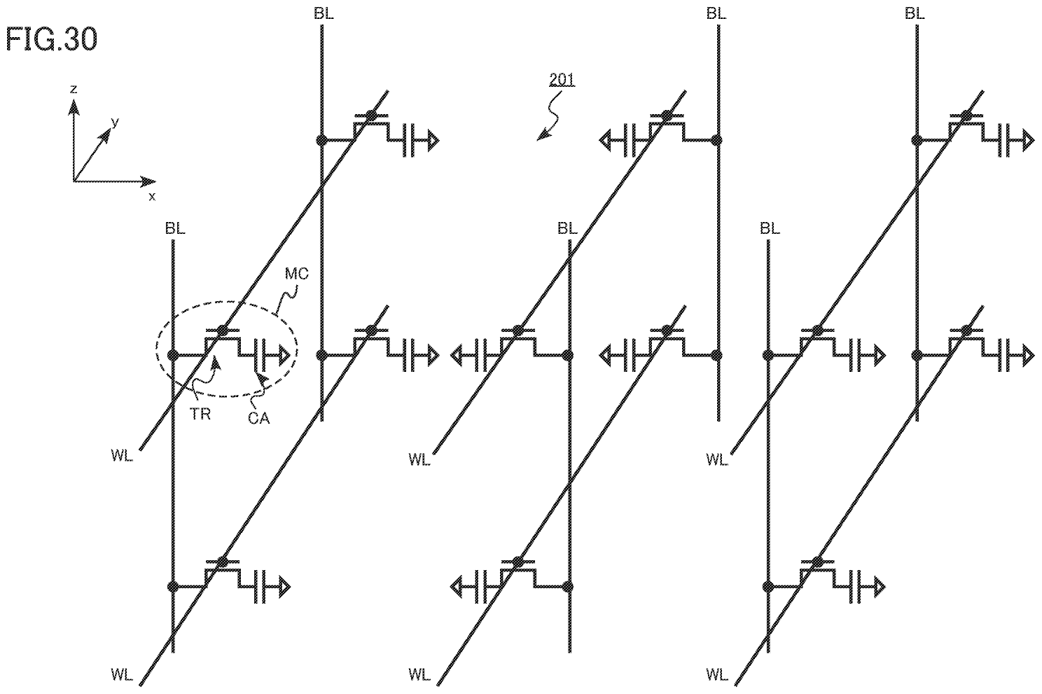

FIG. 30 is an equivalent circuit diagram of a memory cell array of the semiconductor memory device of the second embodiment. The DRAM of the second embodiment includes a memory cell array 201. FIG. 30 schematically illustrates a wiring structure in the memory cell array 201. The memory cell array 201 of the second embodiment has a three-dimensional structure in which the plurality of memory cells MC are three-dimensionally disposed. Although FIG. 30 illustrates a case where the number of the memory cells MC is twelve, the number of memory cells included in the memory cell array is not limited to twelve.

Hereinafter, a z direction illustrated in FIG. 30 is an example of a first direction. An x direction is an example of a second direction. A y direction is an example of a third direction. The y direction intersects with the x direction. The z direction intersects with the x direction and the y direction. For example, the x direction and the y direction are orthogonal to each other. For example, the z direction, the x direction, and the y direction are orthogonal to each other.

The memory cell array 201 includes the plurality of memory cells MC, the plurality of word lines WL, and the plurality of bit lines BL. The memory cell MC includes the transistor TR and the capacitor CA.

The bit line BL extends in the z direction. The word line extends in the y direction.

The word line WL is electrically connected to a gate electrode of the transistor TR. The bit line BL is electrically connected to one of source and drain electrodes of the transistor TR. The other of the source and drain electrodes of the transistor TR is electrically connected to one of electrodes of the capacitor CA.

The memory cell MC stores data by accumulating charge in the capacitor CA. Data is written and read by turning on the transistor TR.

One memory cell MC can be selected by selecting one bit line BL and one word line WL. For example, the transistor TR is turned on by applying a voltage to the word line WL in a state where a desired voltage is applied to the bit line BL, thereby writing data to the memory cell MC. In addition, for example, the transistor TR is turned on, and a voltage change of the bit line BL corresponding to the amount of charge accumulated in the capacitor CA is detected, thereby reading data of the memory cell MC.

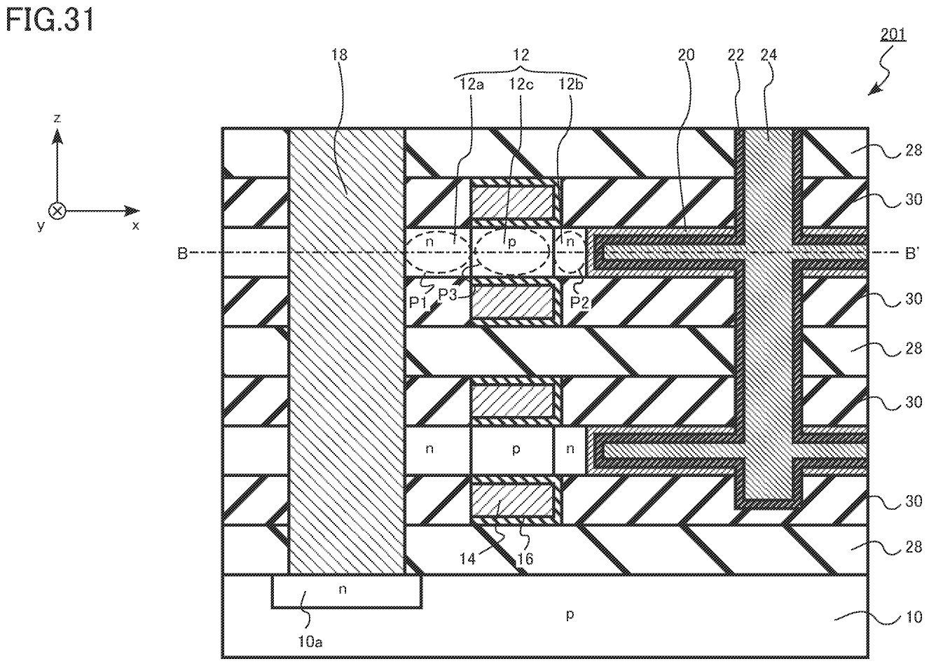

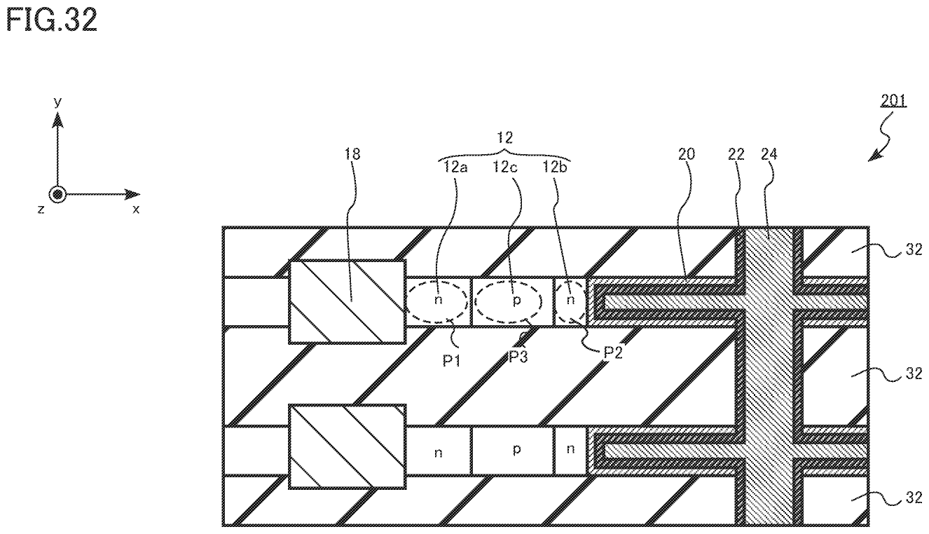

FIGS. 31 and 32 are schematic cross-sectional views of the semiconductor memory device of the second embodiment. FIGS. 31 and 32 are cross sections each including two memory cells MC.

FIG. 31 is an xz cross section. FIG. 32 is an xy cross section. FIG. 32 is a cross-sectional view taken along a line BB′ of FIG. 31.

The memory cell array 201 of the DRAM of the second embodiment includes the single crystal silicon substrate 10, the single crystal silicon layer 12, the gate electrode layer 14, the gate insulating film 16, the wiring layer 18, the storage node electrode 20, the capacitor insulating film 22, the plate electrode 24, the first interlayer insulating layer 28, the second interlayer insulating layer 30, and the third interlayer insulating layer 32.

The single crystal silicon substrate 10 includes an n-type impurity region 10a.

The single crystal silicon layer 12 includes the first n-type impurity region 12a, the second n-type impurity region 12b, and the p-type impurity region 12c.

The single crystal silicon layer 12, the gate electrode layer 14, and the gate insulating film 16 constitute the transistor TR. In addition, the storage node electrode 20, the capacitor insulating film 22, and the plate electrode 24 constitute the capacitor CA.

The single crystal silicon substrate 10 is single crystal silicon. The single crystal silicon substrate 10 contains, for example, p-type impurities. The single crystal silicon substrate 10 is, for example, a p-type substrate. A normal direction of a surface of the single crystal silicon substrate 10 is the z direction. The normal direction of the surface of the single crystal silicon substrate 10 is the first direction.

The single crystal silicon substrate 10 includes an n-type impurity region 10a. The n-type impurity region 10a is in contact with the wiring layer 18.

The single crystal silicon layer 12 is single crystal silicon. The single crystal silicon layer 12 extends in a direction along the surface of the single crystal silicon substrate 10. The single crystal silicon layer 12 extends, for example, in the second direction. The single crystal silicon layer 12 is separated from the single crystal silicon substrate 10 in the first direction.

The single crystal silicon layer 12 includes the first n-type impurity region 12a, the second n-type impurity region 12b, and the p-type impurity region 12c. The p-type impurity region 12c is provided between the first n-type impurity region 12a and the second n-type impurity region 12b.

The first n-type impurity region 12a contains n-type impurities. The first n-type impurity region 12a is n-type silicon. The second n-type impurity region 12b contains n-type impurities. The second n-type impurity region 12b is n-type silicon. The p-type impurity region 12c contains p-type impurities. The p-type impurity region 12c is p-type silicon.

The single crystal silicon layer 12 has the first portion P1, the second portion P2, and the third portion P3. The third portion P3 is provided between the first portion P1 and the second portion P2. The first portion P1, the second portion P2, and the third portion P3 are portions surrounded by dotted lines in FIGS. 31 and 32, respectively.

The first portion P1 includes, for example, the first n-type impurity region 12a. The second portion P2 includes, for example, the second n-type impurity region 12b. The third portion P3 includes, for example, the p-type impurity region 12c.

A crystal defect density of the first portion P1 is higher than a crystal defect density of the third portion P3. The crystal defect density of the first portion P1 is, for example, equal to or more than ten times and equal to or less than 1000 times the crystal defect density of the third portion P3.

A crystal defect density of the first n-type impurity region 12a is higher than a crystal defect density of the p-type impurity region 12c. The crystal defect density of the first n-type impurity region 12a is equal to or more than ten times and equal to or less than 1000 times the crystal defect density of the p-type impurity region 12c.

The gate electrode layer 14 extends in a direction along the surface of the single crystal silicon substrate 10. The gate electrode layer 14 extends, for example, in the third direction. The gate electrode layer 14 corresponds to the word line WL.

The gate electrode layer 14 is provided on each of both sides of the single crystal silicon layer 12 in the first direction. For example, the single crystal silicon layer 12 is provided between the two gate electrode layers 14 having the same electric potential.

The gate electrode layer 14 is facing the single crystal silicon layer 12. The gate electrode layer 14 is facing the third portion P3 of the single crystal silicon layer 12. The gate electrode layer 14 is facing the p-type impurity region 12c of the single crystal silicon layer 12.

The gate electrode layer 14 is a conductor. The gate electrode layer 14 is, for example, polycrystalline silicon containing conductive impurities.

The gate insulating film 16 is provided between the gate electrode layer 14 and the single crystal silicon layer 12. The gate insulating film 16 is provided between the gate electrode layer 14 and the third portion P3 of the single crystal silicon layer 12. The gate insulating film 16 is provided between the gate electrode layer 14 and the p-type impurity region 12c of the single crystal silicon layer 12.

The gate insulating film 16 is an insulator. The gate insulating film 16 is, for example, silicon oxide.

The wiring layer 18 extends in the normal direction of the surface of the single crystal silicon substrate 10. The wiring layer 18 extends in the first direction. The wiring layer 18 corresponds to the bit line BL.

The wiring layer 18 is electrically connected to the first portion P1 of the single crystal silicon layer 12. The wiring layer 18 is electrically connected to the first n-type impurity region 12a of the single crystal silicon layer 12. The wiring layer 18 is in contact with the first portion P1 of the single crystal silicon layer 12. The wiring layer 18 is in contact with the first n-type impurity region 12a of the single crystal silicon layer 12.

The wiring layer 18 is in contact with, for example, the single crystal silicon substrate 10. The wiring layer 18 is in contact with, for example, the n-type impurity region 10a of the single crystal silicon substrate 10.

The wiring layer 18 is a conductor. The wiring layer 18 is, for example, metal. The wiring layer 18 contains, for example, tungsten.

The storage node electrode 20 is electrically connected to the second portion P2 of the single crystal silicon layer 12. The storage node electrode 20 is electrically connected to the second n-type impurity region 12b of the single crystal silicon layer 12. The storage node electrode 20 is in contact with the second portion P2 of the single crystal silicon layer 12. The storage node electrode 20 is in contact with the second n-type impurity region 12b of the single crystal silicon layer 12. The storage node electrode 20 is a conductor. The storage node electrode 20 is, for example, metal. The storage node electrode 20 is, for example, titanium nitride.

The capacitor insulating film 22 is provided between the storage node electrode 20 and the plate electrode 24. The capacitor insulating film 22 is in contact with the storage node electrode 20 and the plate electrode 24.

The capacitor insulating film 22 is an insulator. The capacitor insulating film 22 includes, for example, an insulator having a dielectric constant higher than that of silicon dioxide. The capacitor insulating film 22 includes, for example, a so-called High-k insulator.

The capacitor insulating film 22 contains, for example, zirconium oxide or aluminum oxide. The capacitor insulating film 22 is, for example, zirconium oxide, aluminum oxide, or a combination of zirconium oxide and aluminum oxide.

The plate electrode 24 is a conductor. The plate electrode 24 is, for example, metal. The plate electrode 24 is, for example, titanium nitride.

The first interlayer insulating layer 28, the second interlayer insulating layer 30, and the third interlayer insulating layer 32 are insulators. The first interlayer insulating layer 28, the second interlayer insulating layer 30, and the third interlayer insulating layer 32 are, for example, silicon oxide or silicon nitride. The first interlayer insulating layer 28, the second interlayer insulating layer 30, and the third interlayer insulating layer 32 may include, for example, a semiconductor.

Next, an example of a method for manufacturing the semiconductor memory device of the second embodiment will be described.

The example of the method for manufacturing the semiconductor memory device of the second embodiment includes: forming a first film of a first material in a first direction of a single crystal silicon substrate; forming a second film of a second material different from the first material, in the first direction of the first film; forming a third film of a third material different from the second material, in the first direction of the second film; forming a first opening penetrating the third film, the second film, and the first film and reaching the single crystal silicon substrate; forming a first single crystal silicon layer in contact with the single crystal silicon substrate in the first opening; forming a second opening penetrating the third film and the second film; etching the second film from a side face of the second opening to form a first recess reaching the first single crystal silicon layer; forming a second single crystal silicon layer in contact with the first single crystal silicon layer in the first recess; forming a wiring layer in contact with a first portion of the second single crystal silicon layer; forming a capacitor in contact with a second portion of the second single crystal silicon layer; and forming a gate electrode layer facing a third portion of the second single crystal silicon layer between the first portion and the second portion.

In addition, in the example of the method for manufacturing the semiconductor memory device of the second embodiment, the second material is amorphous silicon or polycrystalline silicon, an oxide film is formed on a surface of the second film exposed on a side face of the first opening after the forming the first opening and before the forming the first single crystal silicon layer, and the oxide film is removed after the etching the second film to form the first recess.

In addition, in the example of the method for manufacturing the semiconductor memory device of the second embodiment, a fourth film of a fourth material different from the first material and the second material, is formed between the first film and the second film, a fifth film of a fifth material identical to the fourth material, is formed between the second film and the third film, the first single crystal silicon layer in the first opening is removed after the forming the second single crystal silicon layer, and each of the fourth film and the fifth film is etched from a side face of the first opening to form a second recess after the removing the first single crystal silicon layer. The gate electrode layer is formed in the second recess.

In addition, in the example of the method for manufacturing the semiconductor memory device of the second embodiment, a first n-type impurity region, a p-type impurity region, and a second n-type impurity region are formed in order from a side closer to the first single crystal silicon layer in the forming the second single crystal silicon layer. The gate electrode layer is facing the p-type impurity region.

Hereinafter, a case where the first material is silicon oxide, the second material is amorphous silicon, the third material is silicon oxide, and the fourth material and the fifth material are silicon nitride will be described as an example. In this case, the first material and the third material are the same material.

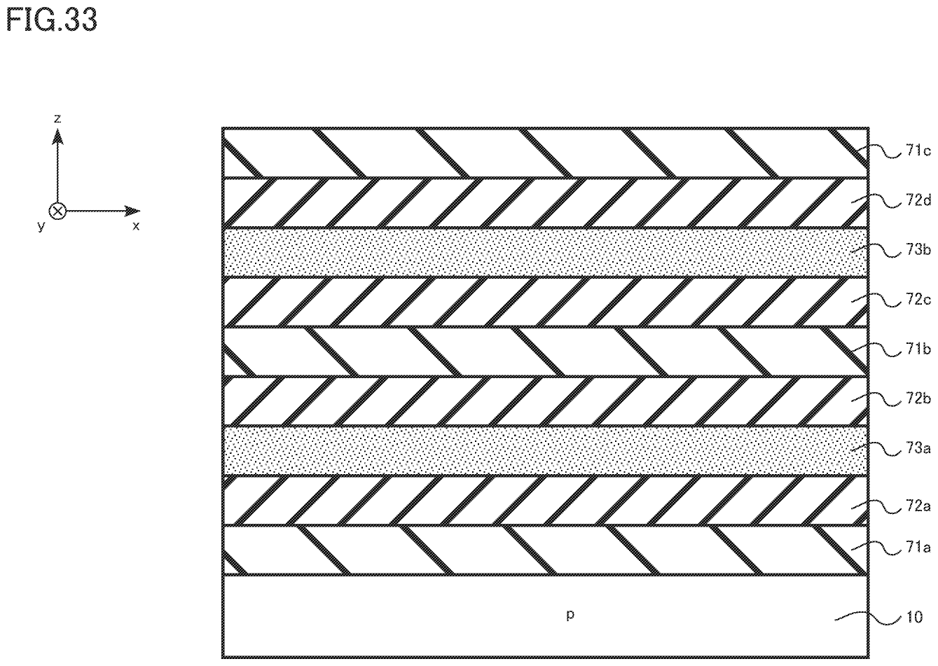

FIGS. 33, 34, 35, 36, 37, 38, 39, 40, 41, 42, 43, 44, 45, 46, 47, 48, 49, and 50 are schematic cross-sectional views illustrating the method for manufacturing the semiconductor memory device of the second embodiment.

FIGS. 33 to 50 are cross sections corresponding to FIG. 31. FIGS. 33 to 50 are xz cross sections.

First, a first silicon oxide film 71a, a first silicon nitride film 72a, a first amorphous silicon film 73a, a second silicon nitride film 72b, a second silicon oxide film 71b, a third silicon nitride film 72c, a second amorphous silicon film 73b, a fourth silicon nitride film 72d, and a third silicon oxide film 71c are formed in this order in the first direction of the single crystal silicon substrate 10 (FIG. 33).

The first silicon oxide film 71a is formed on the surface of the single crystal silicon substrate 10. The first silicon nitride film 72a is formed on the first silicon oxide film 71a. The first amorphous silicon film 73a is formed on the first silicon nitride film 72a. The second silicon nitride film 72b is formed on the first amorphous silicon film 73a. The second silicon oxide film 71b is formed on the second silicon nitride film 72b. The third silicon nitride film 72c is formed on the second silicon oxide film 71b. The second amorphous silicon film 73b is formed on the third silicon nitride film 72c. The fourth silicon nitride film 72d is formed on the second amorphous silicon film 73b. The third silicon oxide film 71c is formed on the fourth silicon nitride film 72d.

The first silicon oxide film 71a, the first silicon nitride film 72a, the first amorphous silicon film 73a, the second silicon nitride film 72b, the second silicon oxide film 71b, the third silicon nitride film 72c, the second amorphous silicon film 73b, the fourth silicon nitride film 72d, and the third silicon oxide film 71c are formed by, for example, a CVD method.

The first silicon oxide film 71a is an example of the first film. The first amorphous silicon film 73a is an example of the second film. The second silicon oxide film 71b is an example of the third film. The first silicon nitride film 72a is an example of the fourth film. The second silicon nitride film 72b is an example of the fifth film.

A part of each of the first silicon oxide film 71a, the second silicon oxide film 71b, and the third silicon oxide film 71c finally serves as the first interlayer insulating layer 28. In addition, a part of each of the first silicon nitride film 72a, the second silicon nitride film 72b, the third silicon nitride film 72c, and the fourth silicon nitride film 72d finally serves as the second interlayer insulating layer 30.

Note that each of the first amorphous silicon film 73a and the second amorphous silicon film 73b is patterned into a plurality of regions so as to be divided in the third direction by a method (not illustrated).

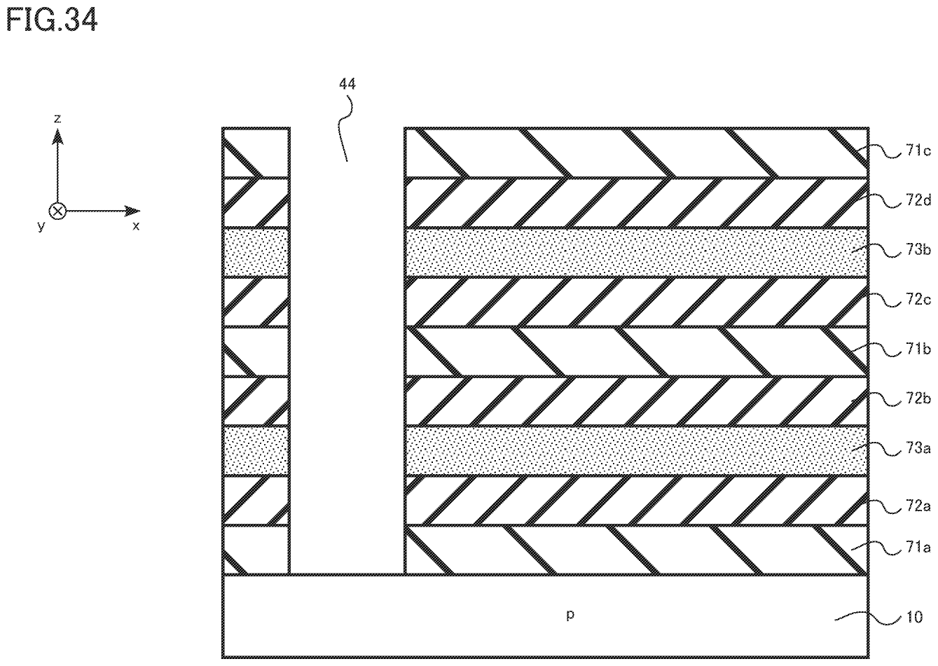

Next, the first opening 44 that penetrates the third silicon oxide film 71c, the fourth silicon nitride film 72d, the second amorphous silicon film 73b, the third silicon nitride film 72c, the second silicon oxide film 71b, the second silicon nitride film 72b, the first amorphous silicon film 73a, the first silicon nitride film 72a, and the first silicon oxide film 71a and reaches the single crystal silicon substrate 10 is formed (FIG. 34).

The first opening 44 is formed by, for example, a lithography method and a reactive ion etching method (RIE method).

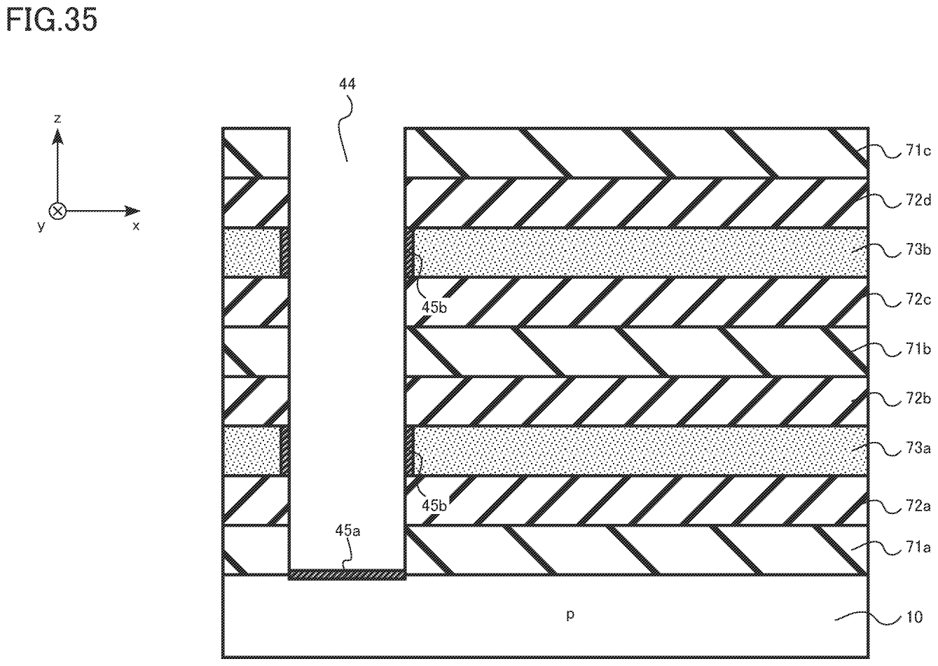

Next, the first oxide film 45a is formed on the surface of the single crystal silicon substrate 10 exposed at a bottom of the first opening 44. In addition, the second oxide film 45b is formed on each of a surface of the first amorphous silicon film 42a exposed on a side face of the first opening 44 and a surface of the second amorphous silicon film 42b exposed on the side face of the first opening 44 (FIG. 35). The second oxide film 45b is an example of the oxide film.

The first oxide film 45a and the second oxide film 45b are formed by thermal oxidation, for example.

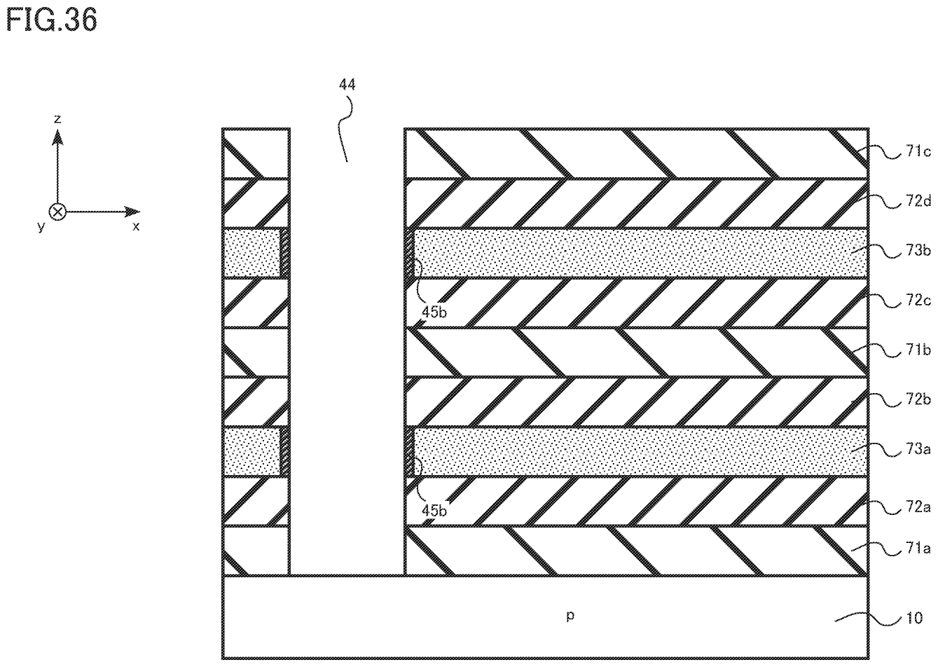

Next, the first oxide film 45a at the bottom of the first opening 44 is removed (FIG. 36). The first oxide film 45a is removed by, for example, a dry etching method or a wet etching method. The second oxide film 45b remains.

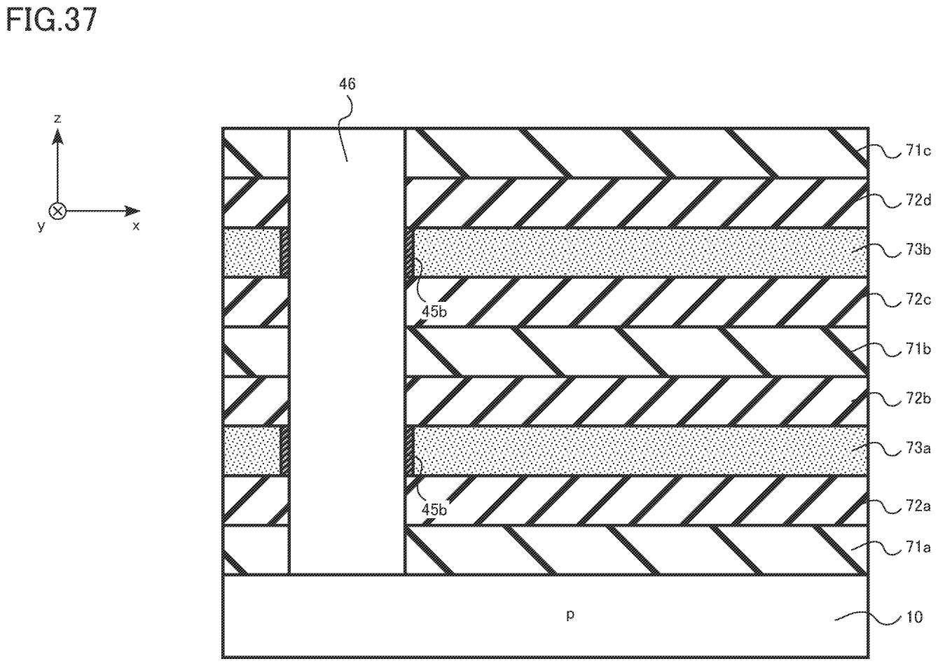

Next, the first single crystal silicon layer 46 in contact with the single crystal silicon substrate 10 is formed in the first opening 44 (FIG. 37). The first single crystal silicon layer 46 is formed using the single crystal silicon substrate 10 as a seed crystal. The first single crystal silicon layer 46 is, for example, non-doped single crystal silicon containing no conductive impurity.

The first single crystal silicon layer 46 is formed using, for example, a solid phase epitaxial growth method. In a case where the solid phase epitaxial growth method is used, for example, the first opening 44 is filled with an amorphous silicon layer. Thereafter, heat treatment is performed to form the single crystal silicon.

Alternatively, the first single crystal silicon layer 46 may be formed using, for example, a vapor phase epitaxial growth method.

Furthermore, as a method for accelerating vapor phase epitaxial growth, the first single crystal silicon layer 46 is formed using, for example, a vapor-liquid-solid method (VLS method). In a case where the VLS method is used, metal or a metal compound is formed as a catalyst, and single crystal silicon is formed using the catalyst as a nucleus. The catalyst is, for example, gold (Au), indium (In), tin (Sb), or indium tin oxide. The catalyst is formed using, for example, an ALD method, a CVD method, or a sputtering method.

Note that at least a part of the first single crystal silicon layer 46 is a single crystal. In the first single crystal silicon layer 46, for example, at least a portion in contact with the second oxide film 45b is a single crystal. The first single crystal silicon layer 46 may partially include, for example, crystal grains or crystal defects.

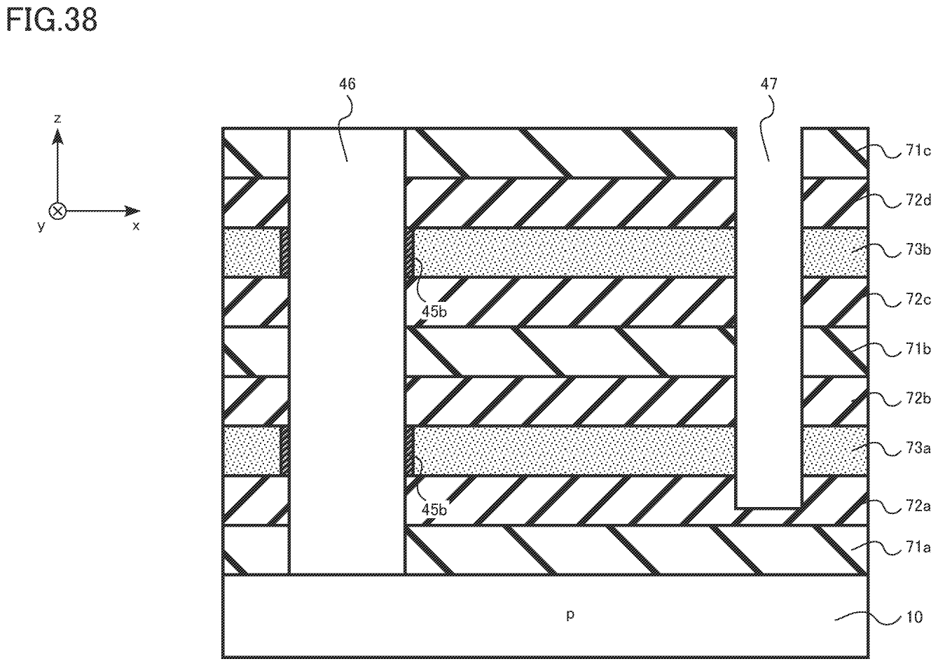

Next, the second opening 47 that penetrates the third silicon oxide film 71c, the fourth silicon nitride film 72d, the second amorphous silicon film 73b, the third silicon nitride film 72c, the second silicon oxide film 71b, the second silicon nitride film 72b, and the first amorphous silicon film 73a is formed (FIG. 38). The surface of the single crystal silicon substrate 10 is not exposed at a bottom of the second opening 47.

The second opening 47 is formed by, for example, a lithography method and an RIE method.

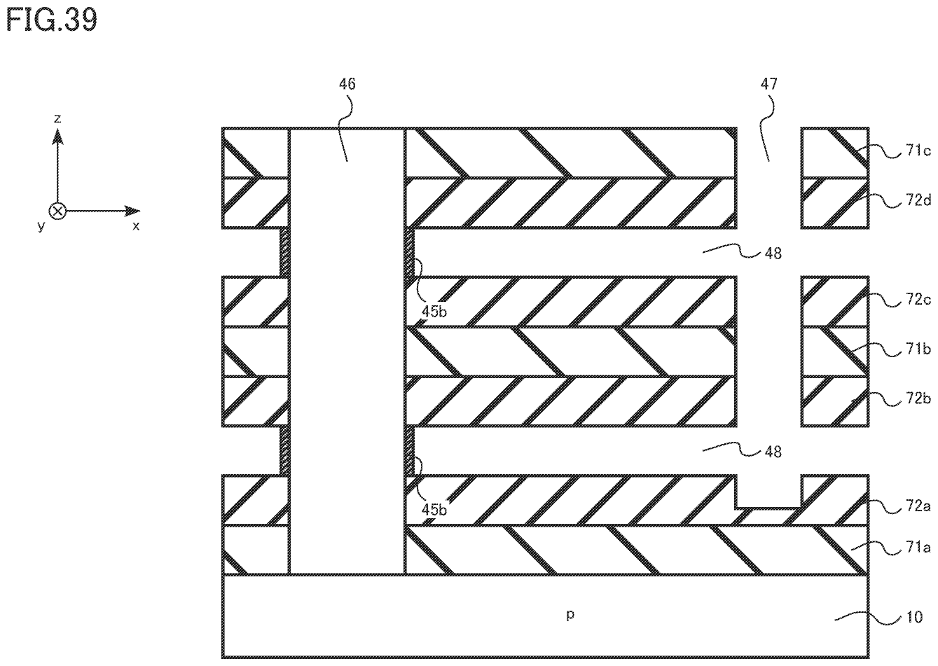

Next, the first amorphous silicon film 73a and the second amorphous silicon film 73b are selectively etched from a side face of the second opening 47 to form first recesses 48 (FIG. 39). The second oxide films 45b are exposed at depths of the first recesses 48, respectively. The first amorphous silicon film 73a and the second amorphous silicon film 73b are etched using, for example, a dry etching method or a wet etching method.

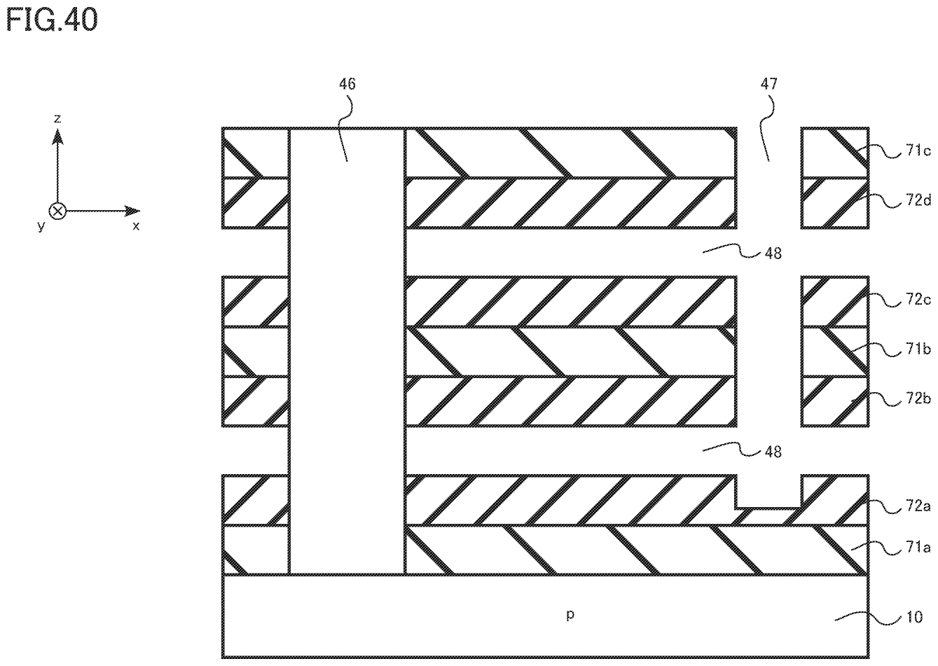

Next, the second oxide film 45b is removed (FIG. 40). The second oxide films 45b are removed using, for example, a wet etching method. The first single crystal silicon layer 46 is exposed at depths of the first recesses 48.

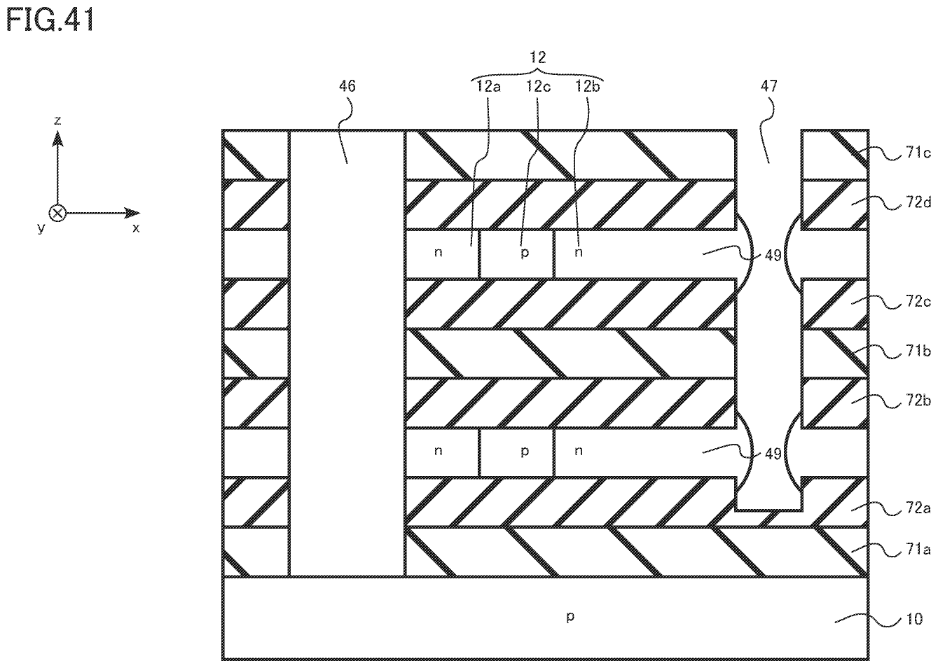

Next, the second single crystal silicon layer 49 in contact with the first single crystal silicon layer 46 is formed in each of the first recesses 48 (FIG. 41). The second single crystal silicon layer 49 is formed using the first single crystal silicon layer 46 as a seed crystal.

When the second single crystal silicon layer 49 is formed, the first n-type impurity region 12a, the p-type impurity region 12c, and the second n-type impurity region 12b are formed in order from a side closer to the first single crystal silicon layer 46. For example, an impurity conductivity type is switched by switching a doping gas for growing the second single crystal silicon layer 49 in the middle. A part of the second single crystal silicon layer 49 finally serves as the single crystal silicon layer 12.

When the second single crystal silicon layer 49 is formed, for example, only an impurity concentration can be switched without switching the impurity conductivity type. For example, a threshold voltage of the transistor TR can be adjusted by finally changing only a p-type impurity concentration of a portion facing the gate electrode layer 14.

In addition, after the second single crystal silicon layer 49 is formed, it is also possible to dope and activate impurities of a conductivity type different from that of the initial single crystal silicon using a method such as vapor phase doping as in the first embodiment. In the second embodiment, polycrystalline silicon doped with impurities may be brought into contact with an exposed surface where an impurity region is to be formed, and the impurities may be diffused by thermal diffusion.

The second single crystal silicon layer 49 is formed using, for example, a vapor phase epitaxial growth method.

Furthermore, the second single crystal silicon layer 49 may be formed using, for example, a VLS method. In a case where the VLS method is used, metal or a metal compound is formed as a catalyst, and single crystal silicon is formed using the catalyst as a nucleus. The catalyst is, for example, gold (Au), indium (In), tin (Sb), or indium tin oxide. Here, it is necessary to form the catalyst on an exposed surface of the first single crystal silicon layer 46 on sidewalls at the depth of the first recess 48, and thus the catalyst is selectively attached to the surface side of the exposed seed crystal silicon using, for example, an ALD method, a CVD method, or the like.

Note that at least a part of the second single crystal silicon layer 49 is a single crystal. In the second single crystal silicon layer 49, for example, at least the p-type impurity region 12c is a single crystal. The second single crystal silicon layer 49 may partially include, for example, crystal grains or crystal defects.

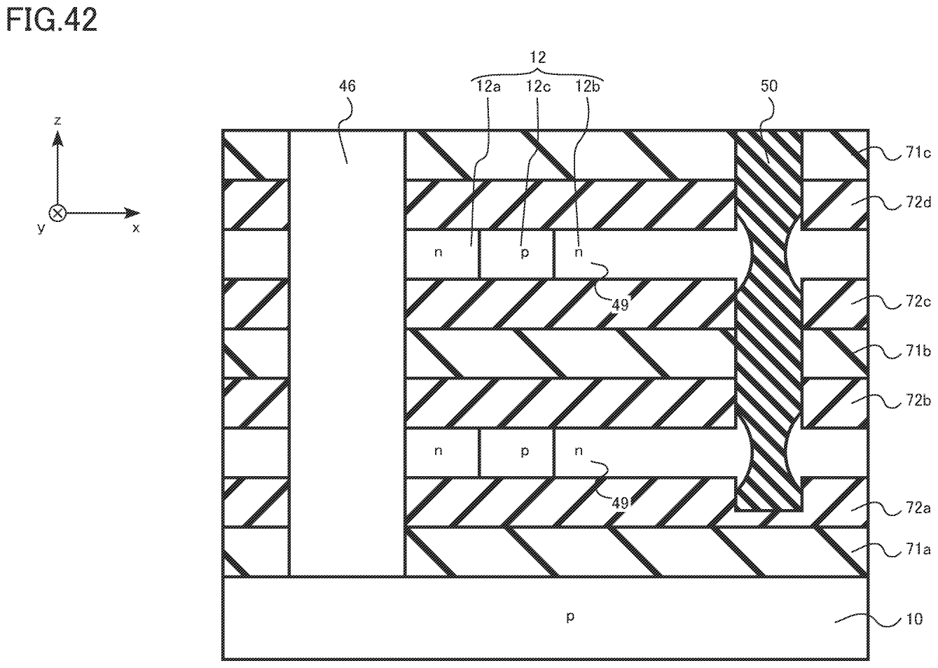

Next, the second opening 47 is filled with the silicon oxide film 50 (FIG. 42).

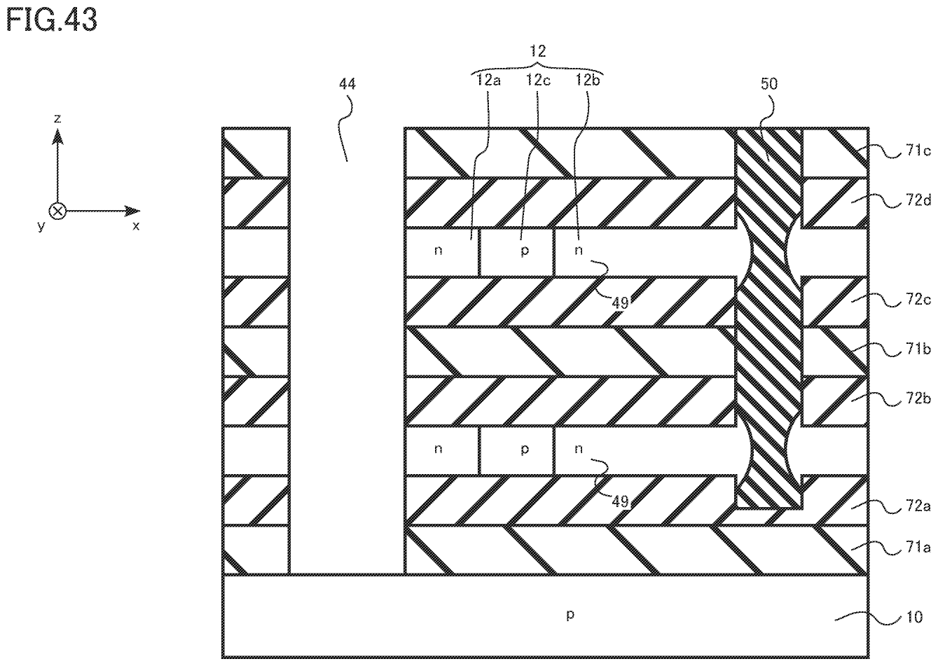

Next, the first single crystal silicon layer 46 in the first opening 44 is removed (FIG. 43). The first single crystal silicon layer 46 is removed by, for example, a dry etching method or a wet etching method.

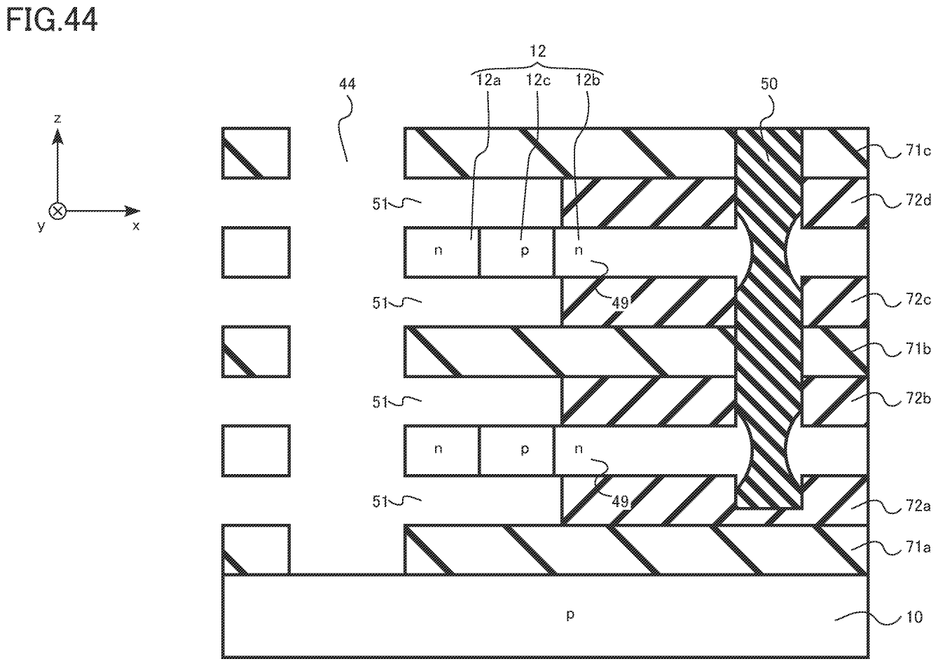

Next, the first silicon nitride film 72a, the second silicon nitride film 72b, the third silicon nitride film 72c, and the fourth silicon nitride film 72d are etched from the side face of the first opening 44 to form the second recesses 51 (FIG. 44). The first silicon nitride film 72a, the second silicon nitride film 72b, the third silicon nitride film 72c, and the fourth silicon nitride film 72d are removed by, for example, a wet etching method.

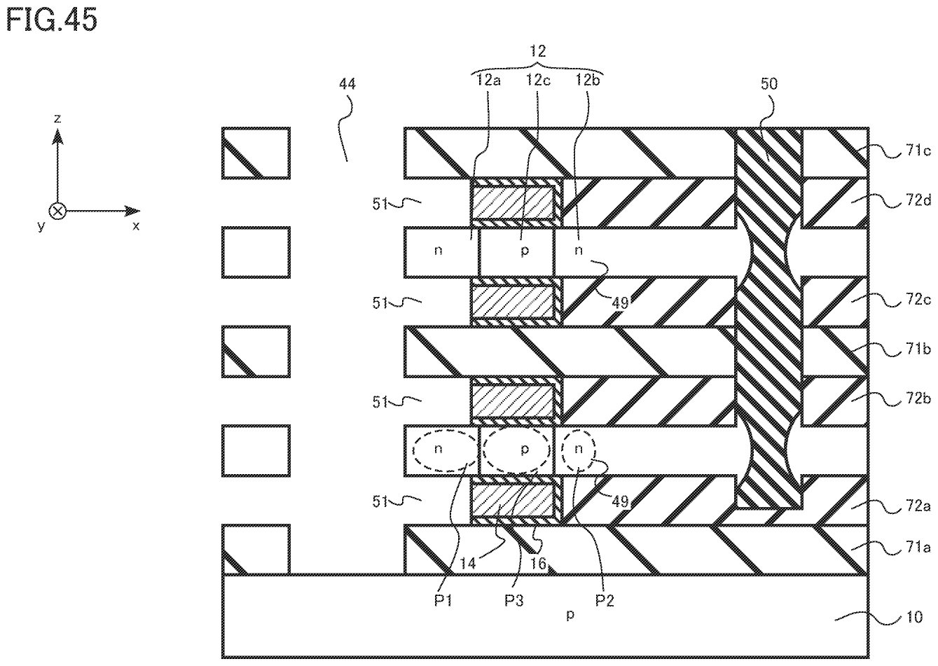

Next, the gate insulating film 16 and the gate electrode layer 14 are formed in each of the second recesses 51 (FIG. 45). The gate insulating film 16 is in contact with the third portion P3 of the second single crystal silicon layer 49. The gate insulating film 16 is in contact with the p-type impurity region 12c of the second single crystal silicon layer 49. The gate electrode layer 14 is facing the third portion P3 of the second single crystal silicon layer 49. The gate electrode layer 14 is facing the p-type impurity region 12c of the second single crystal silicon layer 49.

The gate insulating film 16 and the gate electrode layer 14 are formed in the second recess 51 using, for example, a CVD method and a dry etching method.

Next, the first opening 44 and the second recess 51 are filled with the silicon oxide film 52. The first opening 44 and the second recess 51 are filled with the silicon oxide film 52 using, for example, a CVD method and a dry etching method.

Next, a plurality of openings 44x separated in the third direction are formed in the silicon oxide film 52

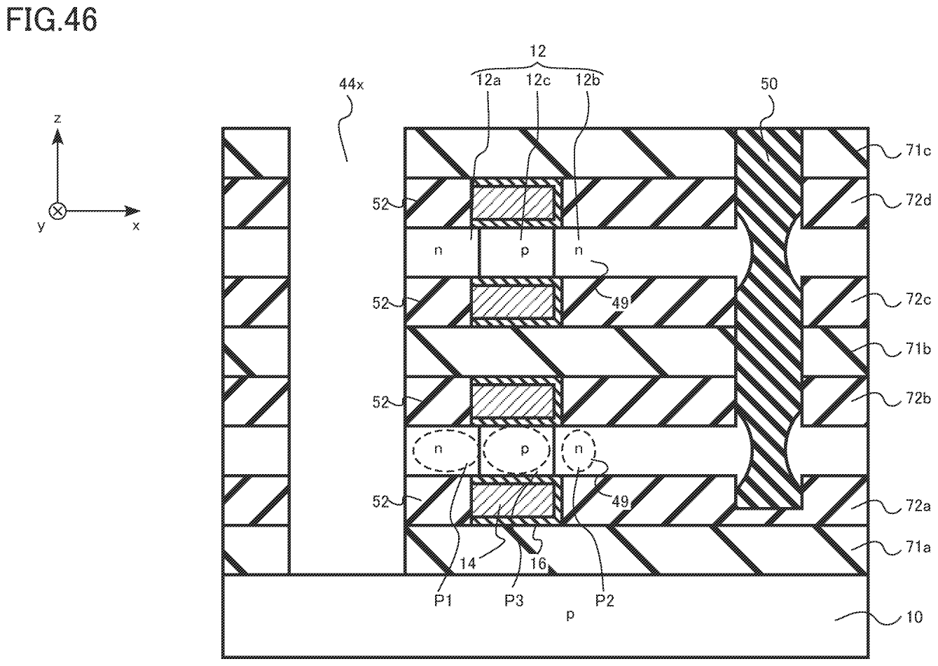

(FIG. 46).

Next, the n-type impurity region 10a is formed in the single crystal silicon substrate 10 at the bottom of each of the plurality of openings 44x. The n-type impurity region 10a is formed by, for example, an ion implantation method. The n-type impurity region 10a can also be formed by, for example, doping and activating impurities of a conductivity type different from that of the single crystal silicon substrate 10 using a method such as vapor phase doping. In addition, the n-type impurity region 10a can also be formed by bringing polycrystalline silicon doped with conductive impurities into contact with an exposed surface of the single crystal silicon substrate 10, diffusing the impurities by thermal diffusion, and then removing the polycrystalline silicon.

N-type impurities introduced into the single crystal silicon substrate 10 are activated by, for example, heat treatment at a high temperature for a short time.

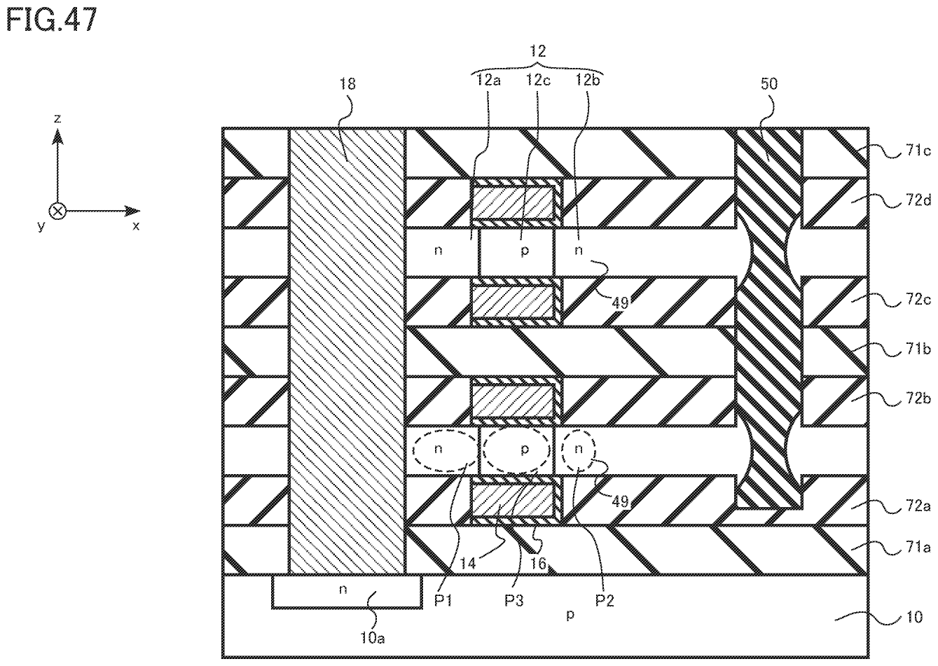

Next, the wiring layer 18 is formed in each of the plurality of openings 44x (FIG. 47). The wiring layer 18 is formed by, for example, a CVD method.

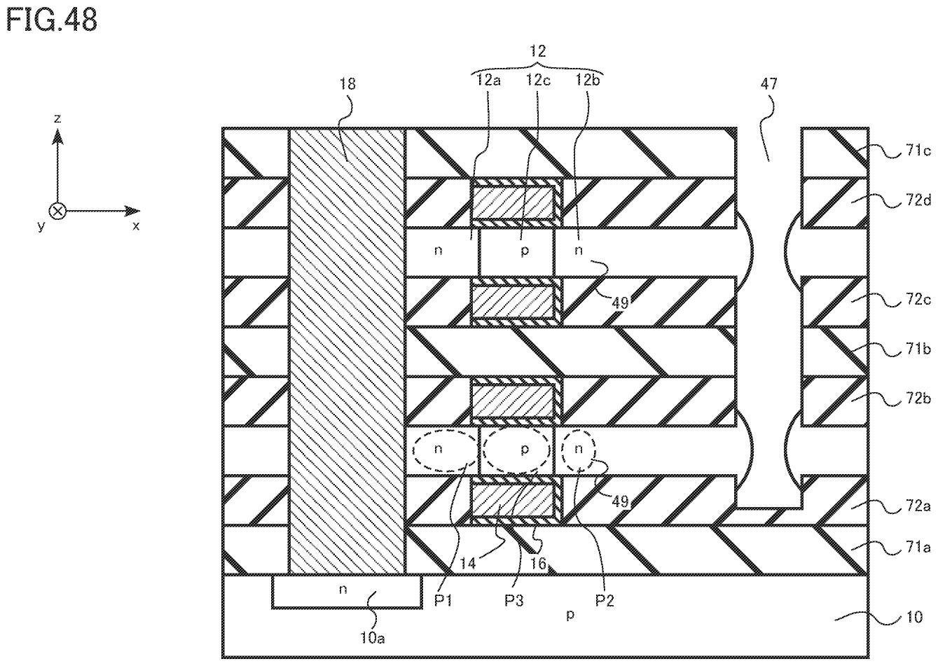

Next, the silicon oxide film 50 in the second opening 47 is removed (FIG. 48). The silicon oxide film 50 is removed by, for example, a wet etching method.

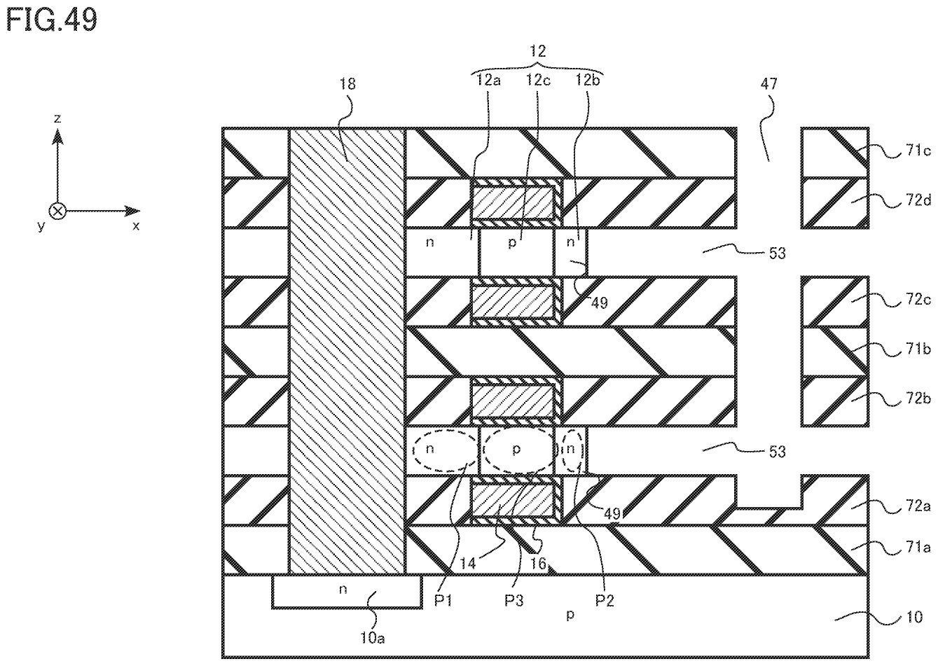

Next, the second single crystal silicon layers 49 are selectively etched from the side face of the second opening 47 to form the third recesses 53 (FIG. 49). The second single crystal silicon layers 49 are etched using, for example, a dry etching method or a wet etching method.

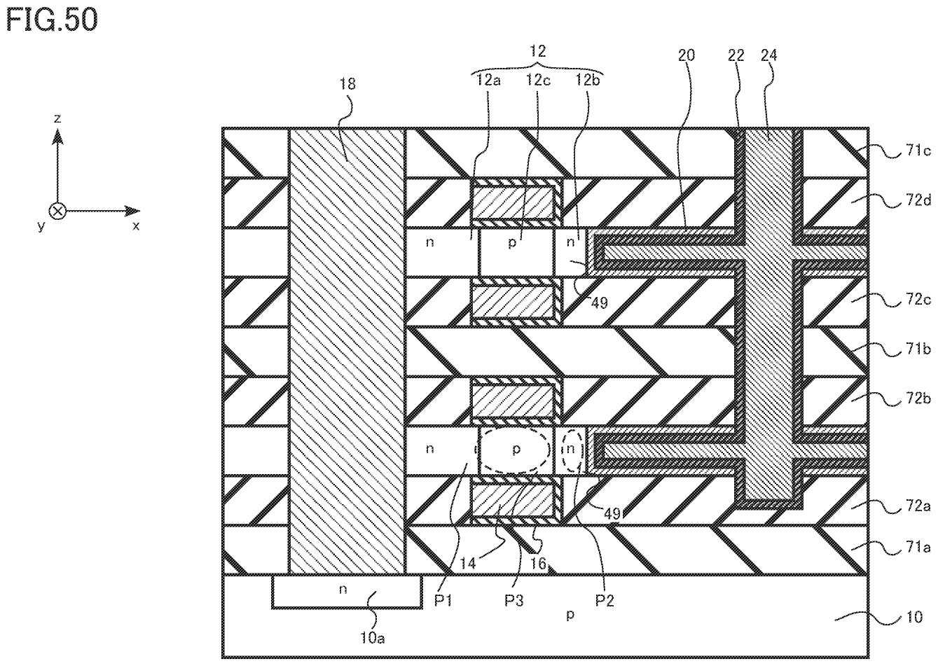

Next, the storage node electrode 20, the capacitor insulating film 22, and the plate electrode 24 are formed in each of the third recesses 53 (FIG. 50). The storage node electrode 20 is in contact with the second portion P2 of the second single crystal silicon layer 49. The capacitor CA including the storage node electrode 20, the capacitor insulating film 22, and the plate electrode 24 is in contact with the second portion P2 of the second single crystal silicon layer 49. The storage node electrode 20, the capacitor insulating film 22, and the plate electrode 24 are formed using, for example, a CVD method.

The memory cell array 201 of the DRAM of the second embodiment is formed by the above manufacturing method.

In the DRAM of the second embodiment, the memory cells MC are three-dimensionally disposed. Therefore, high integration can be realized.

In the DRAM of the second embodiment, the crystal defect density of the first portion P1 of the single crystal silicon layer 12 is higher than the crystal defect density of the third portion P3. Therefore, for example, charge retention characteristics are improved similarly to the DRAM of the first embodiment.

In addition, according to the method for manufacturing the DRAM of the second embodiment, the DRAM having the three-dimensional structure with stable characteristics can be manufactured in a short manufacturing time similarly to the method for manufacturing the DRAM of the first embodiment.

### Modified Example

A method for manufacturing a DRAM of a modified example of the second embodiment is different from the method for manufacturing the DRAM of the second embodiment in that the second material is silicon nitride and the fourth material and the fifth material are amorphous silicon. According to the method for manufacturing the DRAM of the modified example of the second embodiment, the DRAM having a three-dimensional structure with stable characteristics can be manufactured in a short manufacturing time similarly to the method for manufacturing the DRAM of the second embodiment.

As described above, according to the second embodiment and the modified example, it is possible to realize high integration of the semiconductor memory device.

### Third Embodiment

A method for manufacturing a semiconductor memory device of a third embodiment is different from the method for manufacturing the semiconductor memory device of the modified example of the first embodiment in that a fourth film is not formed. Hereinafter, some of the content overlapping with that in the first embodiment will not be described in some cases.

An example of the method for manufacturing the semiconductor memory device of the third embodiment includes: forming a first film of a first material in a first direction of a single crystal silicon substrate; forming a second film of a second material different from the first material, in the first direction of the first film; forming a third film of a third material different from the second material, in the first direction of the second film; forming a first opening penetrating the third film, the second film, and the first film and reaching the single crystal silicon substrate; forming a first single crystal silicon layer in contact with the single crystal silicon substrate in the first opening; forming a second opening penetrating the third film and the second film; etching the second film from a side face of the second opening to form a first recess reaching the first single crystal silicon layer; forming a second single crystal silicon layer in contact with the first single crystal silicon layer in the first recess; forming a wiring layer in contact with a first portion of the second single crystal silicon layer; forming a capacitor in contact with a second portion of the second single crystal silicon layer; and forming a gate electrode layer facing a third portion of the second single crystal silicon layer between the first portion and the second portion.

Hereinafter, a case where the first material is silicon oxide, the second material is silicon nitride, and the third material is silicon oxide will be described as an example. In this case, the first material and the third material are the same material.

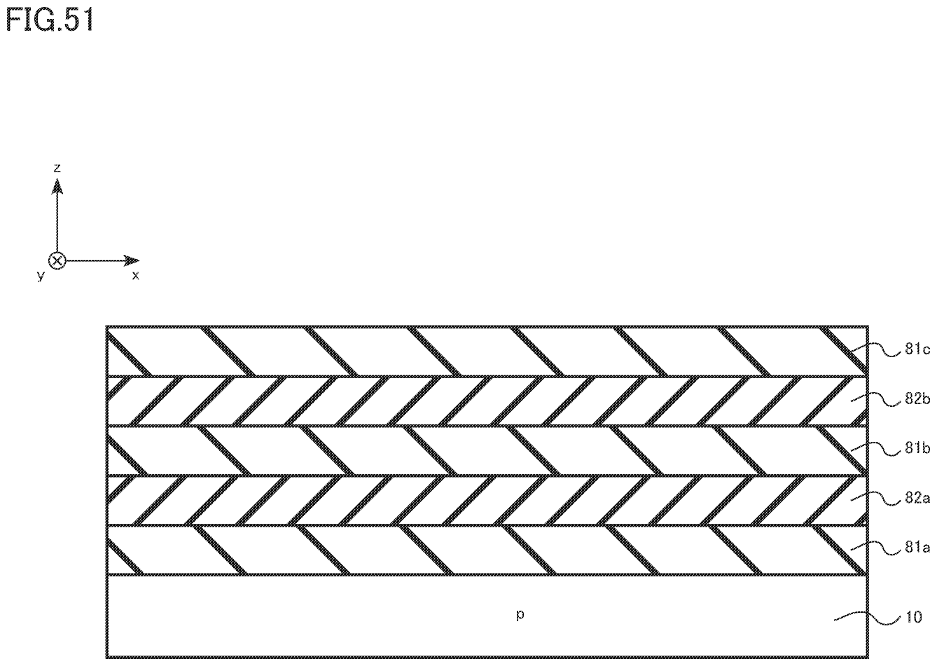

FIGS. 51, 52, 53, 54, 55, and 56 are schematic cross-sectional views illustrating the method for manufacturing the semiconductor memory device of the third embodiment.

First, a first silicon oxide film 81a, a first silicon nitride film 82a, a second silicon oxide film 81b, a second silicon nitride film 82b, and a third silicon oxide film 81c are formed in this order in the first direction of the single crystal silicon substrate 10 (FIG. 51).

The first silicon oxide film 81a is formed on a surface of the single crystal silicon substrate 10. The first silicon nitride film 82a is formed on the first silicon oxide film 81a. The second silicon oxide film 81b is formed on the first silicon nitride film 82a. The second silicon nitride film 82b is formed on the second silicon oxide film 81b. The third silicon oxide film 81c is formed on the second silicon nitride film 82b.

The first silicon oxide film 81a, the first silicon nitride film 82a, the second silicon oxide film 81b, the second silicon nitride film 82b, and the third silicon oxide film 81c are formed by, for example, a CVD method.

The first silicon oxide film 81a is an example of the first film. The first silicon nitride film 82a is an example of the second film. The second silicon oxide film 81b is an example of the third film.

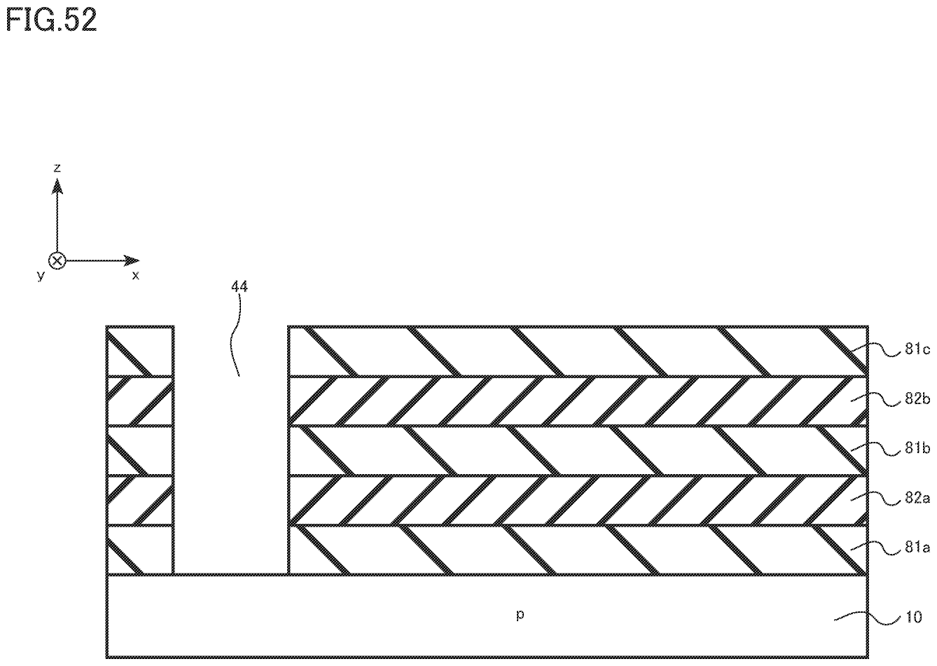

Next, the first opening 44 that penetrates the third silicon oxide film 81c, the second silicon nitride film 82b, the second silicon oxide film 81b, the first silicon oxide film 81a, and the first silicon oxide film 81a and reaches the single crystal silicon substrate 10 is formed (FIG. 52).

The first opening 44 is formed by, for example, a lithography method and a reactive ion etching method (RIE method).

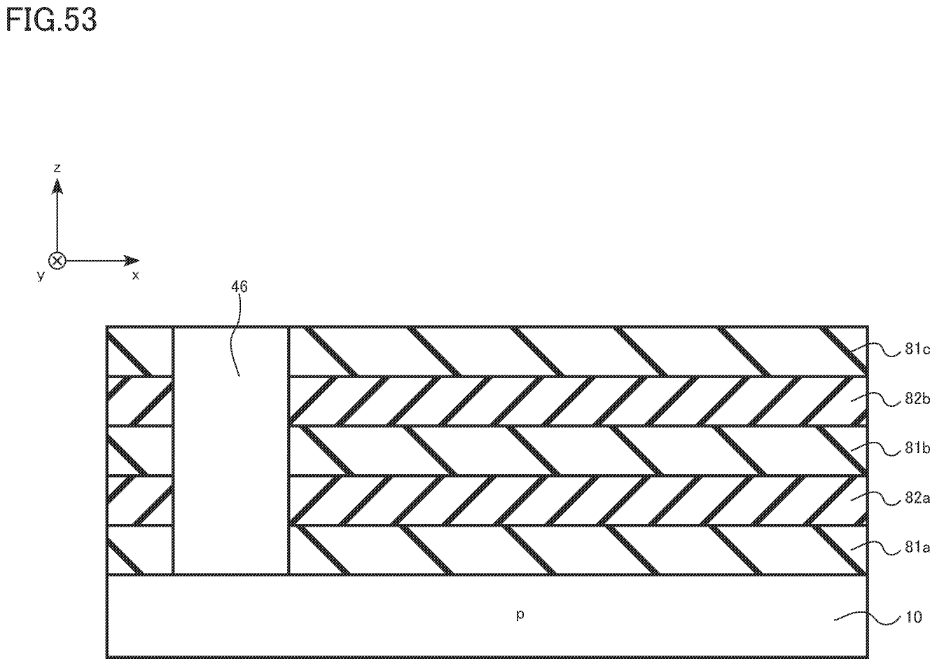

Next, the first single crystal silicon layer 46 in contact with the single crystal silicon substrate 10 is formed in the first opening 44 (FIG. 53). The first single crystal silicon layer 46 is formed using the single crystal silicon substrate 10 as a seed crystal. The first single crystal silicon layer 46 is, for example, non-doped single crystal silicon containing no conductive impurity.

The first single crystal silicon layer 46 is formed using, for example, a solid phase epitaxial growth method. In a case where the solid phase epitaxial growth method is used, for example, the first opening 44 is filled with an amorphous silicon layer. Thereafter, heat treatment is performed to form the single crystal silicon.

In addition, the first single crystal silicon layer 46 may be formed using, for example, a vapor phase epitaxial growth method.

In addition, the first single crystal silicon layer 46 may be formed using, for example, a VLS method. In a case where the VLS method is used, metal or a metal compound is formed as a catalyst, and single crystal silicon is formed using the catalyst as a nucleus. The catalyst is, for example, gold (Au), indium (In), tin (Sb), or indium tin oxide. The catalyst is formed using, for example, an ALD method, a CVD method, or a sputtering method.

Note that at least a part of the first single crystal silicon layer 46 is a single crystal. In the first single crystal silicon layer 46, for example, at least a portion in contact with the first silicon nitride film 82a and a portion in contact with the second silicon nitride film 82b are single crystals. The first single crystal silicon layer 46 may partially include, for example, crystal grains or crystal defects.

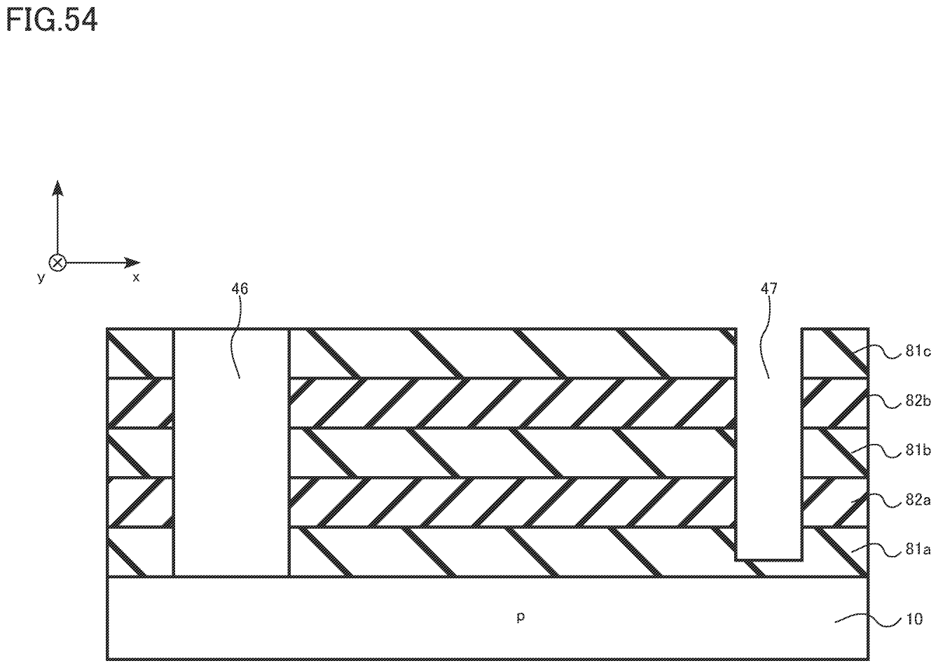

Next, the second opening 47 that penetrates the third silicon oxide film 81c, the second silicon nitride film 82b, the second silicon oxide film 81b, and the first silicon nitride film 82a is formed (FIG. 54). The surface of the single crystal silicon substrate 10 is not exposed at a bottom of the second opening 47.

The second opening 47 is formed by, for example, a lithography method and an RIE method.

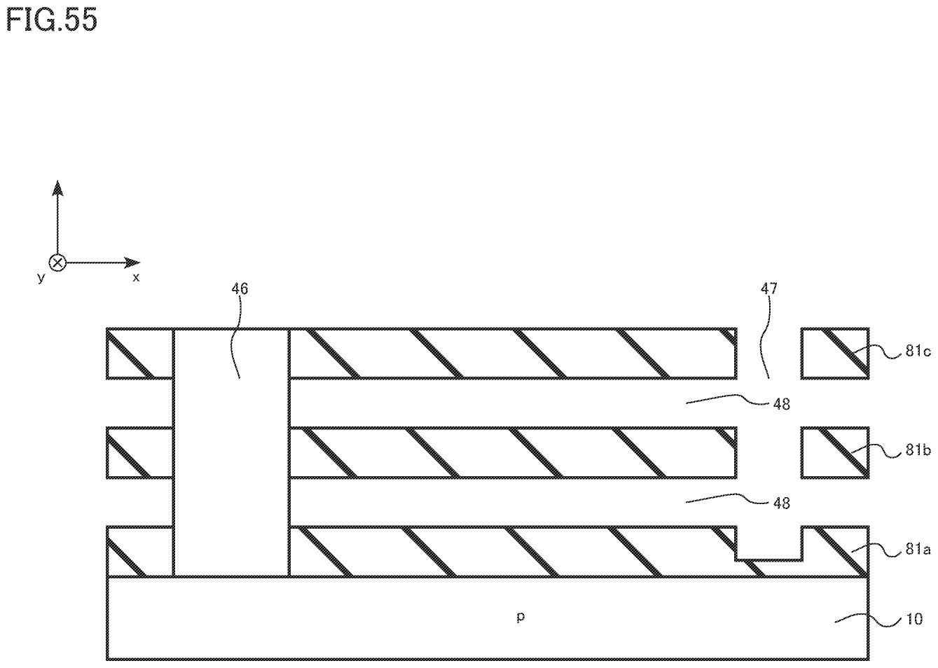

Next, the first silicon nitride film 82a and the second silicon nitride film 82b are selectively etched from the side face of the second opening 47 to form the first recesses 48 (FIG. 55). The first single crystal silicon layer 46 is exposed at depths of the first recesses 48. The first silicon nitride film 82a and the second silicon nitride film 82b are etched using, for example, a dry etching method or a wet etching method.

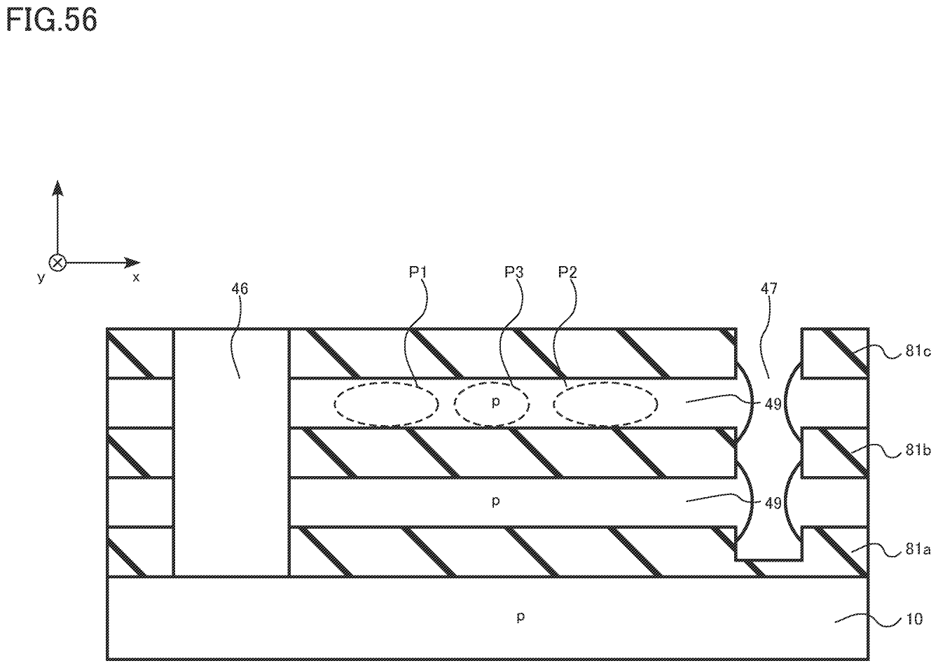

Next, the second single crystal silicon layer 49 in contact with the first single crystal silicon layer 46 is formed in each of the first recesses 48 (FIG. 56). The second single crystal silicon layer 49 is formed using the first single crystal silicon layer 46 as a seed crystal. The second single crystal silicon layer 49 is, for example, p-type single crystal silicon containing p-type impurities.

The second single crystal silicon layer 49 has the first portion P1, the second portion P2, and the third portion P3. The third portion P3 is provided between the first portion P1 and the second portion P2. A part of the second single crystal silicon layer 49 finally serves as the single crystal silicon layer 12.

The second single crystal silicon layer 49 is formed using, for example, a vapor phase epitaxial growth method.

The second single crystal silicon layer 49 is formed using, for example, a VLS method. In a case where the VLS method is used, metal or a metal compound is used as a catalyst, and single crystal silicon is formed using the catalyst as a nucleus. The catalyst is, for example, gold (Au), indium (In), tin (Sb), or indium tin oxide. Here, it is necessary to form the catalyst on an exposed surface of the first single crystal silicon layer 46 on sidewalls at the depth of the first recess 48, and thus the catalyst is selectively attached to the surface side of the exposed seed crystal silicon using, for example, an ALD method, a CVD method, or the like.

Note that at least a part of the second single crystal silicon layer 49 is a single crystal. In the second single crystal silicon layer 49, for example, at least the third portion P3 is a single crystal. The second single crystal silicon layer 49 may partially include, for example, crystal grains or crystal defects.

Thereafter, a wiring layer in contact with the first portion P1 of the second single crystal silicon layer 49 is formed. In addition, a capacitor in contact with the second portion P2 of the second single crystal silicon layer 49 is formed. In addition, a gate electrode layer facing the third portion P3 between the first portion P1 and the second portion P2 of the second single crystal silicon layer 49 is formed. Note that the order of forming the wiring layer, the capacitor, and the gate electrode layer is freely selected.

A memory cell array of the DRAM of the third embodiment is formed by the above manufacturing method.

According to the method for manufacturing the DRAM of the third embodiment, the DRAM having the three-dimensional structure with stable characteristics can be manufactured in a short manufacturing time similarly to the method for manufacturing the DRAM of the first embodiment.

### Modified Example

A method for manufacturing a DRAM of a modified example of the third embodiment is different from the method for manufacturing the DRAM of the third embodiment in that the second material is amorphous silicon. According to the method for manufacturing the DRAM of the modified example of the third embodiment, the DRAM having a three-dimensional structure with stable characteristics can be manufactured in a short manufacturing time similarly to the method for manufacturing the DRAM of the third embodiment.

As described above, according to the third embodiment and the modified example, it is possible to realize high integration of the semiconductor memory device.

### Fourth Embodiment

A method for manufacturing a semiconductor memory device of a fourth embodiment includes: forming a first film of a first material in a first direction of a single crystal silicon substrate; forming a second film of a second material different from the first material in the first direction of the first film, the second material being amorphous silicon having a first hydrogen concentration; forming a third film of a third material different from the second material in the first direction of the second film; forming a first opening penetrating the third film, the second film, and the first film and reaching the single crystal silicon substrate; forming an amorphous silicon layer in contact with the single crystal silicon substrate and the second film in the first opening, the amorphous silicon layer having a second hydrogen concentration lower than the first hydrogen concentration; performing first heat treatment at a first temperature to form a first single crystal silicon layer from the amorphous silicon layer by single-crystallizing the amorphous silicon layer by solid phase epitaxial growth; performing second heat treatment at a second temperature higher than the first temperature to form a second single crystal silicon layer from the second film by single-crystallizing the second film by solid phase; forming a wiring layer in contact with a first portion of the second single crystal silicon layer; forming a capacitor in contact with a second portion of the second single crystal silicon layer; and forming a gate electrode layer facing a third portion of the second single crystal silicon layer between the first portion and the second portion.

The method for manufacturing the semiconductor memory device of the fourth embodiment is a manufacturing method for manufacturing the semiconductor memory device of the first embodiment. The method for manufacturing the semiconductor memory device of the fourth embodiment is different from the method for manufacturing the semiconductor memory device of the first embodiment in that the second single crystal silicon layer is formed using a solid phase epitaxial growth method. Hereinafter, some of the content overlapping with that in the first embodiment will not be described in some cases.

Hereinafter, an example of the method for manufacturing the semiconductor memory device of the fourth embodiment will be described.

In the example of the method for manufacturing the semiconductor memory device of the fourth embodiment, a fourth film of a fourth material different from the second material and the third material, is formed between the second film and the third film, the first single crystal silicon layer in the first opening is removed after the forming the second single crystal silicon layer, and the fourth film is etched from a side face of the first opening to form a recess after the removing the first single crystal silicon layer. The wiring layer is formed in the recess.

Hereinafter, a case where the first material is silicon oxide, the second material is amorphous silicon, the third material is silicon oxide, and the fourth material is silicon nitride will be described as an example. In this case, the first material and the third material are the same material.

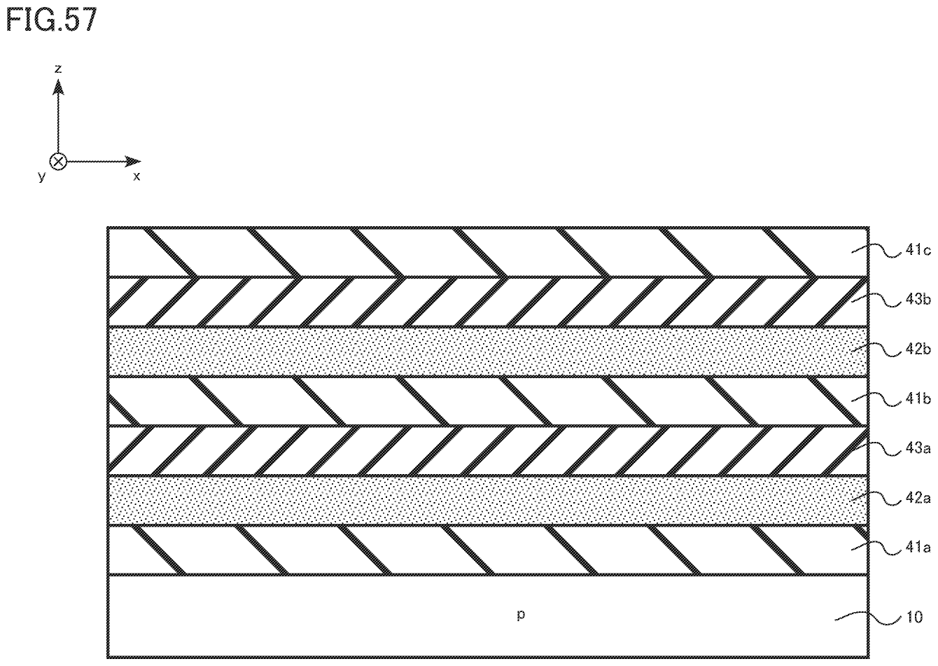

FIGS. 57, 58, 59, 60, 61, 62, 63, 64, 65, 66, 67, 68, 69, 70, and 71 are schematic cross-sectional views illustrating the method for manufacturing the semiconductor memory device of the fourth embodiment.

FIGS. 57 to 71 are cross sections corresponding to FIG. 2 of the first embodiment. FIGS. 57 to 71 are xz cross sections.

First, the first silicon oxide film 41a, the first amorphous silicon film 42a, the first silicon nitride film 43a, the second silicon oxide film 41b, the second amorphous silicon film 42b, the second silicon nitride film 43b, and the third silicon oxide film 41c are formed in this order in the first direction of the single crystal silicon substrate 10 (FIG. 57).

The first silicon oxide film 41a is formed on the surface of the single crystal silicon substrate 10. The first amorphous silicon film 42a is formed on the first silicon oxide film 41a. The first silicon nitride film 43a is formed on the first amorphous silicon film 42a. The second silicon oxide film 41b is formed on the first silicon nitride film 43a. The second amorphous silicon film 42b is formed on the second silicon oxide film 41b. The second silicon nitride film 43b is formed on the second amorphous silicon film 42b. The third silicon oxide film 41c is formed on the second silicon nitride film 43b.

The first silicon oxide film 41a, the first amorphous silicon film 42a, the first silicon nitride film 43a, the second silicon oxide film 41b, the second amorphous silicon film 42b, the second silicon nitride film 43b, and the third silicon oxide film 41c are formed by, for example, a chemical vapor deposition method (CVD method).

The first silicon oxide film 41a is an example of the first film. The first amorphous silicon film 42a is an example of the second film. The second silicon oxide film 41b is an example of the third film. The first silicon nitride film 43a is an example of the fourth film.

A part of each of the first silicon oxide film 41a, the second silicon oxide film 41b, and the third silicon oxide film 41c finally serves as the first interlayer insulating layer 28. In addition, a part of each of the first silicon nitride film 43a and the second silicon nitride film 43b finally serves as the second interlayer insulating layer 30. A part of each of the first amorphous silicon film 42a and the second amorphous silicon film 42b finally serves as the single crystal silicon layer 12.

Note that each of the first amorphous silicon film 42a and the second amorphous silicon film 42b is patterned into a plurality of regions so as to be divided in the third direction by a method (not illustrated).

The amorphous silicon as the second material for forming the first amorphous silicon film 42a and the second amorphous silicon film 42b contains hydrogen. The amorphous silicon as the second material may or may not contain carbon.

The amorphous silicon as the second material has the first hydrogen concentration. The first hydrogen concentration is, for example, equal to or more than 1E20 cm⁻³ and equal to or less than 1E22 cm⁻³. The amorphous silicon as the second material has a first carbon concentration. The amorphous silicon as the second material contains, for example, boron (B) as a p-type impurity.

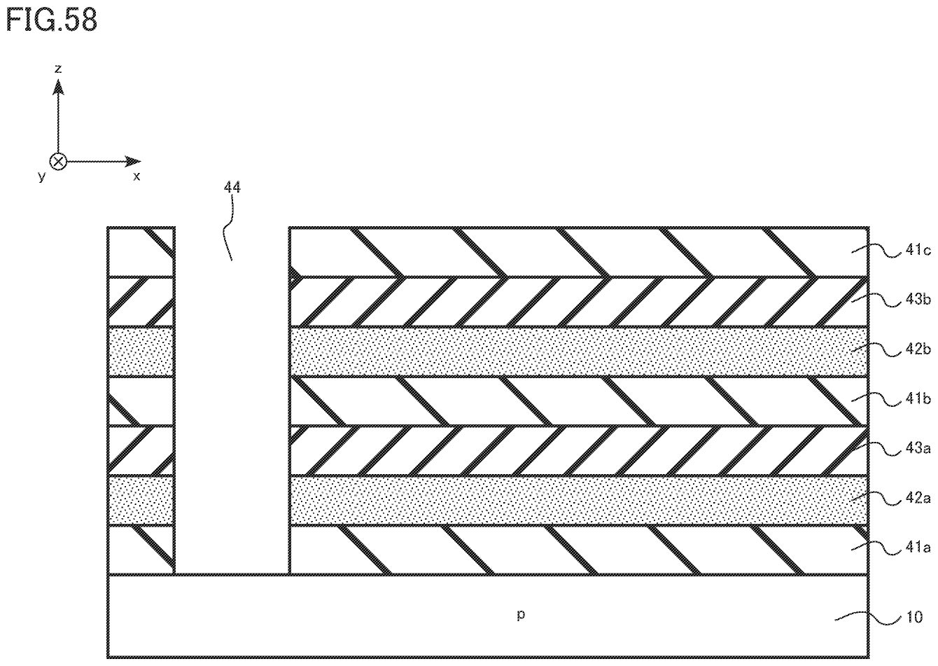

The first amorphous silicon film 42a and the second amorphous silicon film 42b are formed by, for example, a plasma enhanced CVD (PECVD) method. Amorphous silicon having a relatively high hydrogen concentration can be formed by the PECVD method. The first amorphous silicon film 42a and the second amorphous silicon film 42b are formed by, for example, a PECVD method at 300° C. to 550° C. Next, the first opening 44 that penetrates the third silicon oxide film 41c, the second silicon nitride film 43b, the second amorphous silicon film 42b, the second silicon oxide film 41b, the first silicon nitride film 43a, the first amorphous silicon film 42a, and the first silicon oxide film 41a and reaches the single crystal silicon substrate 10 is formed (FIG. 58).

The first opening 44 is formed by, for example, a lithography method and a reactive ion etching method (RIE method).

Next, etching damage and a native oxide film at the time of forming the first opening 44, which are formed on a surface of the single crystal silicon substrate 10 exposed at a bottom of the first opening 44, a surface of the first amorphous silicon film 42a exposed at a side face of the first opening 44, and a surface of the second amorphous silicon film 42b exposed at the side face of the first opening 44, are removed by pretreatment.

Since the etching damage and the native oxide film at the time of forming the first opening 44 are removed, an amorphous silicon layer 46x, to be single-crystallized later by solid phase epitaxial growth, and the single crystal silicon substrate 10 which serves as a seed crystal are favorably bonded. In addition, since the etching damage and the native oxide film at the time of forming the first opening 44 are removed, the first amorphous silicon film 42a and the second amorphous silicon film 42b, to be single-crystallized later by solid phase epitaxial growth, and the first single crystal silicon layer 46 which serves as a seed crystal are favorably bonded.

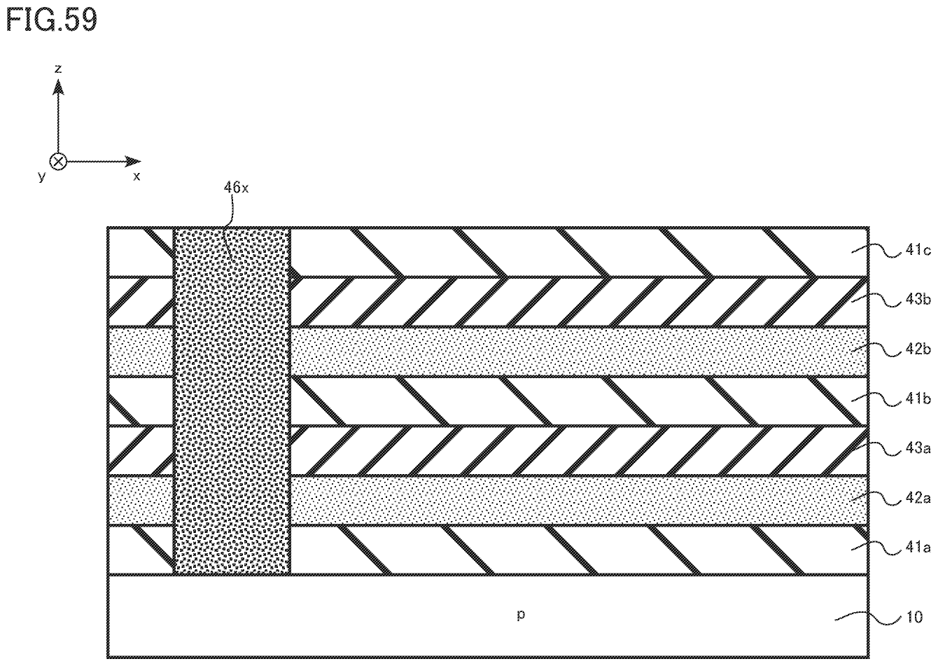

Next, the amorphous silicon layer 46x in contact with the single crystal silicon substrate 10, the first amorphous silicon film 42a, and the second amorphous silicon film 42b is formed in the first opening 44 (FIG. 59). For example, the first opening 44 is filled with the amorphous silicon layer 46x.

The amorphous silicon layer 46x contains hydrogen. The amorphous silicon layer 46x may or may not contain carbon.

The amorphous silicon layer 46x has the second hydrogen concentration. The second hydrogen concentration is lower than the first hydrogen concentration of the amorphous silicon as the second material. The second hydrogen concentration is, for example, equal to or more than 1E17 cm⁻³ and less than 1E20 cm⁻³.

The amorphous silicon layer 46x has a second carbon concentration. The second carbon concentration is, for example, lower than the first carbon concentration of the amorphous silicon as the second material. The amorphous silicon layer 46x is, for example, non-doped amorphous silicon containing no conductive impurity.

The amorphous silicon layer 46x is formed by, for example, a thermal CVD method or a thermal ALD method. Amorphous silicon having a relatively low hydrogen concentration can be formed by the thermal CVD method or the thermal ALD method. The amorphous silicon layer 46x is formed by, for example, a thermal CVD method at 450° C. to 530° C.

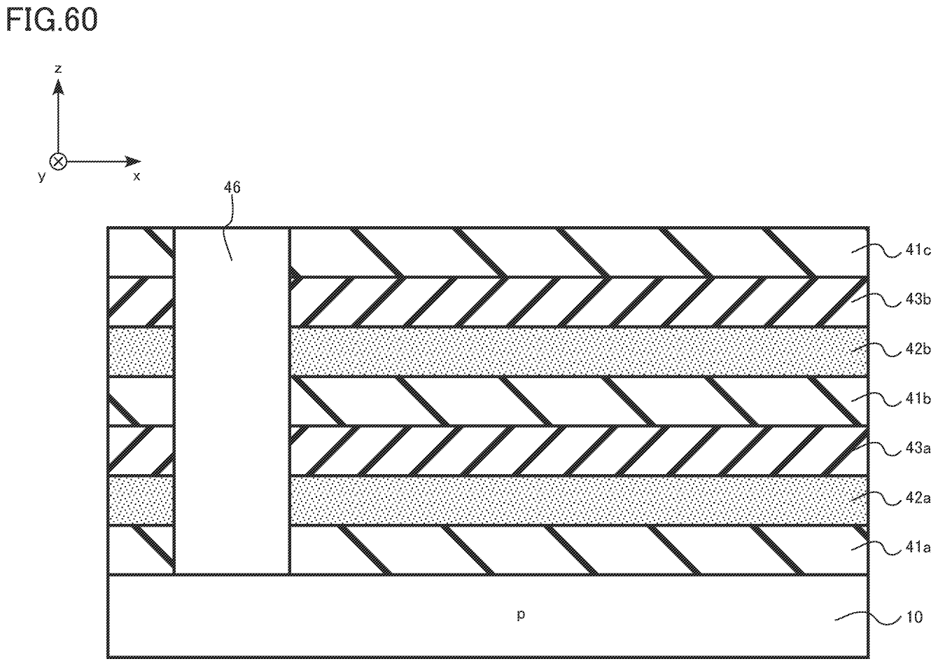

Next, the first heat treatment is performed to single-crystallize the amorphous silicon layer 46x by solid phase epitaxial growth, thereby forming the first single crystal silicon layer 46 (FIG. 60). The amorphous silicon layer 46x is single-crystallized using the single crystal silicon substrate 10 as the seed crystal.

Note that at least a part of the amorphous silicon layer 46x is single-crystallized by the first heat treatment. For example, in the amorphous silicon layer 46x, at least a portion in contact with the first amorphous silicon film 42a and a portion in contact with the second amorphous silicon film 42b are single-crystallized by the first heat treatment.

At least a part of the first single crystal silicon layer 46 is a single crystal. In the first single crystal silicon layer 46, for example, at least a portion in contact with the first amorphous silicon film 42a and a portion in contact with the second amorphous silicon film 42b are single crystals. The first single crystal silicon layer 46 may partially include, for example, crystal grains or crystal defects.

The first heat treatment is performed at the first temperature. The first temperature is, for example, equal to or higher than 550° C. and equal to or lower than 650° C.

The first heat treatment is performed, for example, in a non-oxidizing atmosphere. The first heat treatment is performed, for example, in a nitrogen gas atmosphere or an argon gas atmosphere.

In the first heat treatment, the first amorphous silicon film 42a and the second amorphous silicon film 42b are not single-crystallized. Since the first amorphous silicon film 42a and the second amorphous silicon film 42b have the first hydrogen concentration higher than the second hydrogen concentration of the amorphous silicon layer 46x, the temperature for single crystallization of amorphous silicon is high so that the single crystallization is suppressed. In addition, also in a case where the first amorphous silicon film 42a and the second amorphous silicon film 42b have the first carbon concentration higher than the second carbon concentration of the amorphous silicon layer 46x, the temperature for single crystallization of amorphous silicon of the first amorphous silicon film 42a and the second amorphous silicon film 42b is similarly high so that the single crystallization is suppressed.

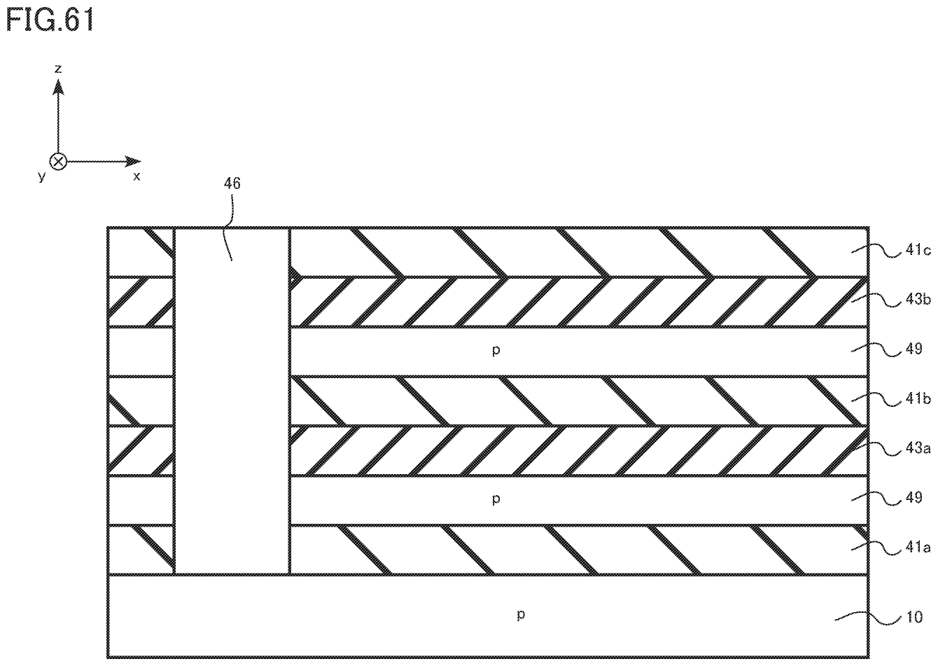

Next, the second heat treatment is performed to single-crystallize the first amorphous silicon film 42a and the second amorphous silicon film 42b by solid phase epitaxial growth, thereby forming the second single crystal silicon layer 49 (FIG. 61). The first amorphous silicon film 42a and the second amorphous silicon film 42b are single-crystallized using the first single crystal silicon layer 46 as the seed crystal.

The second single crystal silicon layer 49 is, for example, p-type single crystal silicon containing p-type impurities. The p-type impurities are impurities doped in the first amorphous silicon film 42a and the second amorphous silicon film 42b at the time of forming the first amorphous silicon film 42a and the second amorphous silicon film 42b.

Note that at least a part of the first amorphous silicon film 42a and at least a part of the second amorphous silicon film 42b are single-crystallized by the second heat treatment. For example, at least a portion where the p-type impurity region 12c is to be finally formed in each of the first amorphous silicon film 42a and the second amorphous silicon film 42b is single-crystallized by the second heat treatment.

At least a part of the second single crystal silicon layer 49 is a single crystal. In the second single crystal silicon layer 49, for example, at least a portion where the p-type impurity region 12c is to be finally formed is a single crystal. The second single crystal silicon layer 49 may partially include, for example, crystal grains or crystal defects.

The second heat treatment is performed at the second temperature. The second temperature is higher than the first temperature for forming the first single crystal silicon layer 46. The second temperature is, for example, higher than 650° C. and equal to or lower than 800° C.

The second heat treatment is performed, for example, in a non-oxidizing atmosphere. The second heat treatment is performed, for example, in a nitrogen gas atmosphere or an argon gas atmosphere.

Since the second heat treatment is performed at the temperature higher than that of the first heat treatment, the single crystallization of each of the first amorphous silicon film 42a and the second amorphous silicon film 42b having a high hydrogen concentration proceeds. Note that the temperature of the first heat treatment and the temperature of the second heat treatment can be changed depending on the hydrogen concentration of the first amorphous silicon film 42a and the hydrogen concentration of the second amorphous silicon film 42b. Therefore, for example, the temperature of the first heat treatment may be set to a temperature higher than the temperature range of the first heat treatment exemplified above, and the temperature of the second heat treatment may be set to a temperature higher than the temperature range of the second heat treatment exemplified above. A part of the second single crystal silicon layer 49 finally serves as the single crystal silicon layer 12 illustrated in FIGS. 2 and 3 in the first embodiment.

The hydrogen concentration of the first single crystal silicon layer 46 is, for example, equal to or lower than the hydrogen concentration of the amorphous silicon layer 46x. The hydrogen concentration of the second single crystal silicon layer 49 is, for example, equal to or lower than the hydrogen concentration of the first amorphous silicon film 42a and the hydrogen concentration of the second amorphous silicon film 42b. The hydrogen concentration of the first single crystal silicon layer 46 is, for example, lower than the hydrogen concentration of the second single crystal silicon layer 49. The hydrogen concentration of the single crystal silicon layer 12 thus finally formed is, for example, equal to or lower than the hydrogen concentration of the first amorphous silicon film 42a and the hydrogen concentration of the second amorphous silicon film 42b.

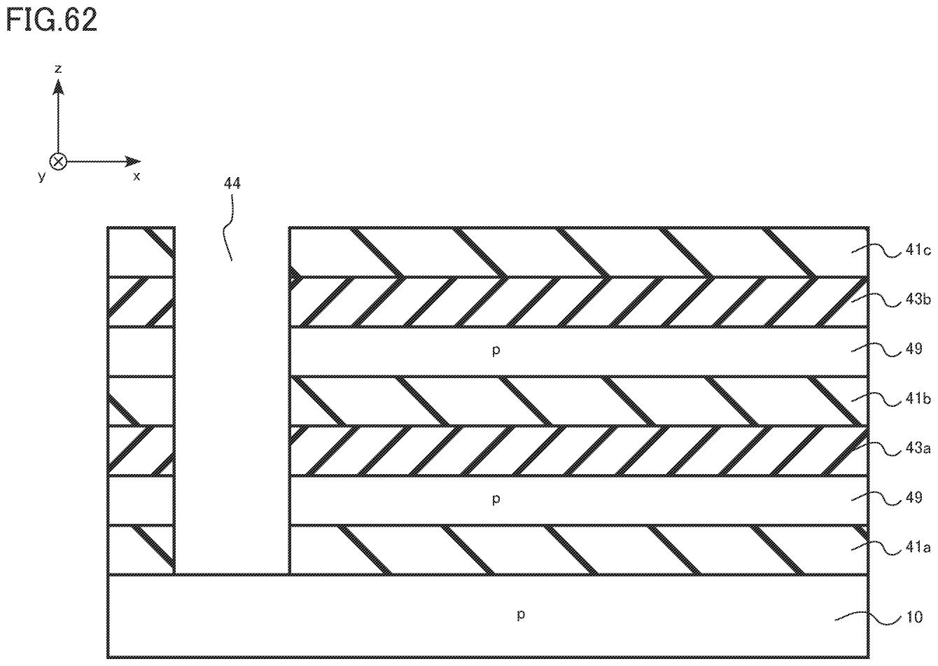

Next, the first single crystal silicon layer 46 in the first opening 44 is removed (FIG. 62). The first single crystal silicon layer 46 is removed by, for example, a dry etching method or a wet etching method.

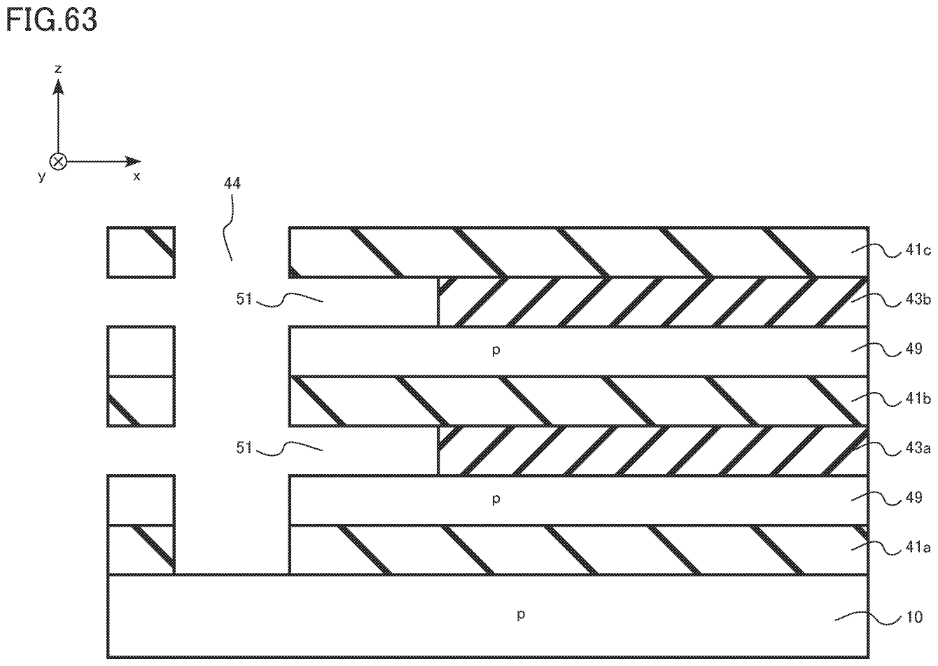

Next, a part of the first silicon nitride film 43a and a part of the second silicon nitride film 43b are etched from the side face of the first opening 44 to form the second recesses 51 (FIG. 63). The first silicon nitride film 43a and the second silicon nitride film 43b are removed by, for example, a wet etching method. The second recess 51 is an example of the recess.

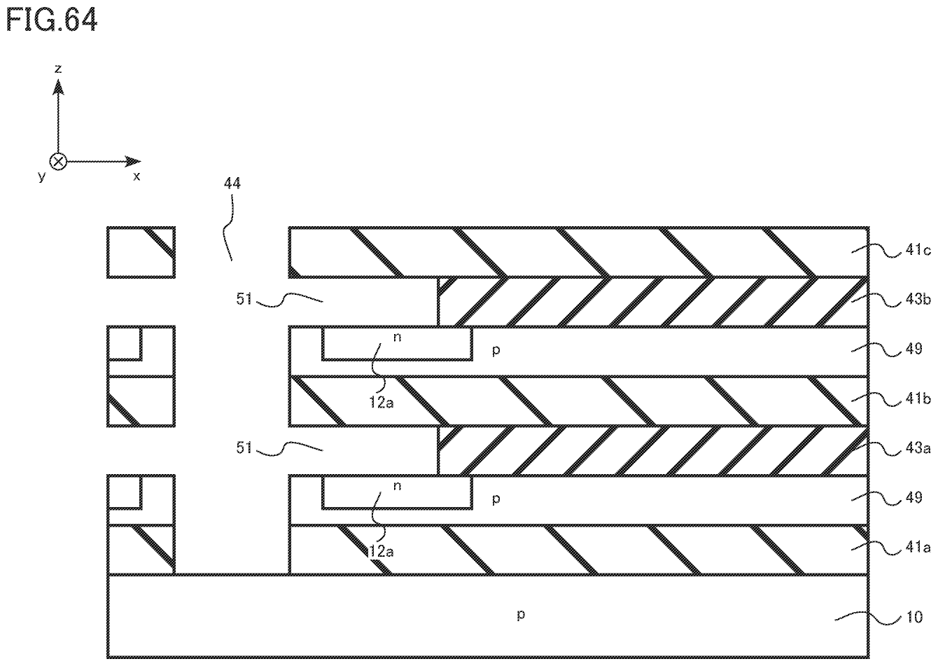

Next, the first n-type impurity region 12a is formed in the second single crystal silicon layer 49 (FIG. 64). The first n-type impurity region 12a is formed using, for example, a vapor phase diffusion method.

For example, a mask material (not illustrated) that covers corners of the second single crystal silicon layer 49 or the surface of the single crystal silicon substrate 10 at the bottom of the first opening 44 is used to form the first n-type impurity region 12a.

The n-type impurities introduced into the first n-type impurity region 12a are activated by, for example, heat treatment at a high temperature for a short time.

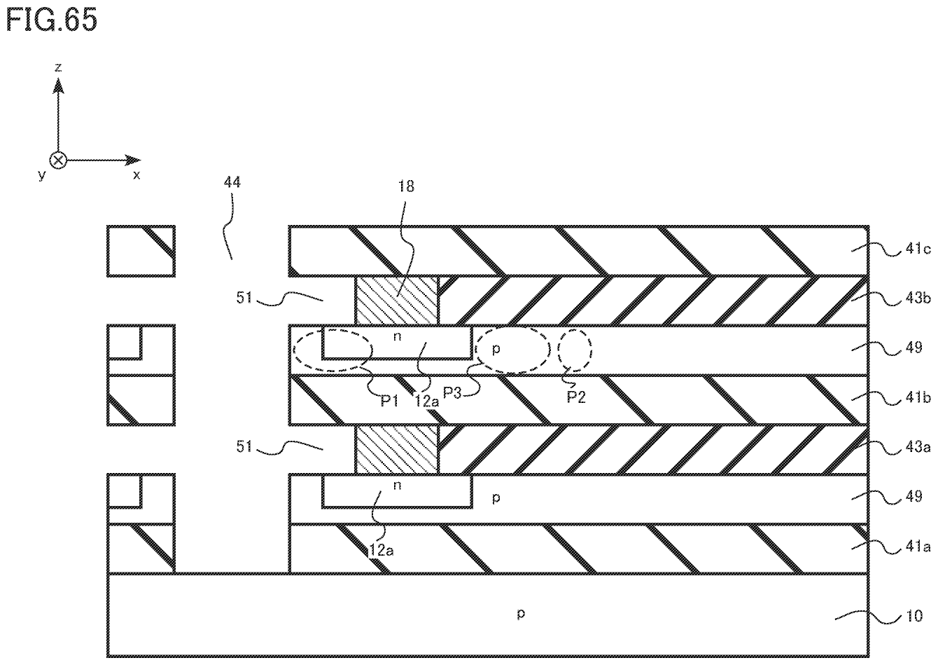

Next, the wiring layer 18 is formed in the second recess 51 (FIG. 65). The wiring layer 18 is in contact with the first portion P1 of the second single crystal silicon layer 49. The wiring layer 18 is in contact with the first n-type impurity region 12a. The wiring layer 18 is formed in the second recess 51 using, for example, a CVD method and a dry etching method.

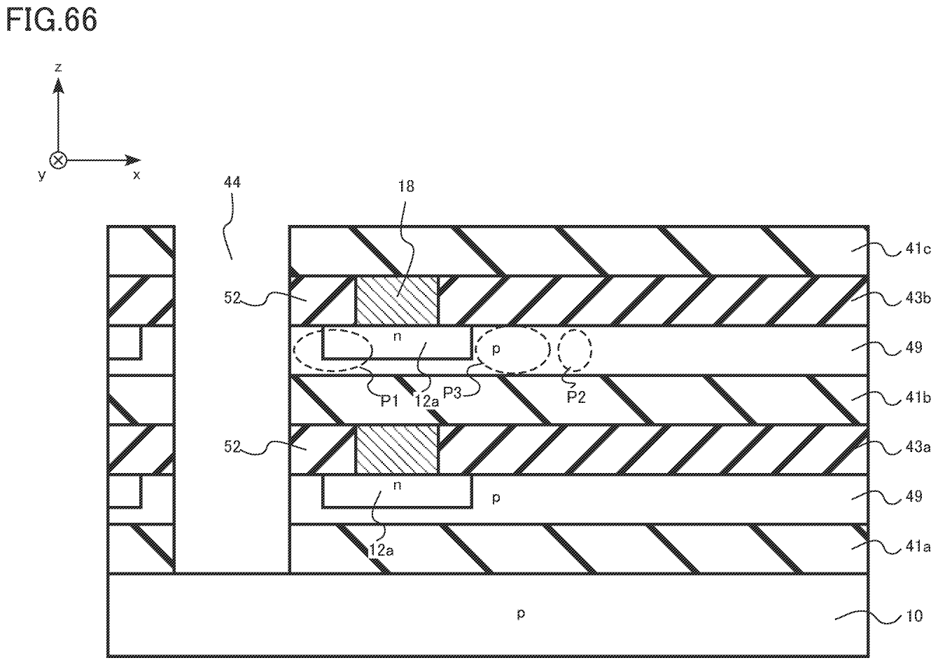

Next, the second recess 51 is filled with the silicon oxide film 52 (FIG. 66). The second recess 51 is filled with the silicon oxide film 52 using, for example, a CVD method and a dry etching method.

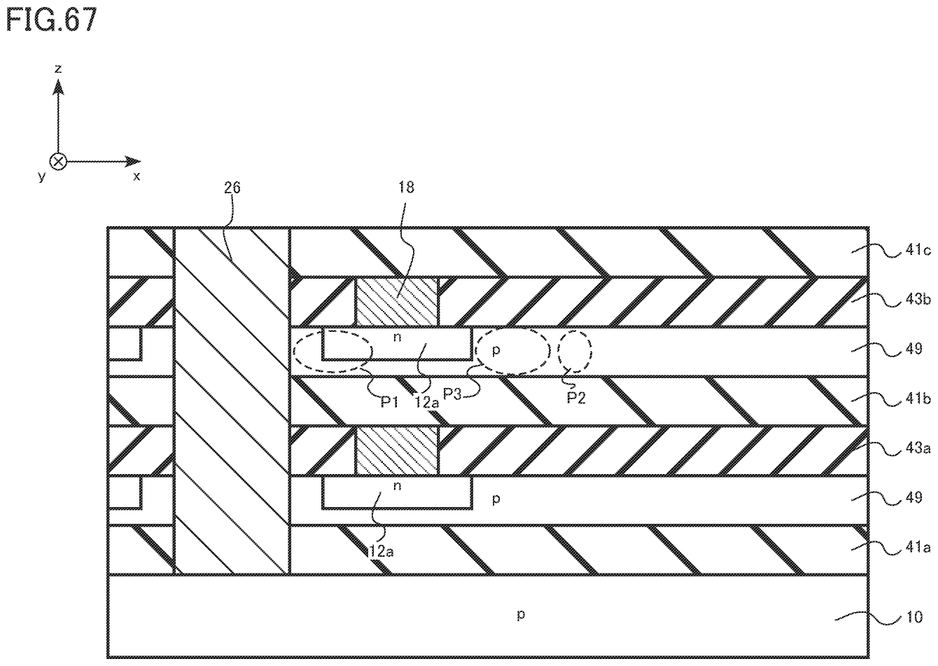

Next, the contact electrode 26 is formed in the first opening 44 (FIG. 67). The contact electrode 26 is formed by, for example, a CVD method.

Thereafter, grooves sandwiching the second single crystal silicon layer 49 in the third direction and extending in the first direction are formed by a method (not illustrated). The gate insulating film 16 and the gate electrode layer 14 extending in the first direction are formed using the formed groove. The gate electrode layer 14 is formed so as to be facing the third portion P3 of the second single crystal silicon layer 49.

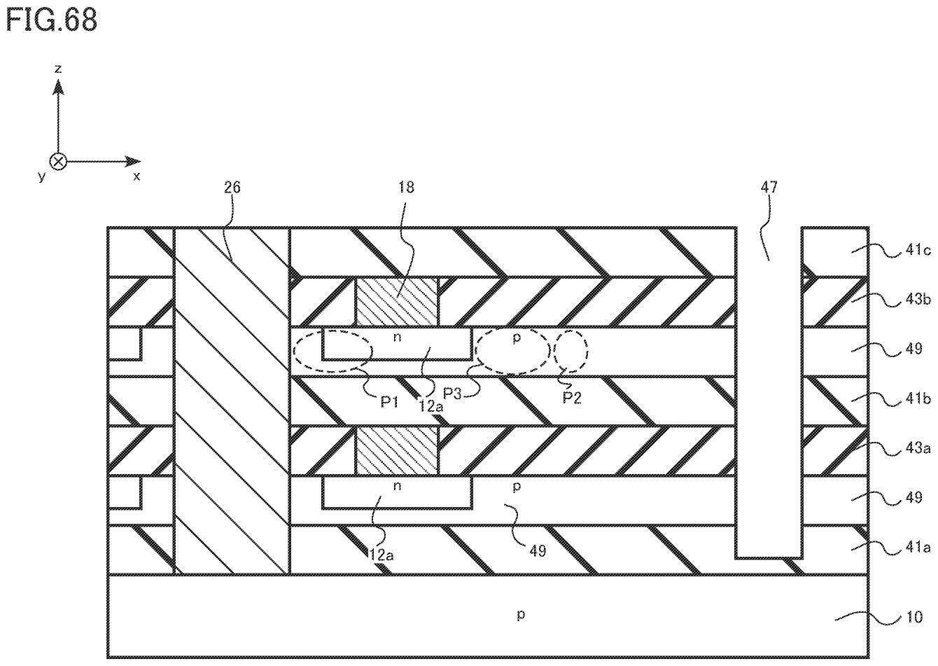

Next, the second opening 47 that penetrates the third silicon oxide film 41c, the second silicon nitride film 43b, the second single crystal silicon layer 49, the second silicon oxide film 41b, the first silicon nitride film 43a, and the second single crystal silicon layer 49 is formed (FIG. 68). The surface of the single crystal silicon substrate 10 is not exposed at a bottom of the second opening 47.

The second opening 47 is formed by, for example, a lithography method and an RIE method.

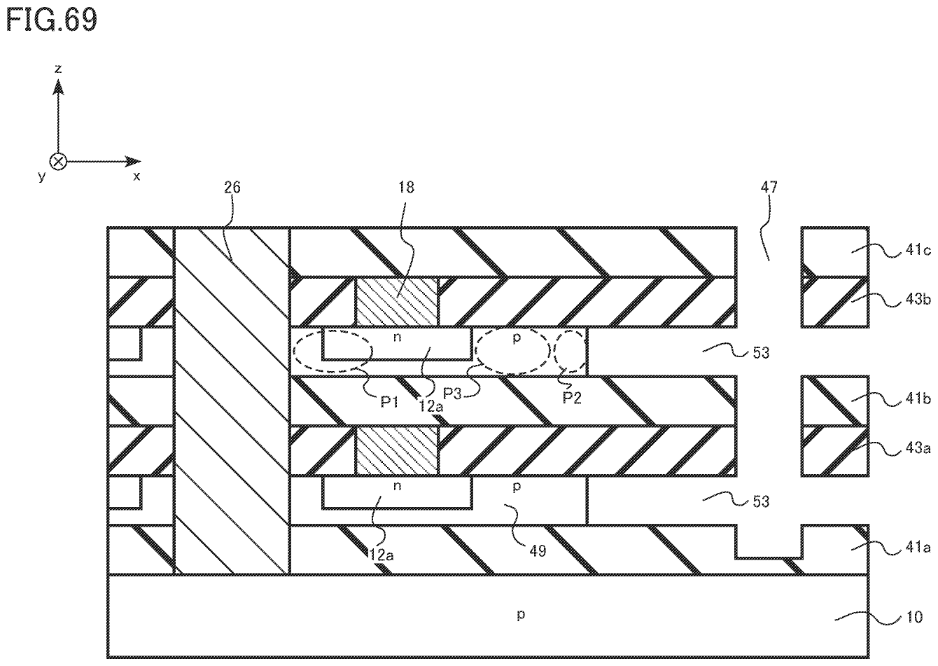

Next, the second single crystal silicon layers 49 are selectively etched from the side face of the second opening 47 to form the third recesses 53 (FIG. 69). The second single crystal silicon layers 49 are etched using, for example, a dry etching method or a wet etching method.

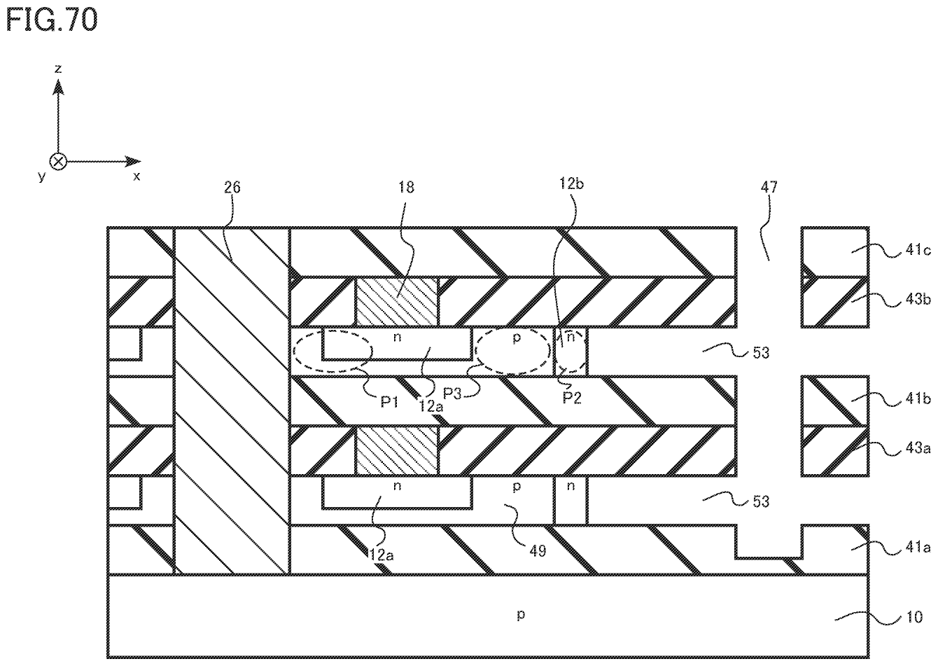

Next, the second n-type impurity region 12b is formed in the second portion P2 of the second single crystal silicon layer 49 (FIG. 70). The second n-type impurity region 12b is formed using, for example, a vapor phase diffusion method.

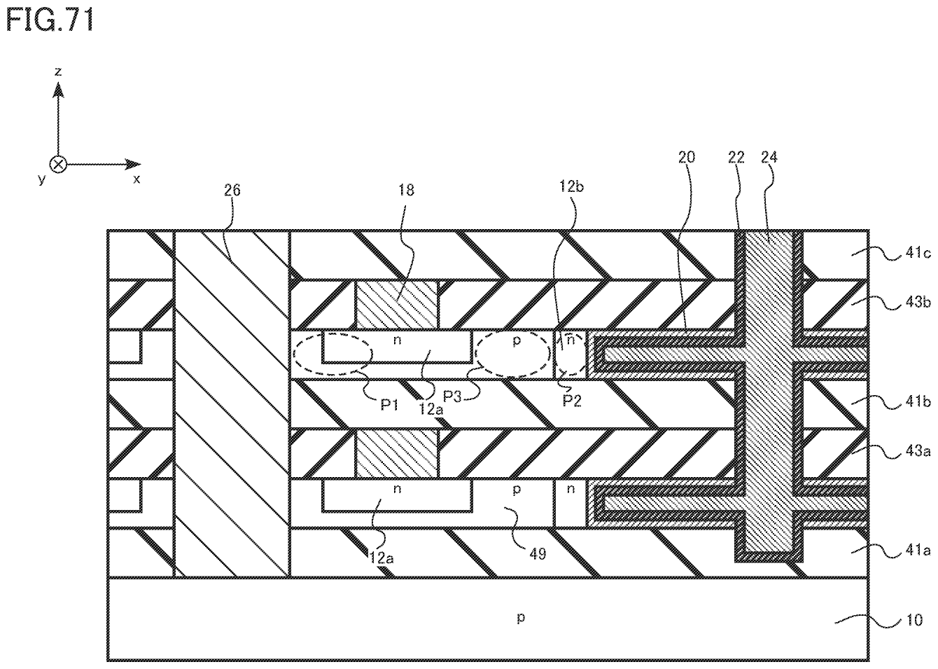

Next, the storage node electrode 20, the capacitor insulating film 22, and the plate electrode 24 are formed in each of the third recesses 53 (FIG. 71). The storage node electrode 20 is in contact with the second portion P2 of the second single crystal silicon layer 49. The capacitor CA including the storage node electrode 20, the capacitor insulating film 22, and the plate electrode 24 is in contact with the second portion P2 of the second single crystal silicon layer 49. The storage node electrode 20, the capacitor insulating film 22, and the plate electrode 24 are formed using, for example, a CVD method.

The memory cell array 101 of the DRAM of the first embodiment is formed by the above manufacturing method.

Next, a function and an effect of the method for manufacturing the semiconductor memory device of the fourth embodiment will be described.

In the method for manufacturing the DRAM of the fourth embodiment, a plurality of the second single crystal silicon layers 49 stacked in the first direction are simultaneously formed using the first single crystal silicon layer 46 as the seed crystal. Therefore, the uniformity of the plurality of single crystal silicon layers 12 stacked in the first direction is improved. In addition, a manufacturing time for forming the single crystal silicon layer 12 is shortened.

In addition, in the method for manufacturing the DRAM of the fourth embodiment, the formation of the first single crystal silicon layer 46 and the formation of the second single crystal silicon layer 49 are performed in different steps. As compared with a case where the formation of the first single crystal silicon layer 46 and the formation of the second single crystal silicon layer 49 are performed in the same step, the uniformity of growth in the second direction of the plurality of second single crystal silicon layers 49 stacked in the first direction is improved.

Therefore, according to the method for manufacturing the DRAM of the fourth embodiment, the DRAM having the three-dimensional structure with stable characteristics can be manufactured in a short manufacturing time.

Furthermore, in the method for manufacturing the DRAM of the fourth embodiment, the single crystal silicon layer 12 is formed by solid phase epitaxial growth while the first amorphous silicon film 42a and the second amorphous silicon film 42b are not recessed by etching or the like but are maintained as a structure, which is different from the method for manufacturing the DRAM of each of the first to third embodiments. For this reason, a pattern serving as a support, which is required in the case of forming the recesses, such as a beam for maintaining the entire structure is unnecessary. Therefore, for example, the device area can be reduced.

Note that a method for forming the first single crystal silicon layer 46 and a method for forming the second single crystal silicon layer 49 may be the same process method or different process methods.

The first single crystal silicon layer 46 may be formed by another method other than the solid phase epitaxial growth method. The first single crystal silicon layer 46 may be formed using, for example, a vapor phase epitaxial growth method.

Furthermore, as still another method, the first single crystal silicon layer 46 may be formed using, for example, a vapor-liquid-solid method (VLS method). In a case where the VLS method is used, metal or a metal compound is formed as a catalyst, and single crystal silicon is formed by vapor phase epitaxial growth using the catalyst as a nucleus. The catalyst is, for example, gold (Au), indium (In), tin (Sb), or indium tin oxide. The catalyst is grown on the bottom of the first opening 44 in FIG. 58, and is formed using, for example, an atomic layer deposition method (ALD method), a CVD method, or a sputtering method. The VLS method enables fast seed crystal growth.

(Modified Example) A method for manufacturing a semiconductor memory device of a modified example of the fourth embodiment is different from the method for manufacturing the semiconductor memory device of the fourth embodiment in that the first opening is not completely filled with the amorphous silicon layer.

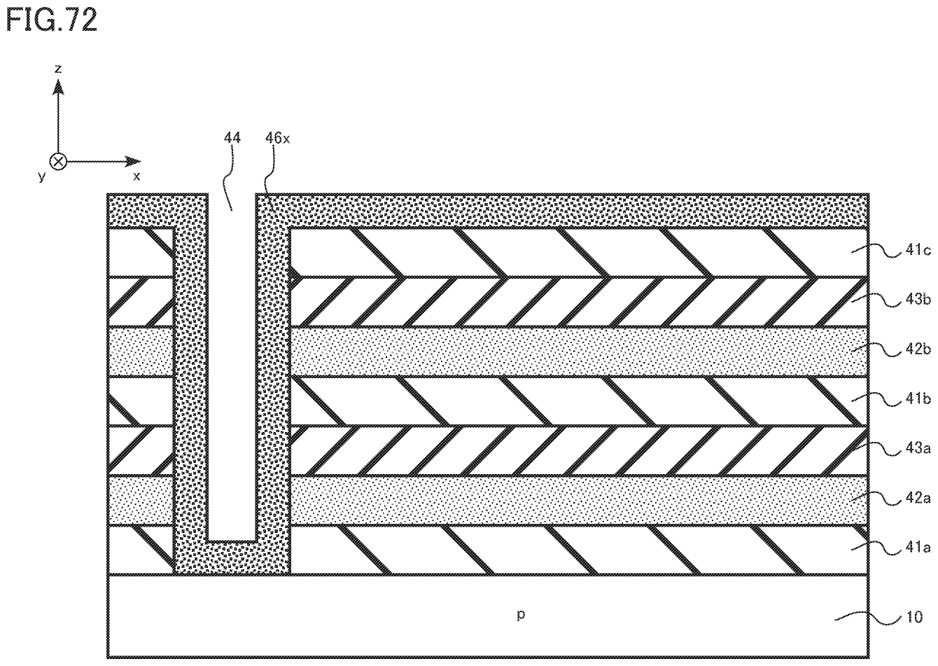

FIGS. 72, 73, and 74 are schematic cross-sectional views illustrating the method for manufacturing the semiconductor memory device according to the modified example of the fourth embodiment.

FIGS. 72 to 74 are cross sections corresponding to FIG. 2 of the first embodiment. FIGS. 72 to 74 are xz cross sections.

First, the first silicon oxide film 41a, the first amorphous silicon film 42a, the first silicon nitride film 43a, the second silicon oxide film 41b, the second amorphous silicon film 42b, the second silicon nitride film 43b, and the third silicon oxide film 41c are formed in this order in the first direction of the single crystal silicon substrate 10.

Next, the first opening 44 that penetrates the third silicon oxide film 41c, the second silicon nitride film 43b, the second amorphous silicon film 42b, the second silicon oxide film 41b, the first silicon nitride film 43a, the first amorphous silicon film 42a, and the first silicon oxide film 41a and reaches the single crystal silicon substrate 10 is formed.

Next, the amorphous silicon layer 46x in contact with the single crystal silicon substrate 10, the first amorphous silicon film 42a, and the second amorphous silicon film 42b is formed in the first opening 44 (FIG. 72). The amorphous silicon layer 46x is formed so as not to completely fill the first opening 44.

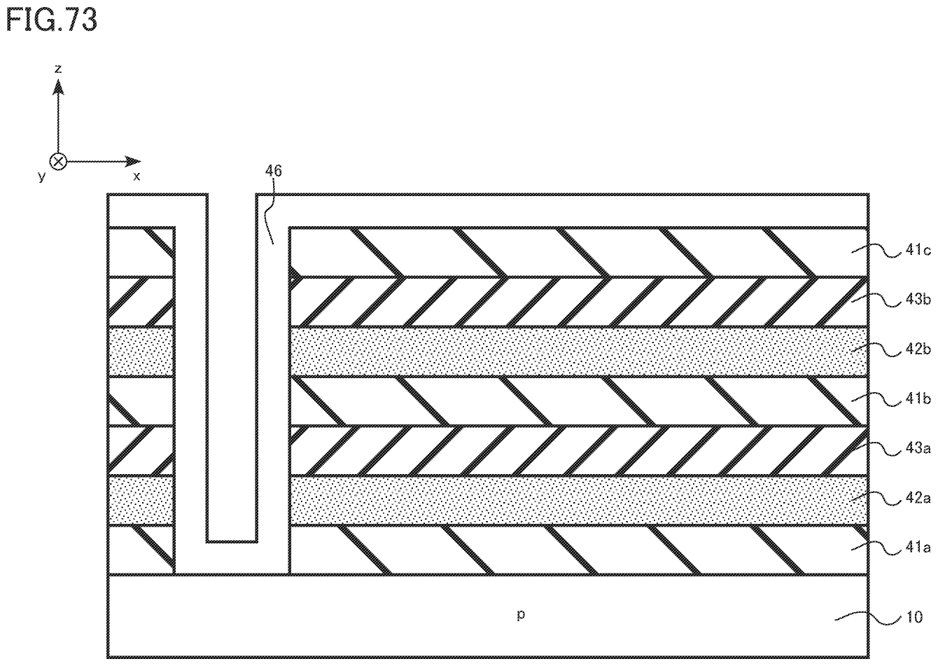

Next, the first heat treatment is performed to single-crystallize the amorphous silicon layer 46x by solid phase epitaxial growth, thereby forming the first single crystal silicon layer 46 (FIG. 73). The amorphous silicon layer 46x is single-crystallized using the single crystal silicon substrate 10 as the seed crystal.

Note that at least a part of the amorphous silicon layer 46x is single-crystallized by the first heat treatment. For example, in the amorphous silicon layer 46x, at least a portion in contact with the first amorphous silicon film 42a and a portion in contact with the second amorphous silicon film 42b are single-crystallized by the first heat treatment.

At least a part of the first single crystal silicon layer 46 is a single crystal. In the first single crystal silicon layer 46, for example, at least a portion in contact with the first amorphous silicon film 42a and a portion in contact with the second amorphous silicon film 42b are single crystals. The first single crystal silicon layer 46 may partially include, for example, crystal grains or crystal defects.

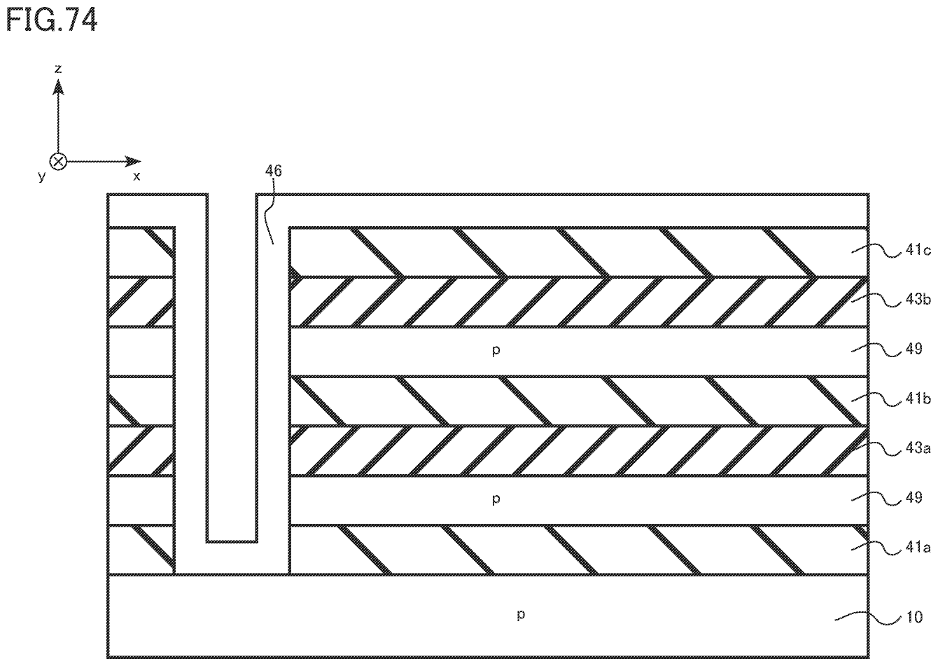

Next, the second heat treatment is performed to single-crystallize the first amorphous silicon film 42a and the second amorphous silicon film 42b by solid phase epitaxial growth, thereby forming the second single crystal silicon layer 49 (FIG. 74). The first amorphous silicon film 42a and the second amorphous silicon film 42b are single-crystallized using the first single crystal silicon layer 46 as the seed crystal.

Note that at least a part of the first amorphous silicon film 42a and at least a part of the second amorphous silicon film 42b are single-crystallized by the second heat treatment. For example, at least a portion where the p-type impurity region 12c is to be finally formed in each of the first amorphous silicon film 42a and the second amorphous silicon film 42b is single-crystallized by the second heat treatment.

At least a part of the second single crystal silicon layer 49 is a single crystal. In the second single crystal silicon layer 49, for example, at least a portion where the p-type impurity region 12c is to be finally formed is a single crystal. The second single crystal silicon layer 49 may partially include, for example, crystal grains or crystal defects.

Thereafter, the memory cell array 101 of the DRAM of the first embodiment is formed by a method similar to the method for manufacturing the semiconductor memory device of the fourth embodiment.

According to the method for manufacturing the semiconductor memory device of the modified example of the fourth embodiment, for example, a film thickness of the amorphous silicon layer 46x thus formed is reduced, and the manufacturing time can be shortened. In addition, for example, since the film thickness of the amorphous silicon layer 46x is thin, it is possible to suppress polycrystallization when the amorphous silicon layer 46x is single-crystallized.

As described above, according to the fourth embodiment and the modified example, it is possible to realize high integration of the semiconductor memory device.

### Fifth Embodiment

An example of a method for manufacturing a semiconductor memory device of a fifth embodiment includes: forming a first film of a first material in a first direction of a single crystal silicon substrate; forming a second film of a second material different from the first material in the first direction of the first film, the second material being amorphous silicon having a first hydrogen concentration; forming a third film of a third material different from the second material in the first direction of the second film; forming a first opening penetrating the third film, the second film, and the first film and reaching the single crystal silicon substrate; forming an amorphous silicon layer in contact with the single crystal silicon substrate and the second film in the first opening, the amorphous silicon layer having a second hydrogen concentration lower than the first hydrogen concentration; performing first heat treatment at a first temperature to form a first single crystal silicon layer from the amorphous silicon layer by single-crystallizing the amorphous silicon layer by solid phase epitaxial growth; performing second heat treatment at a second temperature higher than the first temperature to form a second single crystal silicon layer from the second film by single-crystallizing the second film by solid phase epitaxial growth; forming a wiring layer in contact with a first portion of the second single crystal silicon layer; forming a capacitor in contact with a second portion of the second single crystal silicon layer; and forming a gate electrode layer facing a third portion of the second single crystal silicon layer between the first portion and the second portion.

The method for manufacturing the semiconductor memory device of the fifth embodiment is a manufacturing method for manufacturing the semiconductor memory device of the second embodiment. The method for manufacturing the semiconductor memory device of the fifth embodiment is different from the method for manufacturing the semiconductor memory device of the second embodiment in that the second single crystal silicon layer is formed using a solid phase epitaxial growth method. Hereinafter, some of the content overlapping with that in the second embodiment will not be described in some cases.

In addition, the method for manufacturing the semiconductor memory device of the fifth embodiment is different from the method for manufacturing the semiconductor memory device of the fourth embodiment in that a fourth film of a fourth material different from a first material and a second material, is formed between a first film and a second film, a fifth film of a fifth material identical to the fourth material, is formed between the second film and a third film, a first single crystal silicon layer in a first opening is removed after a second single crystal silicon layer is formed, each of the fourth film and the fifth film is etched from a side face of the first opening to form a recess after the first single crystal silicon layer is removed, and a gate electrode layer is formed in the recess. Hereinafter, some of the content overlapping with that in the fourth embodiment will not be described in some cases.

Hereinafter, an example of the method for manufacturing the semiconductor memory device of the fifth embodiment will be described.

In addition, in the example of the method for manufacturing the semiconductor memory device of the fifth embodiment, a first n-type impurity region, a p-type impurity region, and a second n-type impurity region are formed in order from a side closer to the first single crystal silicon layer in the second single crystal silicon layer. The gate electrode layer is facing the p-type impurity region.

Hereinafter, a case where the first material is silicon oxide, the second material is amorphous silicon, the third material is silicon oxide, and the fourth material and the fifth material are silicon nitride will be described as an example. In this case, the first material and the third material are the same material.

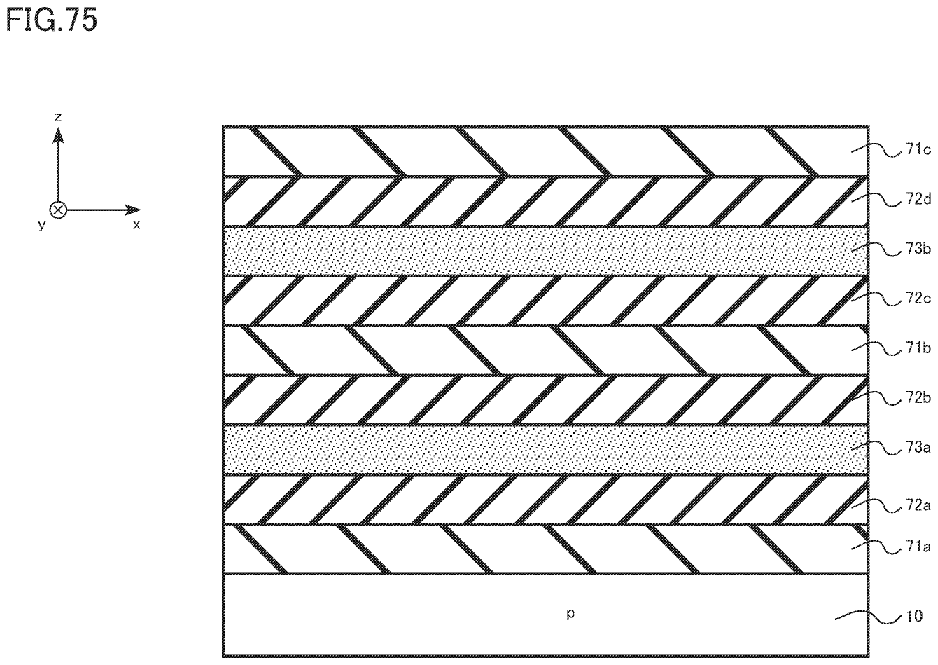

FIGS. 75, 76, 77, 78, 79, 80, 81, 82, 83, 84, 85, 86, 87, 88, 89, and 90 are schematic cross-sectional views illustrating the method for manufacturing the semiconductor memory device of the fifth embodiment.

FIGS. 75 to 90 are cross sections corresponding to FIG. 31 of the second embodiment. FIGS. 75 to 90 are xz cross sections.

First, the first silicon oxide film 71a, the first silicon nitride film 72a, the first amorphous silicon film 73a, the second silicon nitride film 72b, the second silicon oxide film 71b, the third silicon nitride film 72c, the second amorphous silicon film 73b, the fourth silicon nitride film 72d, and the third silicon oxide film 71c are formed in this order in the first direction of the single crystal silicon substrate 10 (FIG. 75).

The first silicon oxide film 71a is formed on the surface of the single crystal silicon substrate 10. The first silicon nitride film 72a is formed on the first silicon oxide film 71a. The first amorphous silicon film 73a is formed on the first silicon nitride film 72a. The second silicon nitride film 72b is formed on the first amorphous silicon film 73a. The second silicon oxide film 71b is formed on the second silicon nitride film 72b. The third silicon nitride film 72c is formed on the second silicon oxide film 71b. The second amorphous silicon film 73b is formed on the third silicon nitride film 72c. The fourth silicon nitride film 72d is formed on the second amorphous silicon film 73b. The third silicon oxide film 71c is formed on the fourth silicon nitride film 72d.

The first silicon oxide film 71a, the first silicon nitride film 72a, the first amorphous silicon film 73a, the second silicon nitride film 72b, the second silicon oxide film 71b, the third silicon nitride film 72c, the second amorphous silicon film 73b, the fourth silicon nitride film 72d, and the third silicon oxide film 71c are formed by, for example, a CVD method.

The first silicon oxide film 71a is an example of the first film. The first amorphous silicon film 73a is an example of the second film. The second silicon oxide film 71b is an example of the third film. The first silicon nitride film 72a is an example of the fourth film. The second silicon nitride film 72b is an example of the fifth film.

A part of each of the first silicon oxide film 71a, the second silicon oxide film 71b, and the third silicon oxide film 71c finally serves as the first interlayer insulating layer 28. In addition, a part of each of the first silicon nitride film 72a, the second silicon nitride film 72b, the third silicon nitride film 72c, and the fourth silicon nitride film 72d finally serves as the second interlayer insulating layer 30. A part of each of the first amorphous silicon film 73a and the second amorphous silicon film 73b finally serves as the single crystal silicon layer 12.

Note that each of the first amorphous silicon film 73a and the second amorphous silicon film 73b is patterned into a plurality of regions so as to be divided in the third direction by a method (not illustrated).

The amorphous silicon as the second material for forming the first amorphous silicon film 73a and the second amorphous silicon film 73b contains hydrogen. The amorphous silicon as the second material may or may not contain carbon.

The amorphous silicon as the second material has the first hydrogen concentration. The first hydrogen concentration is, for example, equal to or more than 1E20 cm⁻³ and equal to or less than 1E22 cm⁻³. The amorphous silicon as the second material has a first carbon concentration. The amorphous silicon as the second material contains, for example, boron (B) as a p-type impurity.

The first amorphous silicon film 73a and the second amorphous silicon film 73b are formed by, for example, a plasma enhanced CVD (PECVD) method. Amorphous silicon having a relatively high hydrogen concentration can be formed by the PECVD method. The first amorphous silicon film 73a and the second amorphous silicon film 73b are formed by, for example, a PECVD method at 300° C. to 550° C.

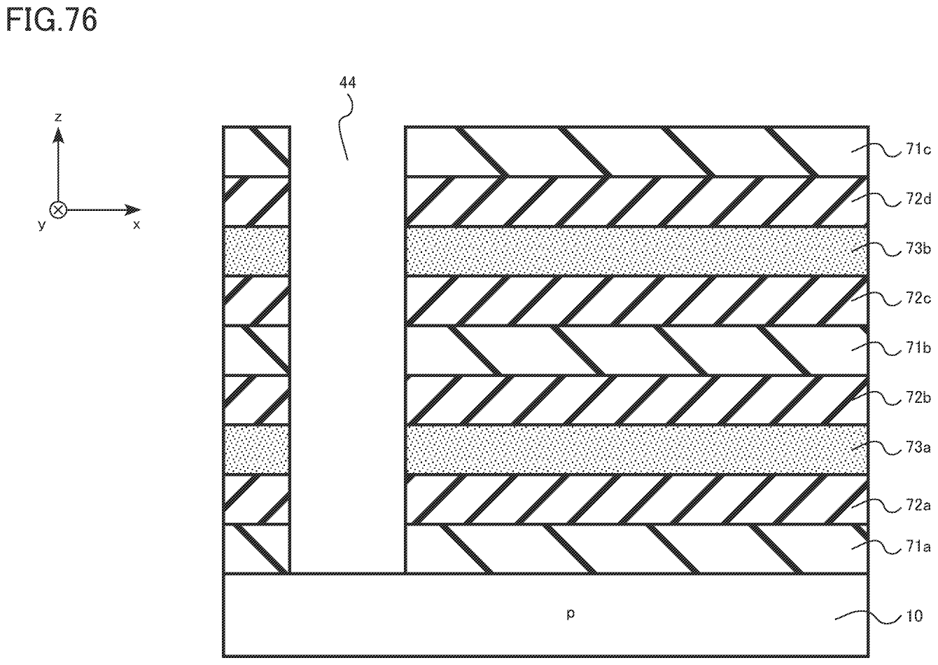

Next, the first opening 44 that penetrates the third silicon oxide film 71c, the fourth silicon nitride film 72d, the second amorphous silicon film 73b, the third silicon nitride film 72c, the second silicon oxide film 71b, the second silicon nitride film 72b, the first amorphous silicon film 73a, the first silicon nitride film 72a, and the first silicon oxide film 71a and reaches the single crystal silicon substrate 10 is formed (FIG. 76).

The first opening 44 is formed by, for example, a lithography method and a reactive ion etching method (RIE method).

Next, etching damage and a native oxide film at the time of forming the first opening 44, which are formed on a surface of the single crystal silicon substrate 10 exposed at a bottom of the first opening 44, a surface of the first amorphous silicon film 73a exposed at a side face of the first opening 44, and a surface of the second amorphous silicon film 73b exposed at the side face of the first opening 44, are removed by pretreatment.

Since the etching damage and the native oxide film at the time of forming the first opening 44 are removed, an amorphous silicon layer 46x, to be single-crystallized later by solid phase epitaxial growth, and the single crystal silicon substrate 10 which serves as a seed crystal are favorably bonded. In addition, since the etching damage and the native oxide film at the time of forming the first opening 44 are removed, the first amorphous silicon film 73a and the second amorphous silicon film 73b, to be single-crystallized later by solid phase epitaxial growth, and the first single crystal silicon layer 46 which serves as a seed crystal are favorably bonded.

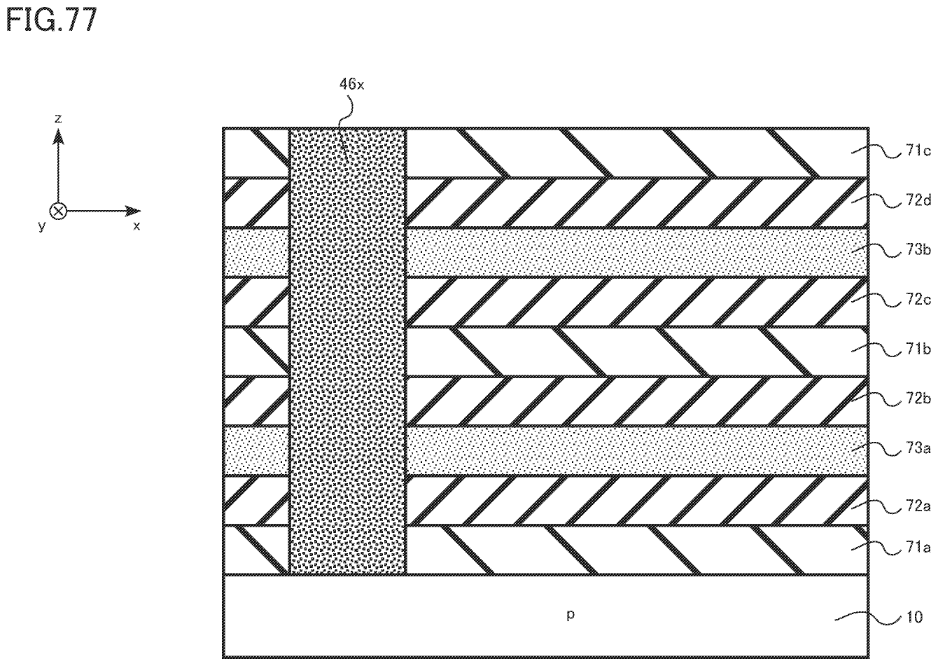

Next, the amorphous silicon layer 46x in contact with the single crystal silicon substrate 10, the first amorphous silicon film 73a, and the second amorphous silicon film 73b is formed in the first opening 44 (FIG. 77). For example, the first opening 44 is filled with the amorphous silicon layer 46x.

The amorphous silicon layer 46x contains hydrogen. The amorphous silicon layer 46x may or may not contain carbon.

The amorphous silicon layer 46x has the second hydrogen concentration. The second hydrogen concentration is lower than the first hydrogen concentration of the amorphous silicon as the second material. The second hydrogen concentration is, for example, equal to or more than 1E17 cm⁻³ and less than 1E20 cm⁻³.

The amorphous silicon layer 46x has a second carbon concentration. The second carbon concentration is, for example, lower than the first carbon concentration of the amorphous silicon as the second material. The amorphous silicon layer 46x is, for example, non-doped amorphous silicon containing no conductive impurity.

The amorphous silicon layer 46x is formed by, for example, a thermal CVD method or a thermal ALD method. Amorphous silicon having a relatively low hydrogen concentration can be formed by the thermal CVD method or the thermal ALD method. The amorphous silicon layer 46x is formed by, for example, a thermal CVD method at 450° C. to 530° C.

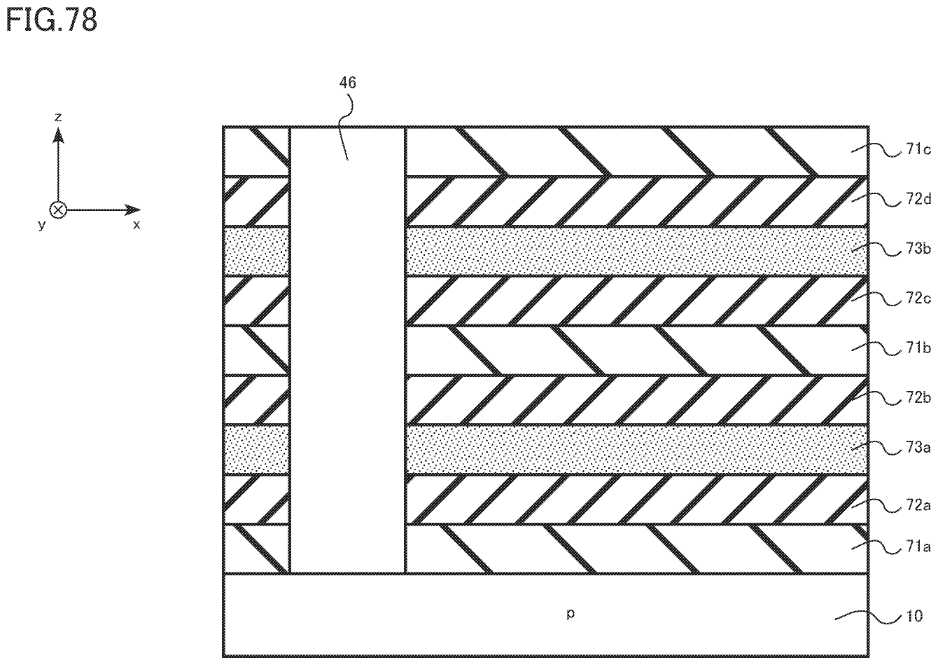

Next, the first heat treatment is performed to single-crystallize the amorphous silicon layer 46x by solid phase epitaxial growth, thereby forming the first single crystal silicon layer 46 (FIG. 78). The amorphous silicon layer 46x is single-crystallized using the single crystal silicon substrate 10 as the seed crystal.

Note that at least a part of the amorphous silicon layer 46x is single-crystallized by the first heat treatment. For example, in the amorphous silicon layer 46x, at least a portion in contact with the first amorphous silicon film 73a and a portion in contact with the second amorphous silicon film 73b are single-crystallized by the first heat treatment.

At least a part of the first single crystal silicon layer 46 is a single crystal. In the first single crystal silicon layer 46, for example, at least a portion in contact with the first amorphous silicon film 73a and a portion in contact with the second amorphous silicon film 73b are single crystals. The first single crystal silicon layer 46 may partially include, for example, crystal grains or crystal defects.

The first heat treatment is performed at the first temperature. The first temperature is, for example, equal to or higher than 550° C. and equal to or lower than 650° C.

The first heat treatment is performed, for example, in a non-oxidizing atmosphere. The first heat treatment is performed, for example, in a nitrogen gas atmosphere or an argon gas atmosphere.

In the first heat treatment, the first amorphous silicon film 73a and the second amorphous silicon film 73b are not single-crystallized. Since the first amorphous silicon film 73a and the second amorphous silicon film 73b have the first hydrogen concentration higher than the second hydrogen concentration of the amorphous silicon layer 46x, the temperature for single crystallization of amorphous silicon is high so that the single crystallization is suppressed. In addition, also in a case where the first amorphous silicon film 73a and the second amorphous silicon film 73b have the first carbon concentration higher than the second carbon concentration of the amorphous silicon layer 46x, the temperature for single crystallization of amorphous silicon of the first amorphous silicon film 73a and the second amorphous silicon film 73b is similarly high so that the single crystallization is suppressed.

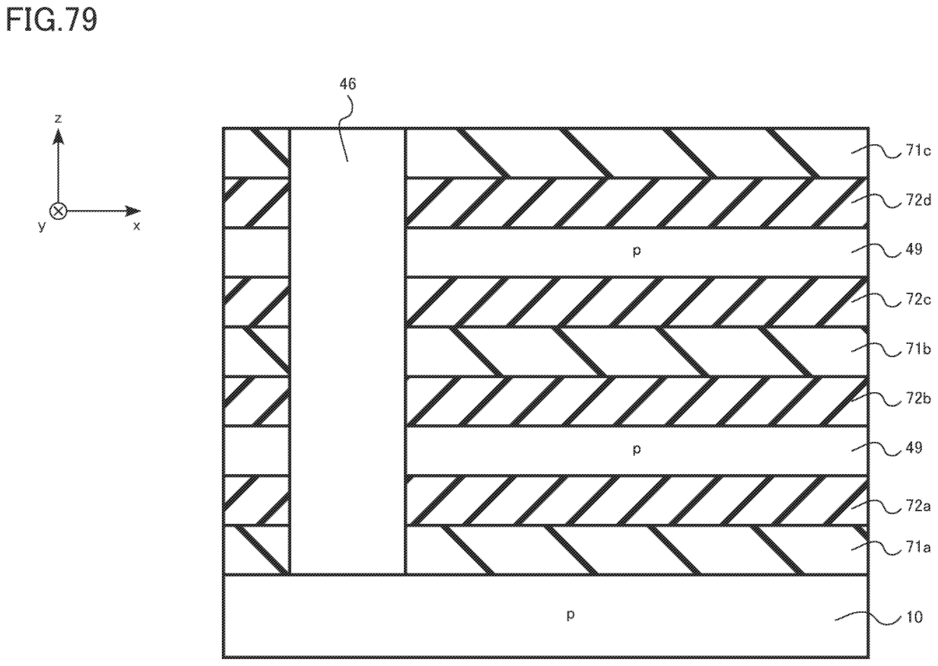

Next, the second heat treatment is performed to single-crystallize the first amorphous silicon film 73a and the second amorphous silicon film 73b by solid phase epitaxial growth, thereby forming the second single crystal silicon layer 49 (FIG. 79). The first amorphous silicon film 73a and the second amorphous silicon film 73b are single-crystallized using the first single crystal silicon layer 46 as the seed crystal.

The second single crystal silicon layer 49 is, for example, p-type single crystal silicon containing p-type impurities. The p-type impurities are impurities doped in the first amorphous silicon film 73a and the second amorphous silicon film 73b at the time of forming the first amorphous silicon film 73a and the second amorphous silicon film 73b.

Note that at least a part of the first amorphous silicon film 73a and at least a part of the second amorphous silicon film 73b are single-crystallized by the second heat treatment. For example, at least a portion where the p-type impurity region 12c is to be finally formed in each of the first amorphous silicon film 73a and the second amorphous silicon film 73b is single-crystallized by the second heat treatment.

At least a part of the second single crystal silicon layer 49 is a single crystal. In the second single crystal silicon layer 49, for example, at least a portion where the p-type impurity region 12c is to be finally formed is a single crystal. The second single crystal silicon layer 49 may partially include, for example, crystal grains or crystal defects.

The second heat treatment is performed at the second temperature. The second temperature is higher than the first temperature for forming the first single crystal silicon layer 46. The second temperature is, for example, higher than 650° C. and equal to or lower than 800° C.

The second heat treatment is performed, for example, in a non-oxidizing atmosphere. The second heat treatment is performed, for example, in a nitrogen gas atmosphere or an argon gas atmosphere.

Since the second heat treatment is performed at the temperature higher than that of the first heat treatment, the single crystallization of each of the first amorphous silicon film 73a and the second amorphous silicon film 73b having a high hydrogen concentration proceeds. Note that the temperature of the first heat treatment and the temperature of the second heat treatment can be changed depending on the hydrogen concentration of the first amorphous silicon film 73a and the hydrogen concentration of the second amorphous silicon film 73b. Therefore, for example, the temperature of the first heat treatment may be set to a temperature higher than the temperature range of the first heat treatment exemplified above, and the temperature of the second heat treatment may be set to a temperature higher than the temperature range of the second heat treatment exemplified above. A part of the second single crystal silicon layer 49 finally serves as the single crystal silicon layer 12 illustrated in FIGS. 31 and 32 in the second embodiment.

The hydrogen concentration of the first single crystal silicon layer 46 is, for example, equal to or lower than the hydrogen concentration of the amorphous silicon layer 46x. The hydrogen concentration of the second single crystal silicon layer 49 is, for example, equal to or lower than the hydrogen concentration of the first amorphous silicon film 73a and the hydrogen concentration of the second amorphous silicon film 73b. The hydrogen concentration of the first single crystal silicon layer 46 is, for example, lower than the hydrogen concentration of the second single crystal silicon layer 49. The hydrogen concentration of the single crystal silicon layer 12 thus finally formed is, for example, equal to or lower than the hydrogen concentration of the first amorphous silicon film 73a and the hydrogen concentration of the second amorphous silicon film 73b.

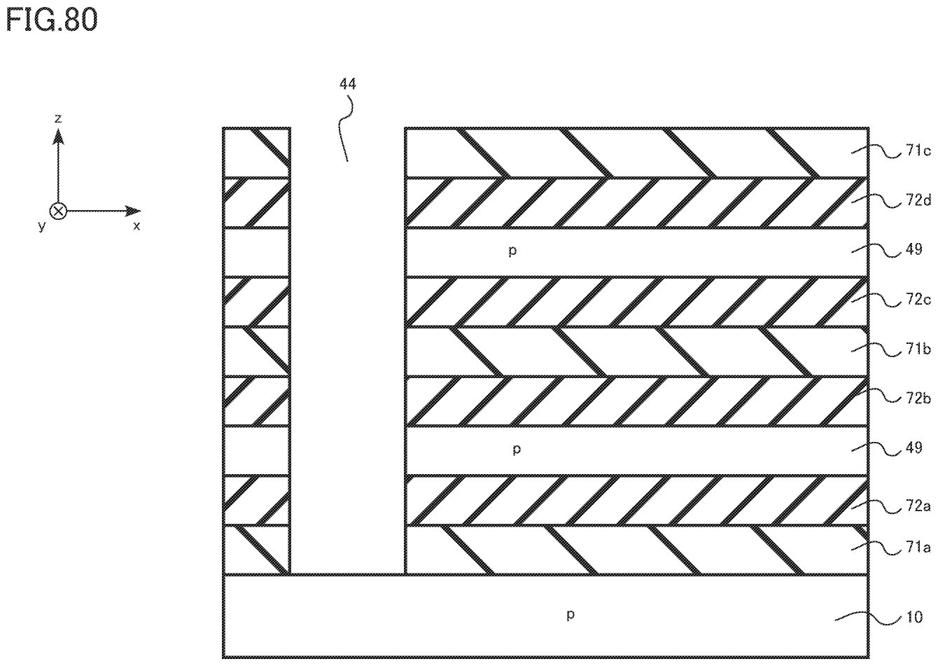

Next, the first single crystal silicon layer 46 in the first opening 44 is removed (FIG. 80). The first single crystal silicon layer 46 is removed by, for example, a dry etching method or a wet etching method.

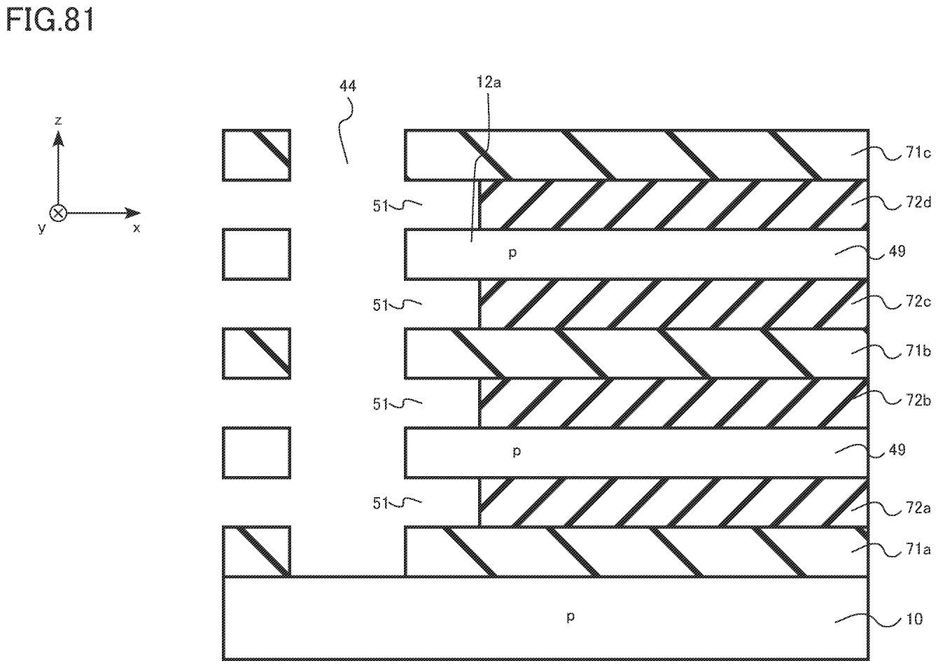

Next, the first silicon nitride film 72a, the second silicon nitride film 72b, the third silicon nitride film 72c, and the fourth silicon nitride film 72d are etched from the side face of the first opening 44 to form the second recesses 51 (FIG. 81). The first silicon nitride film 72a, the second silicon nitride film 72b, the third silicon nitride film 72c, and the fourth silicon nitride film 72d are removed by, for example, a wet etching method. The second recess 51 is an example of the recess.

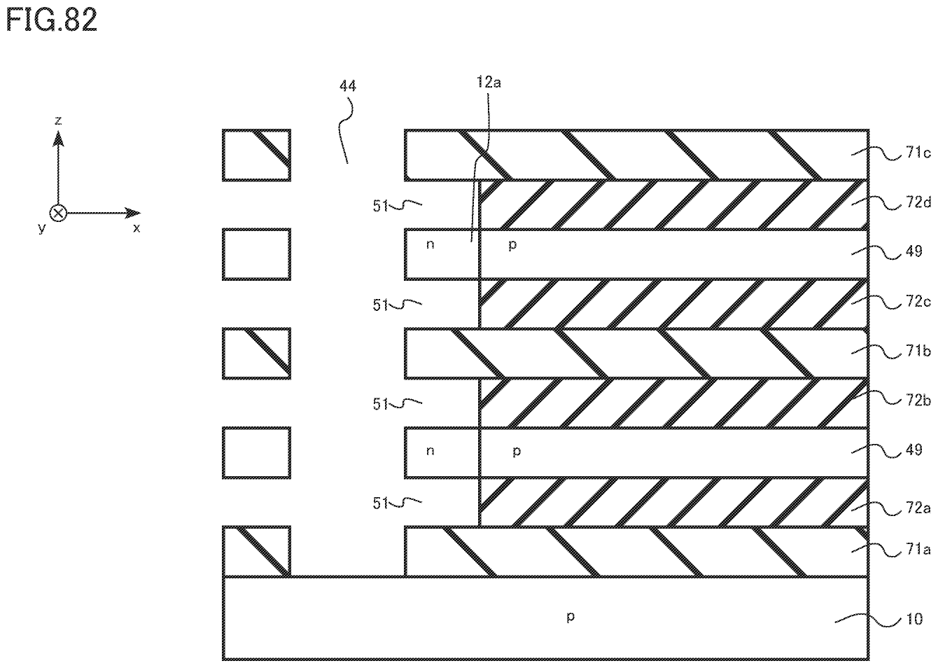

Next, the first n-type impurity region 12a is formed in the second single crystal silicon layer 49 exposed in the second recess 51 (FIG. 82). The first n-type impurity region 12a is formed using, for example, a vapor phase diffusion method. In addition, the first n-type impurity region 12a may be formed by, for example, bringing polycrystalline silicon doped with impurities into contact with the second single crystal silicon layer 49 and diffusing the impurities by thermal diffusion.

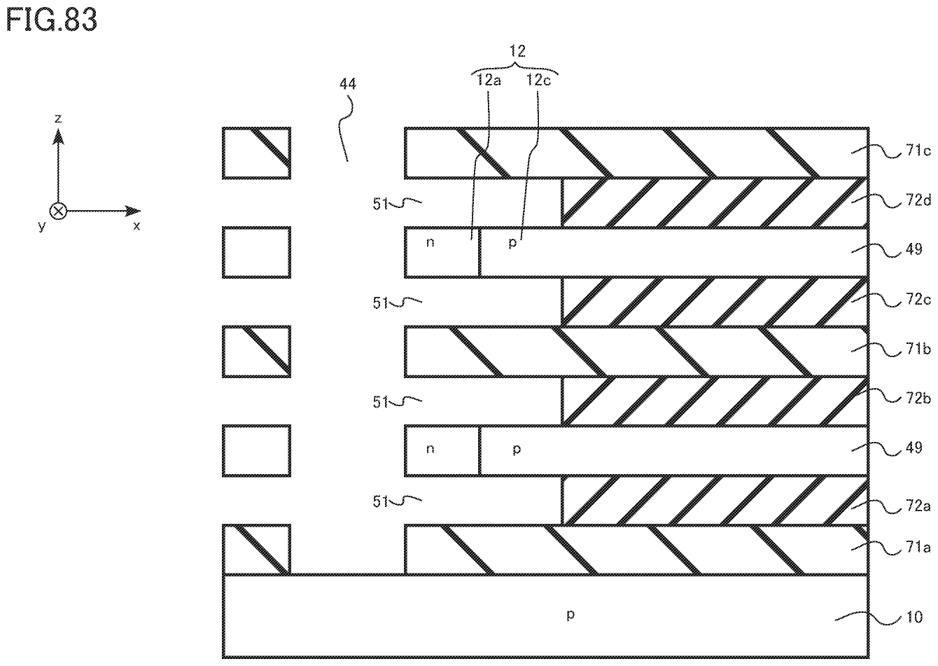

Next, the first silicon nitride film 72a, the second silicon nitride film 72b, the third silicon nitride film 72c, and the fourth silicon nitride film 72d are etched again from the side face of the first opening 44 to deepen the second recesses 51 (FIG. 83). The first silicon nitride film 72a, the second silicon nitride film 72b, the third silicon nitride film 72c, and the fourth silicon nitride film 72d are removed by, for example, a wet etching method. The second single crystal silicon layer 49 exposed in the second recess 51 that is deepened serves as the p-type impurity region 12c.

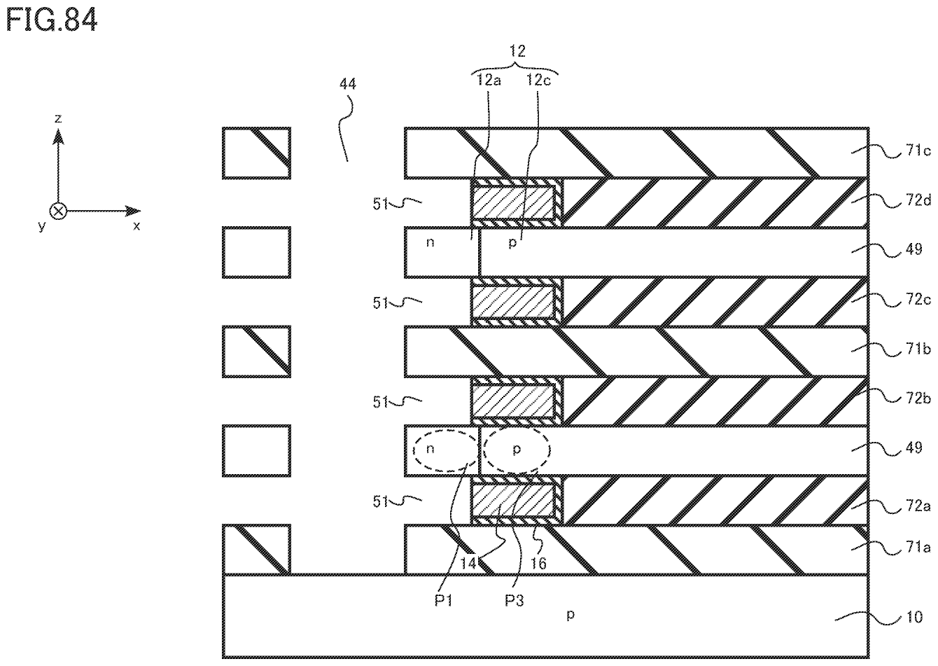

Next, the gate insulating film 16 and the gate electrode layer 14 are formed in each of the second recesses 51 (FIG. 84). The gate insulating film 16 is in contact with the third portion P3 of the second single crystal silicon layer 49. The gate insulating film 16 is in contact with the p-type impurity region 12c of the second single crystal silicon layer 49. The gate electrode layer 14 is facing the third portion P3 of the second single crystal silicon layer 49. The gate electrode layer 14 is facing the p-type impurity region 12c of the second single crystal silicon layer 49.

The gate insulating film 16 and the gate electrode layer 14 are formed in the second recess 51 using, for example, a CVD method and a dry etching method.

Next, the first opening 44 and the second recess 51 are filled with the silicon oxide film 52. The first opening 44 and the second recess 51 are filled with the silicon oxide film 52 using, for example, a CVD method and a dry etching method.

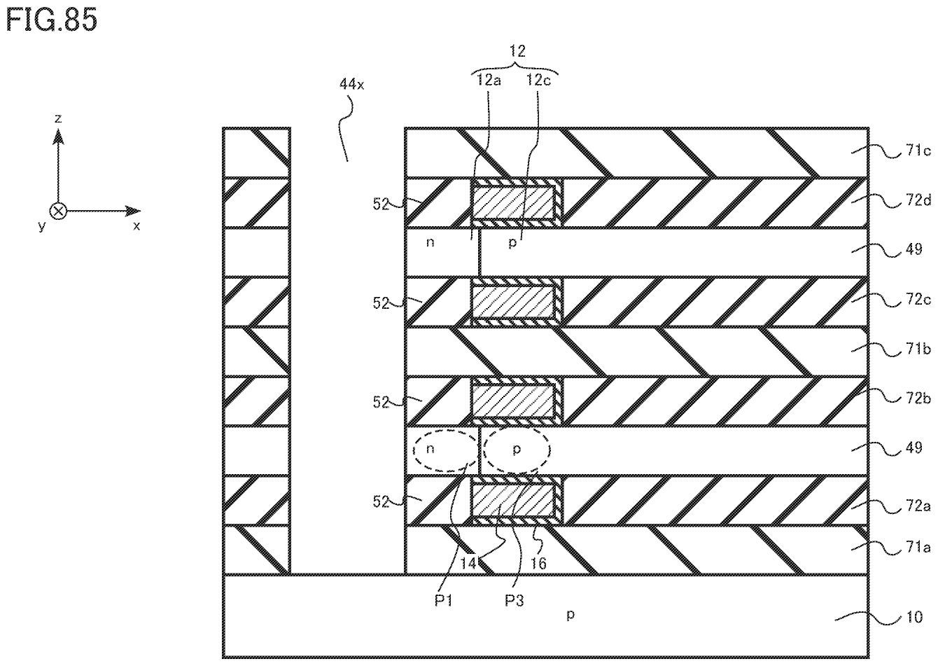

Next, the plurality of openings 44x separated in the third direction are formed in the silicon oxide film 52 (FIG. 85).

Next, the n-type impurity region 10a is formed in the single crystal silicon substrate 10 at the bottom of each of the plurality of openings 44x. The n-type impurity region 10a is formed by, for example, an ion implantation method. The n-type impurity region 10a can also be formed by, for example, doping and activating impurities of a conductivity type different from that of the single crystal silicon substrate 10 using a method such as vapor phase doping. In addition, the n-type impurity region 10a can also be formed by bringing polycrystalline silicon doped with conductive impurities into contact with an exposed surface of the single crystal silicon substrate 10, diffusing the impurities by thermal diffusion, and then removing the polycrystalline silicon.

N-type impurities introduced into the single crystal silicon substrate 10 are activated by, for example, heat treatment at a high temperature for a short time.

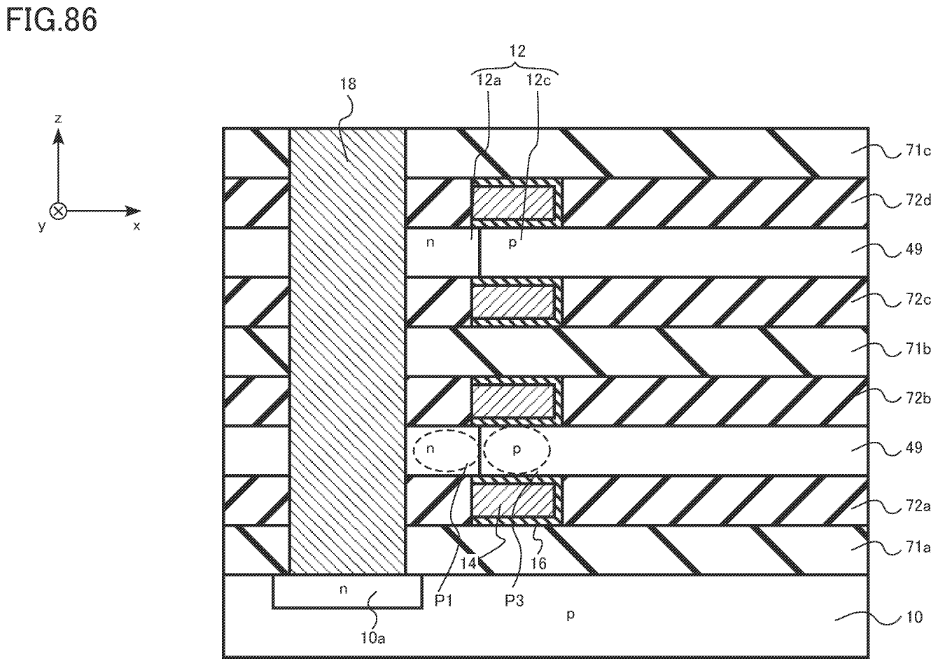

Next, the wiring layer 18 is formed in each of the plurality of openings 44x (FIG. 86). The wiring layer 18 is formed by, for example, a CVD method.

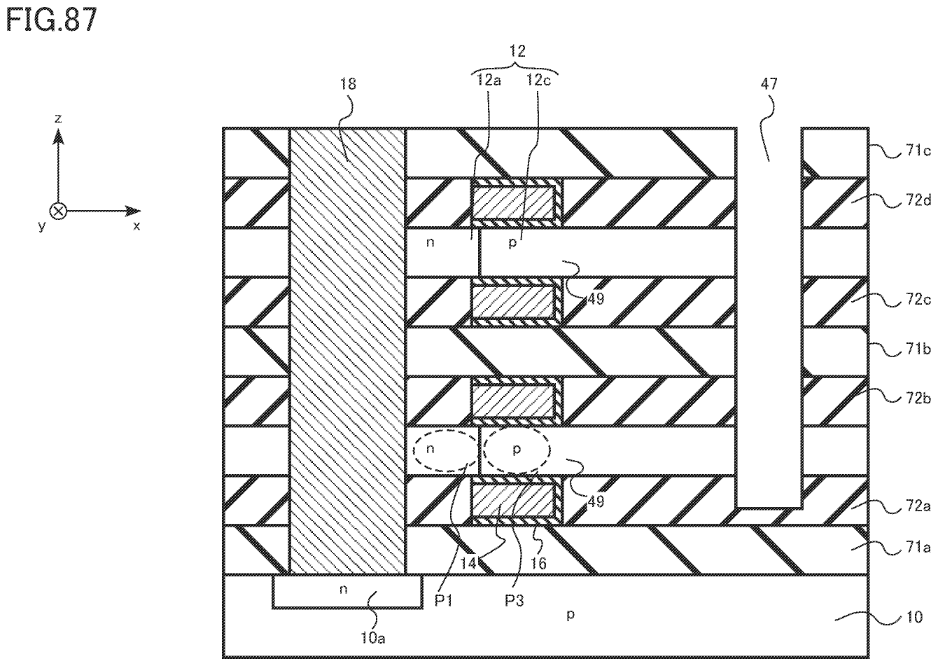

Next, the second opening 47 that penetrates the third silicon oxide film 71c, the fourth silicon nitride film 72d, the second single crystal silicon layer 49, the third silicon nitride film 72c, the second silicon oxide film 71b, the second silicon nitride film 72b, and the second single crystal silicon layer 49 is formed (FIG. 87). The surface of the single crystal silicon substrate 10 is not exposed at a bottom of the second opening 47.

The second opening 47 is formed by, for example, a lithography method and an RIE method.

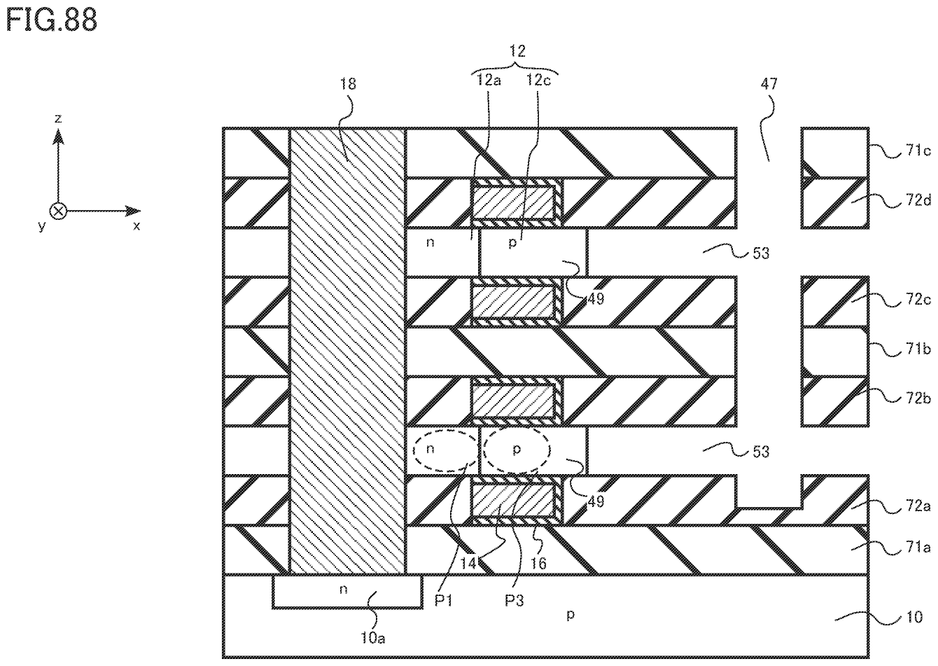

Next, the second single crystal silicon layers 49 are selectively etched from the side face of the second opening 47 to form the third recesses 53 (FIG. 88). The second single crystal silicon layers 49 are etched using, for example, a dry etching method or a wet etching method.

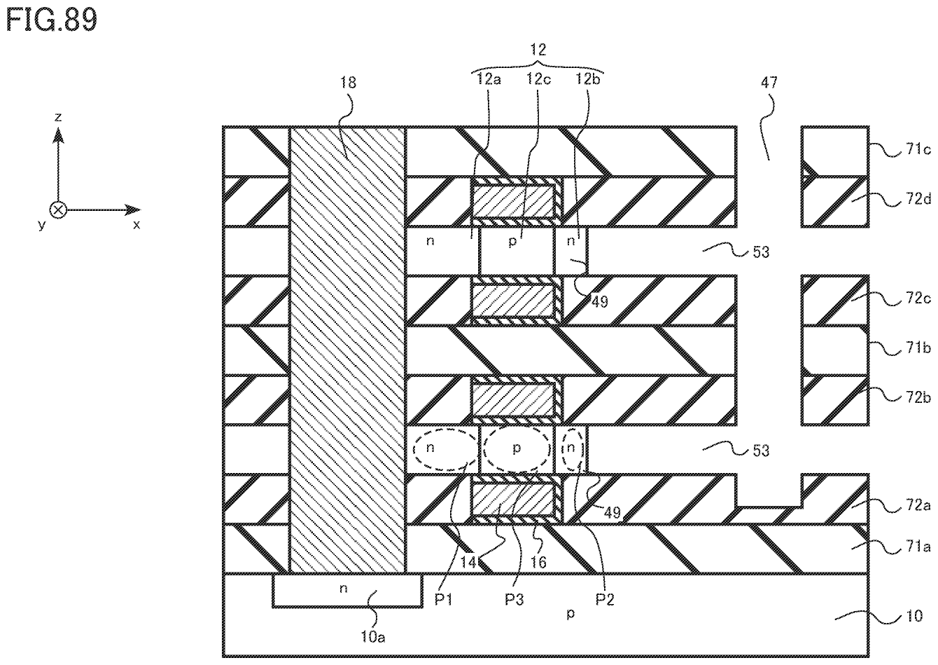

Next, the second n-type impurity region 12b is formed in the second portion P2 of the second single crystal silicon layer 49 (FIG. 89). The second n-type impurity region 12b is formed using, for example, a vapor phase diffusion method.

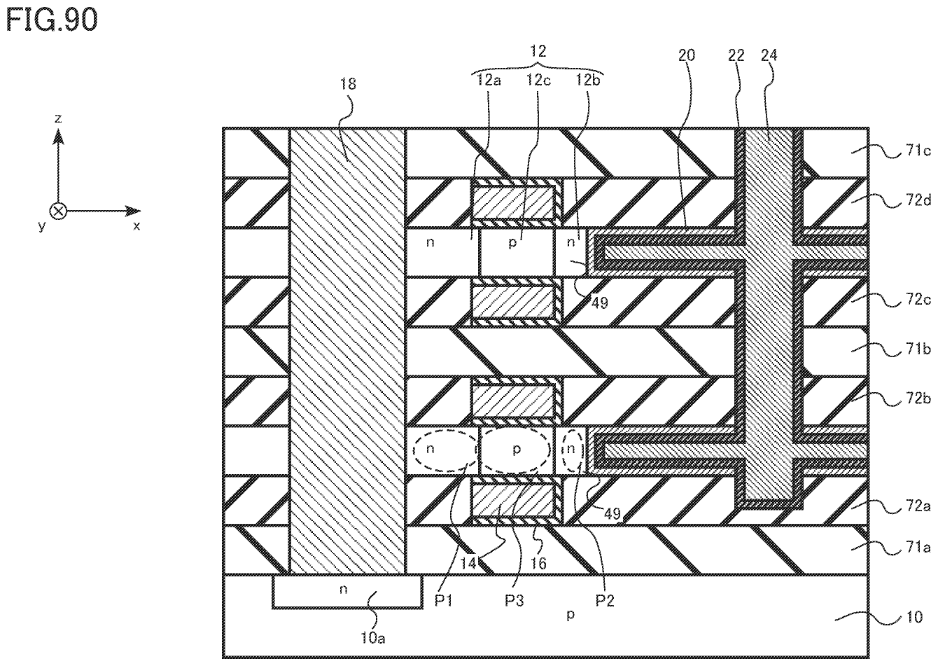

Next, the storage node electrode 20, the capacitor insulating film 22, and the plate electrode 24 are formed in each of the third recesses 53 (FIG. 90). The storage node electrode 20 is in contact with the second portion P2 of the second single crystal silicon layer 49. The capacitor CA including the storage node electrode 20, the capacitor insulating film 22, and the plate electrode 24 is in contact with the second portion P2 of the second single crystal silicon layer 49. The storage node electrode 20, the capacitor insulating film 22, and the plate electrode 24 are formed using, for example, a CVD method.

The memory cell array 201 of the DRAM of the second embodiment is formed by the above manufacturing method.

According to the method for manufacturing the DRAM of the fifth embodiment, the DRAM having the three-dimensional structure with stable characteristics can be manufactured in a short manufacturing time similarly to the method for manufacturing the DRAM of the fourth embodiment.

In addition, according to the method for manufacturing the DRAM of the fifth embodiment, the device area can be reduced similarly to the method for manufacturing the DRAM of the fourth embodiment.

The first single crystal silicon layer 46 may be formed by another method other than the solid phase epitaxial growth method. The first single crystal silicon layer 46 may be formed using, for example, a vapor phase epitaxial growth method or a VLS method.

As described above, according to the fifth embodiment, it is possible to realize high integration of the semiconductor memory device.

### Sixth Embodiment

An example of a method for manufacturing a semiconductor memory device of a sixth embodiment includes: forming a first film of a first material in a first direction of a single crystal silicon substrate; forming a second film of a second material different from the first material in the first direction of the first film, the second material being amorphous silicon having a first hydrogen concentration; forming a third film of a third material different from the second material in the first direction of the second film; forming a first opening penetrating the third film, the second film, and the first film and reaching the single crystal silicon substrate; forming an amorphous silicon layer in contact with the single crystal silicon substrate and the second film in the first opening, the amorphous silicon layer having a second hydrogen concentration lower than the first hydrogen concentration; performing first heat treatment at a first temperature to form a first single crystal silicon layer from the amorphous silicon layer by single-crystallizing the amorphous silicon layer by solid phase epitaxial growth; performing second heat treatment at a second temperature higher than the first temperature to form a second single crystal silicon layer from the second film by single-crystallizing the second film by solid phase epitaxial growth; forming a wiring layer in contact with a first portion of the second single crystal silicon layer; forming a capacitor in contact with a second portion of the second single crystal silicon layer; and forming a gate electrode layer facing a third portion of the second single crystal silicon layer between the first portion and the second portion.

The method for manufacturing the semiconductor memory device of the sixth embodiment is different from the semiconductor memory device of the fourth embodiment in that the fourth film is not formed. Hereinafter, some of the content overlapping with that in the fourth embodiment will not be described in some cases.

Hereinafter, a case where the first material is silicon oxide, the second material is amorphous silicon, and the third material is silicon oxide will be described as an example. In this case, the first material and the third material are the same material.

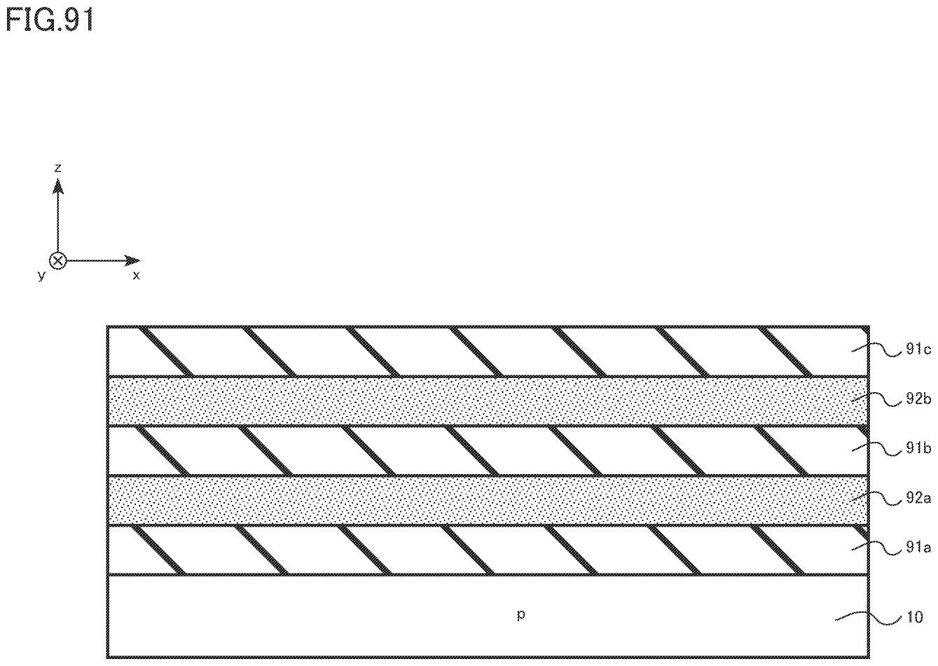

FIGS. 91, 92, 93, 94, and 95 are schematic cross-sectional views illustrating the method for manufacturing the semiconductor memory device of the sixth embodiment.

First, a first silicon oxide film 91a, a first amorphous silicon film 92a, a second silicon oxide film 91b, a second amorphous silicon film 92b, and a third silicon oxide film 91c are formed in this order in the first direction of the single crystal silicon substrate 10 (FIG. 91).

The first silicon oxide film 91a is an example of the first film. The first amorphous silicon film 92a is an example of the second film. The second silicon oxide film 91b is an example of the third film.

The amorphous silicon as the second material for forming the first amorphous silicon film 92a and the second amorphous silicon film 92b contains hydrogen. The amorphous silicon as the second material may or may not contain carbon.

The amorphous silicon as the second material has the first hydrogen concentration. The first hydrogen concentration is, for example, equal to or more than 1E20 cm⁻³ and equal to or less than 1E22 cm⁻³. The amorphous silicon as the second material has a first carbon concentration. The amorphous silicon as the second material contains, for example, boron (B) as a p-type impurity.

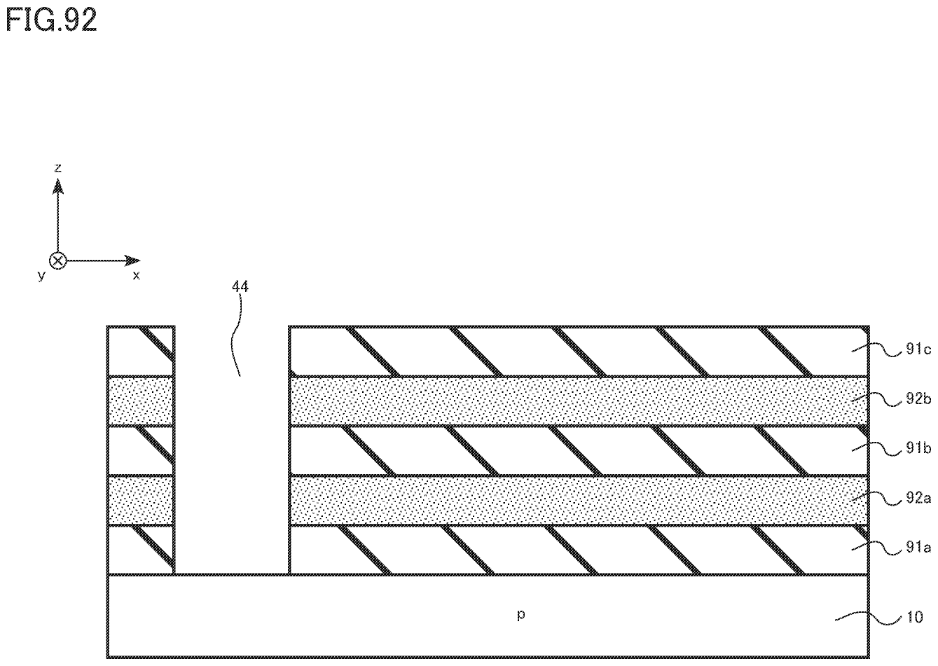

Next, the first opening 44 that penetrates the third silicon oxide film 91c, the second amorphous silicon film 92b, the second silicon oxide film 91b, the first amorphous silicon film 92a, and the first silicon oxide film 91a and reaches the single crystal silicon substrate 10 is formed (FIG. 92).

The first opening 44 is formed by, for example, a lithography method and a reactive ion etching method (RIE method).

Next, etching damage and a native oxide film at the time of forming the first opening 44, which are formed on a surface of the single crystal silicon substrate 10 exposed at a bottom of the first opening 44, a surface of the first amorphous silicon film 92a exposed at a side face of the first opening 44, and a surface of the second amorphous silicon film 92b exposed at the side face of the first opening 44, are removed by pretreatment.

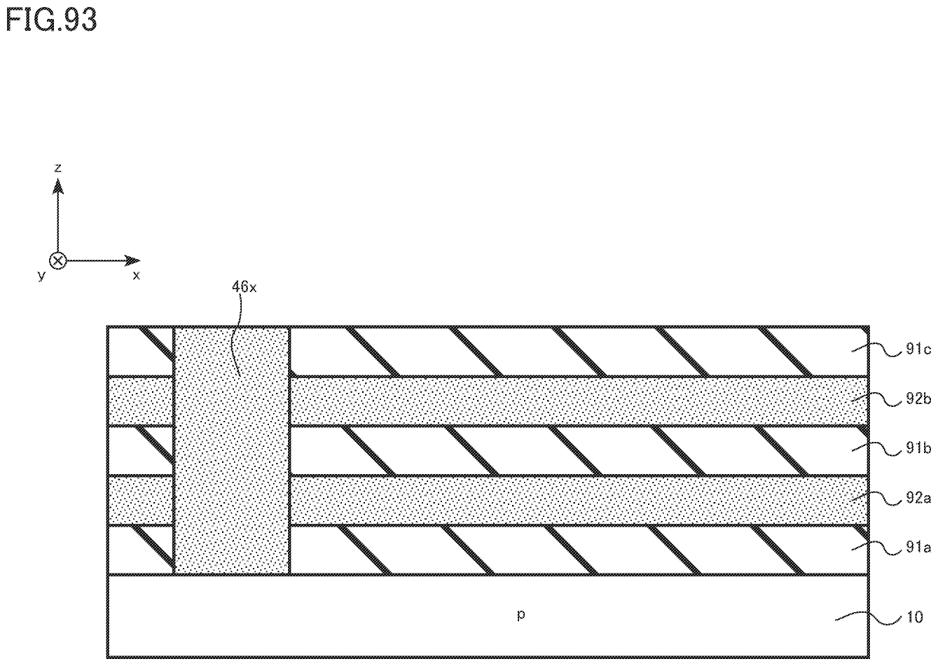

Next, the amorphous silicon layer 46x in contact with the single crystal silicon substrate 10, the first amorphous silicon film 92a, and the second amorphous silicon film 92b is formed in the first opening 44 (FIG. 93). For example, the first opening 44 is filled with the amorphous silicon layer 46x.

The amorphous silicon layer 46x contains hydrogen. The amorphous silicon layer 46x may or may not contain carbon.

The amorphous silicon layer 46x has the second hydrogen concentration. The second hydrogen concentration is lower than the first hydrogen concentration of the amorphous silicon as the second material. The second hydrogen concentration is, for example, equal to or more than 1E17 cm⁻³ and less than 1E20 cm⁻³.

The amorphous silicon layer 46x has a second carbon concentration. The second carbon concentration is, for example, lower than the first carbon concentration of the amorphous silicon as the second material. The amorphous silicon layer 46x is, for example, non-doped amorphous silicon containing no conductive impurity.

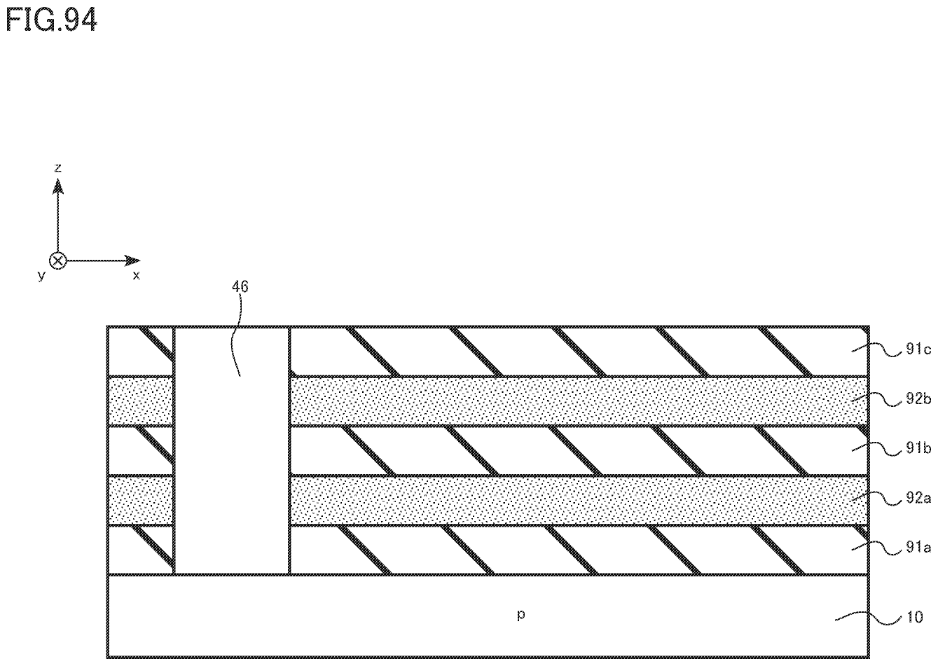

Next, the first heat treatment is performed to single-crystallize the amorphous silicon layer 46x by solid phase epitaxial growth, thereby forming the first single crystal silicon layer 46 (FIG. 94). The amorphous silicon layer 46x is single-crystallized using the single crystal silicon substrate 10 as the seed crystal.

Note that at least a part of the amorphous silicon layer 46x is single-crystallized by the first heat treatment. For example, in the amorphous silicon layer 46x, at least a portion in contact with the first amorphous silicon film 92a and a portion in contact with the second amorphous silicon film 92b are single-crystallized by the first heat treatment.

At least a part of the first single crystal silicon layer 46 is a single crystal. In the first single crystal silicon layer 46, for example, at least a portion in contact with the first amorphous silicon film 92a and a portion in contact with the second amorphous silicon film 92b are single crystals. The first single crystal silicon layer 46 may partially include, for example, crystal grains or crystal defects.

The first heat treatment is performed at the first temperature. The first temperature is, for example, equal to or higher than 550° C. and equal to or lower than 650° C.

The first heat treatment is performed, for example, in a non-oxidizing atmosphere. The first heat treatment is performed, for example, in a nitrogen gas atmosphere or an argon gas atmosphere.

In the first heat treatment, the first amorphous silicon film 92a and the second amorphous silicon film 92b are not single-crystallized. Since the first amorphous silicon film 92a and the second amorphous silicon film 92b have the first hydrogen concentration higher than the second hydrogen concentration of the amorphous silicon layer 46x, the temperature for single crystallization is high so that the single crystallization is suppressed.

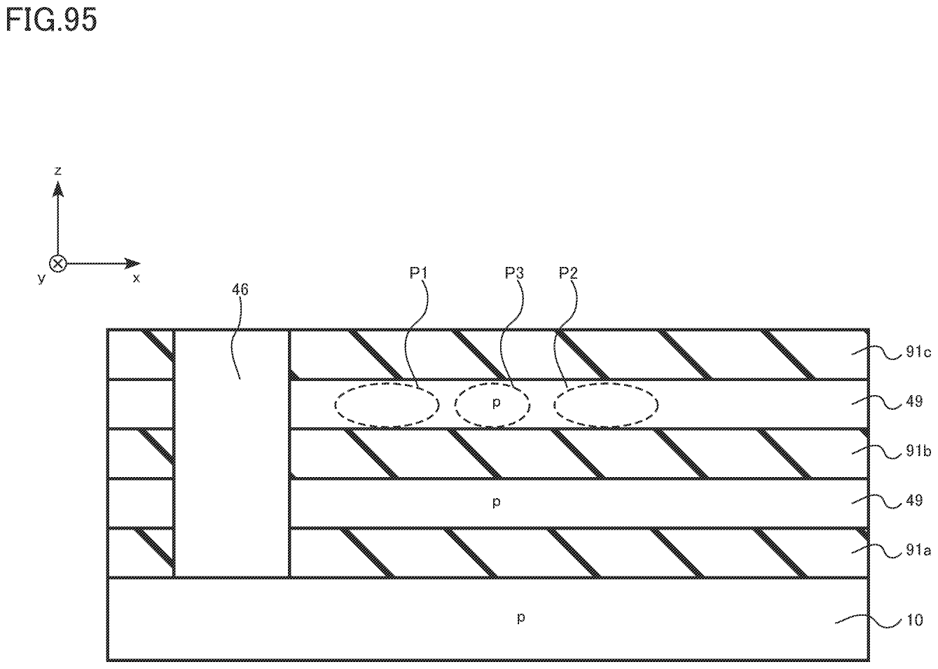

Next, the second heat treatment is performed to single-crystallize the first amorphous silicon film 92a and the second amorphous silicon film 92b by solid phase epitaxial growth, thereby forming the second single crystal silicon layer 49 (FIG. 95). The first amorphous silicon film 92a and the second amorphous silicon film 92b are single-crystallized using the first single crystal silicon layer 46 as the seed crystal.

The second single crystal silicon layer 49 is, for example, p-type single crystal silicon containing p-type impurities. The p-type impurity is an impurity doped in the first amorphous silicon film 92a and the second amorphous silicon film 92b at the time of forming the first amorphous silicon film 42a and the second amorphous silicon film 42b.

Note that at least a part of the first amorphous silicon film 92a and at least a part of the second amorphous silicon film 92b are single-crystallized by the second heat treatment. For example, at least a portion which serves as the third portion P3 in each of the first amorphous silicon film 92a and the second amorphous silicon film 92b is single-crystallized by the second heat treatment.

At least a part of the second single crystal silicon layer 49 is a single crystal. In the second single crystal silicon layer 49, for example, at least the third portion P3 is a single crystal. The second single crystal silicon layer 49 may partially include, for example, crystal grains or crystal defects.

The second heat treatment is performed at the second temperature. The second temperature is higher than the first temperature for forming the first single crystal silicon layer 46. The second temperature is, for example, higher than 650° C. and equal to or lower than 800° C.

The second heat treatment is performed, for example, in a non-oxidizing atmosphere. The second heat treatment is performed, for example, in a nitrogen gas atmosphere or an argon gas atmosphere.

Since the second heat treatment is performed at the temperature higher than that of the first heat treatment, the single crystallization of each of the first amorphous silicon film 42a and the second amorphous silicon film 42b having a high hydrogen concentration proceeds. Note that the temperature of the first heat treatment and the temperature of the second heat treatment can be changed depending on the hydrogen concentration of the first amorphous silicon film 42a and the hydrogen concentration of the second amorphous silicon film 42b. Therefore, for example, the temperature of the first heat treatment may be set to a temperature higher than the temperature range of the first heat treatment exemplified above, and the temperature of the second heat treatment may be set to a temperature higher than the temperature range of the second heat treatment exemplified above.

The second single crystal silicon layer 49 has the first portion P1, the second portion P2, and the third portion P3. The third portion P3 is provided between the first portion P1 and the second portion P2.

Thereafter, a wiring layer in contact with the first portion P1 of the second single crystal silicon layer 49 is formed. In addition, a capacitor in contact with the second portion P2 of the second single crystal silicon layer 49 is formed. In addition, a gate electrode layer facing the third portion P3 between the first portion P1 and the second portion P2 of the second single crystal silicon layer 49 is formed. Note that the order of forming the wiring layer, the capacitor, and the gate electrode layer is freely selected.

A memory cell array of a DRAM of the sixth embodiment is formed by the above manufacturing method.

According to the method for manufacturing the DRAM of the sixth embodiment, the DRAM having the three-dimensional structure with stable characteristics can be manufactured in a short manufacturing time similarly to the method for manufacturing the DRAM of the fourth embodiment.

### Modified Example

A method for manufacturing a DRAM of a modified example of the sixth embodiment is different from the method for manufacturing the DRAM of the sixth embodiment in that the first material and the third material are silicon nitride. According to the method for manufacturing the DRAM of the modified example of the sixth embodiment, the DRAM having a three-dimensional structure with stable characteristics can be manufactured in a short manufacturing time similarly to the method for manufacturing the DRAM of the sixth embodiment.

As described above, according to the sixth embodiment and the modified example, it is possible to realize high integration of the semiconductor memory device.

Although the case where the first material and the third material are the same has been described as an example in the first to sixth embodiments, the first material and the third material may be different from each other.

In the first to sixth embodiments, when a VLS method or the like is used in a step of growing single crystal silicon, steps of re-forming amorphous silicon having a low density, which is obtained by adding an element such as P doping or N doping, and performing heat treatment, and performing gettering may be combined in order to remove metal remaining in a single crystal silicon film.

In the first to third embodiments, the fifth embodiment, or the sixth embodiment, it is also possible to adopt a mode in which the first opening is not completely filled with the silicon layer as in the modified example of the fourth embodiment.

While certain embodiments have been described, these embodiments have been presented by way of example only, and are not intended to limit the scope of the inventions. Indeed, a method for manufacturing the semiconductor memory device and the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A method for manufacturing a semiconductor memory device, the method comprising:
forming a first film of a first material in a first direction of a single crystal silicon substrate;
forming a second film of a second material different from the first material, in the first direction of the first film;
forming a third film of a third material different from the second material, in the first direction of the second film;
forming a first opening penetrating the third film, the second film, and the first film and reaching the single crystal silicon substrate;
forming a first single crystal silicon layer in contact with the single crystal silicon substrate in the first opening;
forming a second opening penetrating the third film and the second film;
etching the second film from a side face of the second opening to form a first recess reaching the first single crystal silicon layer;
forming a second single crystal silicon layer in contact with the first single crystal silicon layer in the first recess;
forming a wiring layer in contact with a first portion of the second single crystal silicon layer;
forming a capacitor in contact with a second portion of the second single crystal silicon layer; and
forming a gate electrode layer facing a third portion of the second single crystal silicon layer between the first portion and the second portion.

2. The method for manufacturing a semiconductor memory device according to claim 1, wherein the first single crystal silicon layer is formed using a solid phase epitaxial growth method.

3. The method for manufacturing a semiconductor memory device according to claim 1, wherein the first single crystal silicon layer is formed using a vapor phase epitaxial growth method.

4. The method for manufacturing a semiconductor memory device according to claim 1, wherein the first single crystal silicon layer is formed using a vapor-liquid-solid method (VLS method).

5. The method for manufacturing a semiconductor memory device according to claim 1, wherein the second single crystal silicon layer is formed using a vapor phase epitaxial growth method.

6. The method for manufacturing a semiconductor memory device according to claim 1, wherein the second single crystal silicon layer is formed using a vapor-liquid-solid method (VLS method).

7. The method for manufacturing a semiconductor memory device according to claim 1, wherein an impurity concentration or an impurity conductivity type in the second single crystal silicon layer is changed during formation of the second single crystal silicon layer in the forming the second single crystal silicon layer.

8. The method for manufacturing a semiconductor memory device according to claim 1, wherein
a first n-type impurity region, a p-type impurity region, and a second n-type impurity region are formed in order from a side closer to the first single crystal silicon layer in the forming the second single crystal silicon layer, and
the gate electrode layer is facing the p-type impurity region.

9. The method for manufacturing a semiconductor memory device according to claim 1, further comprising forming an oxide film on a surface of the second film exposed on a side face of the first opening after the forming the first opening and before the forming the first single crystal silicon layer, wherein
the second material is amorphous silicon or polycrystalline silicon, and
the oxide film is removed after the etching the second film to form the first recess.

10. The method for manufacturing a semiconductor memory device according to claim 1, further comprising:
forming a fourth film of a fourth material different from the second material and the third material, between the second film and the third film;
removing the first single crystal silicon layer in the first opening after the forming the second single crystal silicon layer; and
etching the fourth film from a side face of the first opening to form a second recess after the removing the first single crystal silicon layer, wherein
the wiring layer is formed in the second recess.

11. The method for manufacturing a semiconductor memory device according to claim 1, further comprising:
forming a fourth film of a fourth material different from the first material and the second material, between the first film and the second film;
forming a fifth film of a fifth material identical to the fourth material, between the second film and the third film;
removing the first single crystal silicon layer in the first opening after the forming the second single crystal silicon layer; and
etching each of the fourth film and the fifth film from a side face of the first opening to form a second recess after the removing the first single crystal silicon layer, wherein
the gate electrode layer is formed in the second recess.

12. A semiconductor memory device comprising:
a single crystal silicon substrate;
a single crystal silicon layer extending in a direction along a surface of the single crystal silicon substrate, the single crystal silicon layer being separated from the single crystal silicon substrate;
a wiring layer electrically connected to a first portion of the single crystal silicon layer;
a capacitor electrically connected to a second portion of the single crystal silicon layer; and
a gate electrode layer facing a third portion of the single crystal silicon layer between the first portion and the second portion, wherein
a crystal defect density of the first portion is higher than a crystal defect density of the third portion.

13. The semiconductor memory device according to claim 12, wherein the first portion includes a first n-type impurity region, the second portion includes a second n-type impurity region, and the third portion includes a p-type impurity region.

14. The semiconductor memory device according to claim 12, wherein the crystal defect density of the first portion is equal to or more than ten times the crystal defect density of the third portion.

15. The semiconductor memory device according to claim 12, further comprising a gate insulating film provided between the gate electrode layer and the third portion.

16. A method for manufacturing a semiconductor memory device, the method comprising:
forming a first film of a first material in a first direction of a single crystal silicon substrate;
forming a second film of a second material different from the first material in the first direction of the first film, the second material being amorphous silicon having a first hydrogen concentration;
forming a third film of a third material different from the second material in the first direction of the second film;
forming a first opening penetrating the third film, the second film, and the first film and reaching the single crystal silicon substrate;
forming an amorphous silicon layer in contact with the single crystal silicon substrate and the second film in the first opening, the amorphous silicon layer having a second hydrogen concentration lower than the first hydrogen concentration;
performing first heat treatment at a first temperature to form a first single crystal silicon layer from the amorphous silicon layer by single-crystallizing the amorphous silicon layer by solid phase epitaxial growth;
performing second heat treatment at a second temperature higher than the first temperature to form a second single crystal silicon layer from the second film by single-crystallizing the second film by solid phase epitaxial growth;
forming a wiring layer in contact with a first portion of the second single crystal silicon layer;
forming a capacitor in contact with a second portion of the second single crystal silicon layer; and
forming a gate electrode layer facing a third portion of the second single crystal silicon layer between the first portion and the second portion.

17. The method for manufacturing a semiconductor memory device according to claim 16, wherein the second film has a first carbon concentration, and the amorphous silicon layer has a second carbon concentration lower than the first carbon concentration.

18. The method for manufacturing a semiconductor memory device according to claim 16, wherein the second film is formed by a PECVD method, and the amorphous silicon layer is formed by a thermal CVD method or a thermal ALD method.

19. The method for manufacturing a semiconductor memory device according to claim 16, further comprising:
forming a fourth film of a fourth material different from the second material and the third material, between the second film and the third film;
removing the first single crystal silicon layer in the first opening after the forming the second single crystal silicon layer; and
etching the fourth film from a side face of the first opening to form a recess after the removing the first single crystal silicon layer, wherein
the wiring layer is formed in the recess.

20. The method for manufacturing a semiconductor memory device according to claim 16, further comprising:
forming a fourth film of a fourth material different from the first material and the second material, between the first film and the second film;
forming a fifth film of a fifth material identical to the fourth material, between the second film and the third film;
removing the first single crystal silicon layer in the first opening after the forming the second single crystal silicon layer; and
etching each of the fourth film and the fifth film from a side face of the first opening to form a recess after the removing the first single crystal silicon layer, wherein
the gate electrode layer is formed in the recess.
